(19) United States
(12) Patent Application Publication
(10) Pub. No.: US 2021/0223436 A1
(43) Pub. Date: Jul. 22, 2021

(54) STRUCTURAL BODY, SOLID-STATE IMAGING ELEMENT, AND IMAGE DISPLAY DEVICE

(71) Applicant: FUJIFILM Corporation, Tokyo (JP)

(72) Inventors: Kazuya OOTA, Shizuoka (JP); Yasuhiro SAWAMURA, Shizuoka (JP); Masahiro MORI, Shizuoka (JP)

(73) Assignee: FUJIFILM Corporation, Tokyo (JP)

(21) Appl. No.: 17/219,892

(22) Filed: Apr. 1, 2021

Related U.S. Application Data
(63) Continuation of application No. PCT/JP2019/039894, filed on Oct. 9, 2019.

(30) Foreign Application Priority Data
Oct. 15, 2018 (JP) 2018-194431
Sep. 17, 2019 (JP) 2019-168558

(51) Int. Cl. G02B 1/04; C08K 3/32; C08K 5/3462; C08K 5/357; C08K 5/3415; C08K 3/28; G02B 5/20

(52) U.S. Cl. CPC G02B 1/04; C08K 3/32; C08K 5/3462; G02F 1/133514; C08K 5/3415; C08K 3/28; G02B 5/201; C08K 5/357

(57) ABSTRACT

In a structural body including two pixels which are two-dimensionally arranged in a state of being in contact with each other, each of the two pixels contains a pigment, a pigment derivative in which a maximum value of a molar light absorption coefficient in a wavelength range of 400 to 700 nm is 3000 L·mol⁻¹·cm⁻¹ or less, and a resin. The present invention also relates to a solid-state imaging element and an image display device having the above-described structural body.

### CROSS-REFERENCE TO RELATED APPLICATIONS

This application is a Continuation of PCT International Application No. PCT/JP2019/039894 filed on Oct. 9, 2019, which claims priority under 35 U.S.C § 119(a) to Japanese Patent Application No. 2018-194431 filed on Oct. 15, 2018, and Japanese Patent Application No. 2019-168558 filed on Sep. 17, 2019. Each of the above application(s) is hereby expressly incorporated by reference, in its entirety, into the present application.

### BACKGROUND OF THE INVENTION

### 1. Field of the Invention

The present invention relates to a structural body having a plurality of pixels, a solid-state imaging element, and an image display device.

### 2. Description of the Related Art

In the related art, a color filter has been used in colorizing an image in a solid-state imaging element such as a charge coupled device (CCD) image sensor or an image display device such as a liquid crystal display device.

Generally, in the color filter, a film formed of a photosensitive composition containing a pigment or a dye is formed for each pixel corresponding to each color. By performing exposure, development, heating, and the like, the color filter is formed by cured the film in a pattern. For example, JP2003-081972A discloses that a color filter is formed by using a coloring photosensitive composition of each color, in which a specific triazine compound and a pigment are dispersed in an organic solvent.

### SUMMARY OF THE INVENTION

In recent years, it has been studied to use an infrared filter (IR filter) such as a near-infrared transmission filter and a near-infrared cut filter, or to use an IR filter in addition to the above-described color filter. For example, the near-infrared transmission filter is used to perform infrared sensing and generate an infrared image, and the near-infrared cut filter is used to cut heat ray.

Now, in a structural body including the above-described color filter or IR filter (hereinafter, these are collectively referred to as an “optical filter”), it has been found that a void may be formed over time in a deep layer portion of pixels and a portion where two pixels are in contact with each other. The presence of such a void may deteriorate optical properties of the optical filter. Therefore, it is desired to improve stability of the deep layer portion of pixel to the extent that the void is not formed over time.

The present invention has been studied in view of the above-described problems, and an object of the present invention is to provide a structural body having excellent stability in a deep layer portion of pixel.

Another object of the present invention is to provide a solid-state imaging element and an image display device having the above-described structural body.

The above-described problems can be solved by using a transparent pigment derivative. Specifically, the above-described problems are solved by following methods <1>, preferably <2> to <11>.

<1> A structural body comprising:

two pixels which are two-dimensionally arranged in a state of being in contact with each other,

in which each of the two pixels contains
a pigment,
a pigment derivative in which a maximum value of a molar light absorption coefficient in a wavelength range of 400 to 700 nm is 3000 L·mol⁻¹·cm⁻¹ or less, and
a resin.

<2> The structural body according to <1>,

in which a width of at least one of the two pixels is 0.3 to 5.0 μm.

<3> The structural body according to <1> or <2>,

in which a thickness of at least one of the two pixels is 0.1 to 2.0 μm.

<4> The structural body according to any one of <1> to <3>,

in which a total content of the pigment and the pigment derivative contained in at least one of the two pixels is 25% to 65% by mass.

<5> The structural body according to any one of <1> to <4>,

in which a mass ratio of a content of the pigment derivative contained in at least one of the two pixels and a content of the pigment contained in the same pixel is 3:97 to 20:80.

<6> The structural body according to any one of <1> to <5>,

in which at least one of the pigment derivatives includes an aromatic ring.

<7> The structural body according to <6>,

in which the at least one of the pigment derivatives includes a group represented by Formula (A1),

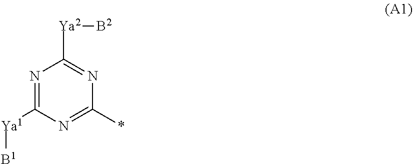

in the formula, * represents a bonding hand,

Ya¹ and Ya² each independently represent —N(Ra¹)— or —O—, where Ra¹ represents a hydrogen atom, an alkyl group, an alkenyl group, an alkynyl group, or an aryl group, and

B¹ and B² each independently represent a hydrogen atom or a substituent.

<8> The structural body according to any one of <1> to <7>,

in which the two pixels are pixels containing different pigments from each other, and

each of the two pixels is a pixel selected from a red pixel, a green pixel, a blue pixel, a yellow pixel, a cyan pixel, a magenta pixel, a black pixel, a white pixel, a pixel of near-infrared cut filter, and a pixel of near-infrared transmission filter.

<9> The structural body according to any one of <1> to <8>, further comprising:

a partition wall which is provided between the two pixels and has a lower height than a thickness of the two pixels.

<10> A solid-state imaging element comprising:

the structural body according to any one of <1> to <9> on a semiconductor substrate.

<11> An image display device comprising:

the structural body according to any one of <1> to <9> on a glass substrate.

According to the present invention, it is possible to obtain a structural body having excellent stability in a deep layer portion of pixel. With the structural body according to the aspect of the present invention, it is possible to provide a solid-state imaging element and an image display device according to the aspect of the present invention.

### BRIEF DESCRIPTION OF THE DRAWINGS

FIGS. 1A to 1C are schematic views showing a structural body including a two-color type color filter.

FIGS. 2A to 2C are schematic views showing a structural body including a three-color type color filter.

FIGS. 3A to 3E are schematic views showing a structural body including a three-color type color filter and an IR filter.

### DESCRIPTION OF THE PREFERRED EMBODIMENTS

Hereinafter, main embodiments of the present invention will be described. However, the present invention is not limited to the specified embodiments.

In the present specification, the numerical value range expressed by a symbol “to” means that the numerical values described before and after “to” are included as a lower limit value and an upper limit value, respectively.

In the present specification, a term “step” is not only an independent step, but also includes a step which cannot be clearly distinguished from other steps as long as the desired action of the step can be achieved.

In describing a group (atomic group) in the present specification, a description having no indication about substitution and non-substitution includes a description having a substituent as well as a description having no substituent. For example, in a case of being simply referred to as an “alkyl group”, this means that the “alkyl group” includes both an alkyl group having no substituent (unsubstituted alkyl group) and an alkyl group having a substituent (substituted alkyl group).

In the present specification, unless specified otherwise, “exposure” denotes not only drawing using light but also drawing using a corpuscular beam such as an electron beam or an ion beam. In addition, examples of energy rays used for the exposure generally include actinic rays such as a bright-line spectrum of a mercury lamp, far ultraviolet rays typified by an excimer laser, extreme ultraviolet rays (EUV light), and X-rays, and particle beams such as electron beams and ion beams.

In the present specification, “(meth)acrylate” means either or both of “acrylate” and “methacrylate”, “(meth)acryl” means either or both of “acryl” and “methacryl”, and “(meth)acryloyl” means either or both of “acryloyl” and “methacryloyl”.

In the present specification, a concentration of solid content in a composition is represented by a mass percentage of other components excluding a solvent with respect to the total mass of the composition.

In the present specification, the atmospheric pressure during boiling point measurement is 101325 Pa (1 atm), unless otherwise specified. In addition, the temperature is 23° C. unless otherwise specified.

In the present specification, unless otherwise stated, weight-average molecular weight (Mw) and number-average molecular weight (Mn) are defined in terms of polystyrene value according to gel permeation chromatography (GPC measurement). The weight-average molecular weight (Mw) and the number-average molecular weight (Mn) can be obtained, for example, by using HLC-8220 (manufactured by Tosoh Corporation) and using, as a column, GUARD COLUMN HZ-L, TSKgel Super HZM-M, TSK gel Super HZ4000, TSK gel Super HZ3000, or TSK gel Super HZ2000 (manufactured by Tosoh Corporation). In addition, unless otherwise stated, measurement is performed using tetrahydrofuran (THF) as an eluent. In addition, unless otherwise stated, detection in the GPC measurement is performed using a detector of ultraviolet rays (UV rays) having a wavelength of 254 nm.

In the present specification, in a case where a positional relationship of each layer constituting a laminate is described as “upper” or “lower”, among a plurality of layers of interest, there may be other layers above or below a reference layer. That is, a third layer or element may be further interposed between the reference layer and the other layers, and the reference layer and the other layers need not be in contact with each other. In addition, unless otherwise specified, a direction in which layers are stacked on a base material is referred to as “upper”, or in a case where there is a photosensitive layer, a direction from the base material to the photosensitive layer is referred to as “upper”. Furthermore, the opposite direction is referred to as “lower”. Such vertical settings are for convenience within the present specification, and in practice, an “upward” direction in the present specification may differ from the vertically upward direction.

In the present specification, “near-infrared light” denotes light (electromagnetic wave) belonging to a wavelength range of 700 to 2500 nm.

<Structural Body>

A structural body according to an embodiment of the present invention includes two pixels which are two-dimensionally arranged in a state of being in contact with each other, in which each of the two pixels contains a pigment, a pigment derivative in which a maximum value of a molar light absorption coefficient in a wavelength range of 400 to 700 nm is 3000 L·mol⁻¹·cm⁻¹ or less, and a resin.

According to the present invention, in a structural body including two pixels which are two-dimensionally arranged in a state of being in contact with each other, stability of a deep layer portion of pixel is improved. The reason is considered as follows.

Generally, in order to dispersibility of a pigment in a photosensitive composition, a pigment derivative having a structure in which a polar group is imparted to the pigment is added together with the pigment.

However, it has been found that, since a pigment derivative in the related art is a colored compound and such a pigment derivative absorbs light during exposure, the curing of a portion deeper than ½ position in the depth direction from the pixel surface, particularly a portion deeper than a ⅔ position in the depth direction from the pixel surface, (hereinafter, these are collectively referred to as a “deep layer portion of pixel”) is hindered. It is considered that a void generated in the deep layer portion between pixels is affected by deterioration over time in the direction in which both pixels contract in such a portion where the curing is insufficient.

Therefore, in the present invention, by using a transparent pigment derivative in which a maximum value of a molar light absorption coefficient in a wavelength range of 400 to 700 nm is 3000 L·mol⁻¹·cm⁻¹ or less, during exposure, consumption of light by the pigment derivative is suppressed, and the curing of the deep layer portion of pixel can be promoted as compared with the related art. It is considered that, by promoting the curing in the deep layer portion in this way, the stability of the pixel is improved in that film quality of the pixels is dense or adhesiveness of the pixels to the support is improved. In addition, it is considered that, since the pigment derivative is transparent, that is, since the pigment derivative is less affected by irradiation light (ultraviolet rays and the like) during exposure, deterioration and destruction of the pigment derivative are suppressed, and the stability of the pigment derivative itself during exposure is improved, which also contributes to efficient curing in the deep layer portion.

Hereinafter, each configuration of the structural body according to the embodiment of the present invention will be described in detail.

<<Configuration of Pixel>>

For example, the structural body according to the embodiment of the present invention functions as a color filter, a near-infrared cut filter, or a near-infrared transmission filter, or functions as an optical filter of a combination of these filters. Such a structural body can be used by being incorporated into various types of optical sensors such as a solid-state imaging element, or into an image display device (for example, liquid crystal display device, organic electroluminescence (organic EL) display device, and the like). For example, the optical sensor incorporating the structural body according to the embodiment of the present invention is preferably used for surveillance applications, security applications, mobile applications, automobile applications, agricultural applications, medical applications, distance measurement applications, gesture recognition applications, vital recognition applications, and the like.

Examples of the color filter include a filter having a colored pixel which transmits light having a specific wavelength, and a filter having at least one colored pixel selected from a red pixel, a blue pixel, a green pixel, a yellow pixel, a cyan pixel, and a magenta pixel is preferable. The color filter can be formed using a photosensitive composition including a chromatic pigment.

Examples of the near-infrared cut filter include a filter having a maximum absorption wavelength in a wavelength range of 700 to 1800 nm. As the near-infrared cut filter, a filter having a maximum absorption wavelength in a wavelength range of 700 to 1300 nm is preferable, and a filter having a maximum absorption wavelength in a wavelength range of 700 to 1000 nm is more preferable. In addition, in the near-infrared cut filter, a transmittance of in the entire wavelength range of 400 to 650 nm is preferably 70% or more, more preferably 80% or more, and still more preferably 90% or more. In addition, the transmittance at at least one point in a wavelength range of 700 to 1800 nm is preferably 20% or less. In addition, in the near-infrared cut filter, absorbance Amax/absorbance A550, which is a ratio of an absorbance Amax at a maximum absorption wavelength to an absorbance A550 at a wavelength of 550 nm, is preferably 20 to 500, more preferably 50 to 500, still more preferably 70 to 450, and particularly preferably 100 to 400. The near-infrared cut filter can be formed using a photosensitive composition including a near-infrared absorbing pigment.

The near-infrared transmission filter is a filter which transmits at least a part of near-infrared rays. The near-infrared transmission filter may be a filter (transparent film) which transmits both visible light and near-infrared ray, or may be a filter which shields at least a part of visible light and transmits at least a part of near-infrared rays. Examples of the near-infrared transmission filter include filters satisfying spectral characteristics in which the maximum value of a transmittance in a wavelength range of 400 to 640 nm is 20% or less (preferably 15% or less and more preferably 10% or less) and the minimum value of a transmittance in a wavelength range of 1100 to 1300 nm is 70% or more (preferably 75% or more and more preferably 80% or more). The near-infrared transmission filter is preferably a filter which satisfies any one of the following spectral characteristics (1) to (4).

(1): filter in which the maximum value of a transmittance in a wavelength range of 400 to 640 nm is 20% or less (preferably 15% or less and more preferably 10% or less) and the minimum value of a transmittance in a wavelength range of 800 to 1300 nm is 70% or more (preferably 75% or more and more preferably 80% or more).

(2): filter in which the maximum value of a transmittance in a wavelength range of 400 to 750 nm is 20% or less (preferably 15% or less and more preferably 10% or less) and the minimum value of a transmittance in a wavelength range of 900 to 1300 nm is 70% or more (preferably 75% or more and more preferably 80% or more).

(3): filter in which the maximum value of a transmittance in a wavelength range of 400 to 830 nm is 20% or less (preferably 15% or less and more preferably 10% or less) and the minimum value of a transmittance in a wavelength range of 1000 to 1300 nm is 70% or more (preferably 75% or more and more preferably 80% or more).

(4): filter in which the maximum value of a transmittance in a wavelength range of 400 to 950 nm is 20% or less (preferably 15% or less and more preferably 10% or less) and the minimum value of a transmittance in a wavelength range of 1100 to 1300 nm is 70% or more (preferably 75% or more and more preferably 80% or more).

In the structural body according to the embodiment of the present invention, the two pixels are two-dimensionally arranged in a state of being in contact with each other. “In a state of being in contact with each other” refers to that two predetermined pixels which are two-dimensionally arranged are in contact with each other at least a part of their opposite side surfaces. In a case where the two predetermined pixels are partially in contact with each other, there may be a partition wall between the two pixels, which has a lower height than the thickness of the two pixels. The low height of the partition wall may be, for example, 10% to 90% of the thickness of the pixels, or 30% to 70% of the thickness of the pixels. In addition, in a case where two pixels are in contact at some positions between the pixels, there may be a partition wall at other positions between the pixels, which has a higher height than the thickness of the pixels. In addition, it is preferable that the partition wall is formed of a material having a lower refractive index than that of a pixel of near-infrared transmission filter. According to this aspect, light collecting property of near-infrared light can be further enhanced, and sensitivity of near improved rays can be further improved.

In the structural body according to the embodiment of the present invention, the two pixels may be pixels containing different pigments from each other, and each of the two pixels may be a pixel selected from a red pixel, a green pixel, a blue pixel, a yellow pixel, a cyan pixel, a magenta pixel, a black pixel, a white pixel, a pixel of near-infrared cut filter, and a pixel of near-infrared transmission filter. Which pixel is included in the structural body according to the embodiment of the present invention is designed according to the desired function of the structural body. For example, the structural body according to the embodiment of the present invention can function as a two-color type color filter including two-color pixels (for example, as an RGB type color filter including a red pixel, a green pixel, and a blue pixel, or as a CMY type color filter including a cyan pixel, a magenta pixel, and a yellow pixel. In addition, for example, the structural body according to the embodiment of the present invention can function as an optical filter in which a near-infrared cut filter (black pixel) added to an RGB type color filter, as an optical filter in which a near-infrared transmission filter is added to an RGB type color filter, or as an optical filter in which a white pixel is added to an RGB type color filter. Specific examples thereof are as follows.

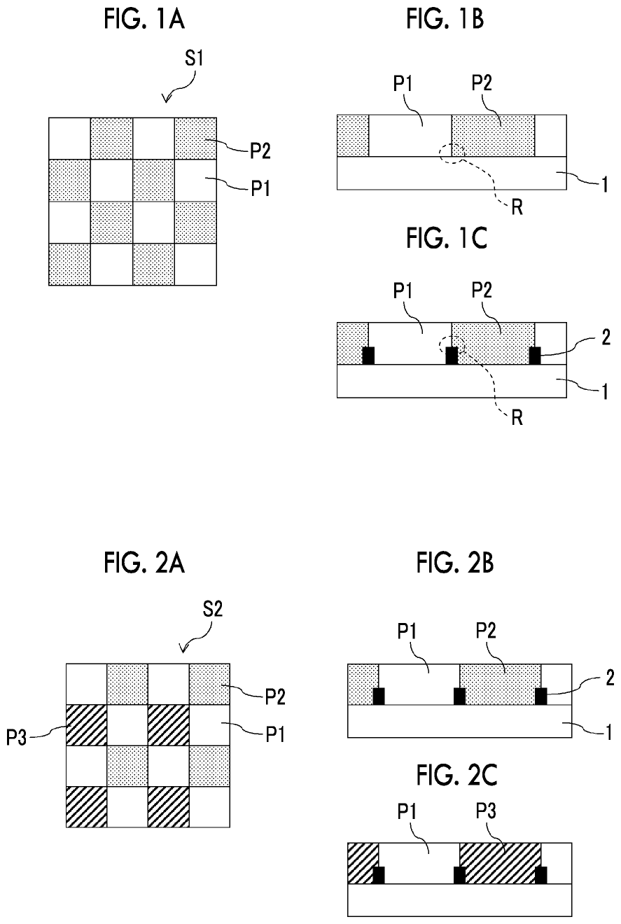

The structural body according to the embodiment of the present invention can be, for example, a structural body including a two-color type color filter. FIGS. 1A to 1C are schematic views showing a structural body S1 including a two-color type color filter. In addition, FIG. 1A is a top view of the structural body S1, and FIGS. 1B and 1C are cross-sectional views of the structural body S1 in a plane including pixels P1 and pixels P2. Here, for example, the pixel P1 is a green pixel and the pixel P2 is a red pixel. In the structural bodies of FIGS. 1A to 1C, the pixel P1 and the pixel P2 are alternately spread on a support 1, and the pixel P1 and the pixel P2 are in contact with each other on all sides in the top view. On the other hand, FIG. 1B is a cross-sectional view in a case where there is no partition wall between the pixels P1 and P2, and FIG. 1C is a cross-sectional view in a case where there is a partition wall 2 between the pixels P1 and P2. Since there is no partition wall between the pixels in FIG. 1B, it can be said that the two adjacent pixels P1 and P2 are in contact with each other on all side surfaces facing each other, and since there is the partition wall 2 between the pixels in FIG. 1C, it can be said that the two adjacent pixels P1 and P2 are in contact with each other on a part of their opposite side surfaces.

In such an optical filter, as described above, a void is likely to generate in a vicinity area R which is the deep layer portion of pixels and is a portion where the two pixels are in contact with each other. Specifically, for example, in the case of FIG. 1B, the area R is in the vicinity of the area where a contact surface of the two pixels P1 and P2 and a surface of the support 1 intersect, and in the case of FIG. 1C, the area R is in the vicinity of the area where a contact surface of the two pixels P1 and P2 and a top surface of the partition wall 2 intersect. In the present invention, as described above, the stability can be improved by promoting the curing of the deep layer portion of pixel, which includes the area R, as compared with the related art.

In addition, the structural body according to the embodiment of the present invention can be, for example, a structural body including a three-color type color filter. FIGS. 2A to 2C are schematic views showing a structural body S2 including a three-color type color filter. In addition, FIG. 2A is a top view of the structural body S2, FIG. 2B is a cross-sectional view of the structural body S2 in a plane including pixels P1 and pixels P2, and FIG. 2C is a cross-sectional view of the structural body S2 in a plane including pixels P1 and pixels P3. Here, for example, the pixel P1 is a green pixel, the pixel P2 is a red pixel, and the pixel P3 is a blue pixel. In the structural bodies S2 of FIGS. 2A to 2C, the pixel P1, the pixel P2, and the pixel P3 are alternately spread on a support 1 at a ratio of 2:1:1, and each of the pixel P1, the pixel P2, and the pixel P3 is in contact with adjacent pixels on all sides in the top view. On the other hand, as shown in FIGS. 2b and 2c, since there is a partition wall 2 between pixels in the structural body S2, it can be said that two adjacent pixels are in contact with each other on a part of their opposite side surfaces. The structural body S2 may not have the partition wall as in the structural body S1 of FIG. 1B. The area where a void is likely to generate is also the same as in the structural body S1.

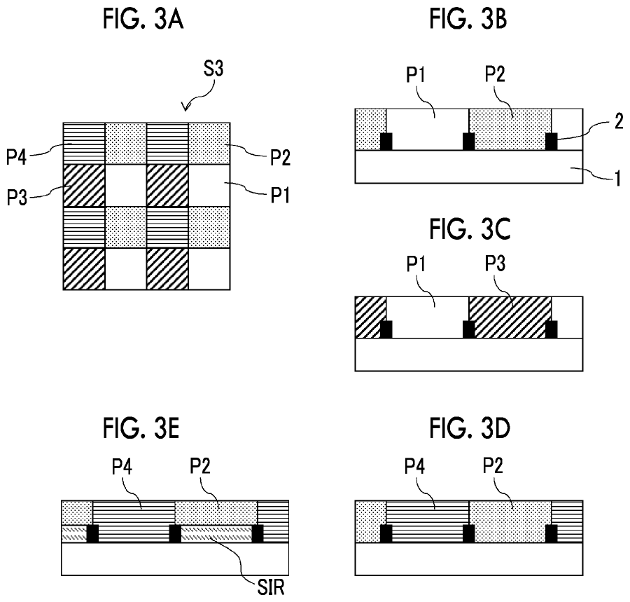

Furthermore, the structural body according to the embodiment of the present invention can be, for example, a structural body including a three-color type color filter and an IR filter. FIGS. 3A to 3E is a schematic view showing a structural body S3 including a three-color type color filter and an IR filter. In addition, FIG. 3A is a top view of the structural body S3, FIG. 3B is a cross-sectional view of the structural body S3 in a plane including pixels P1 and pixels P2, FIG. 3C is a cross-sectional view of the structural body S3 in a plane including pixels P1 and pixels P3, and FIG. 3D is a cross-sectional view of the structural body S3 in a plane including pixels P4 and pixels P2. Here, for example, the pixel P1 is a green pixel, the pixel P2 is a red pixel, the pixel P3 is a blue pixel, and the pixel P4 is a pixel of near-infrared transmission filter. In the structural bodies S3 of FIGS. 3A to 3E, the pixels P1 to P4 are alternately spread on a support 1 at a ratio of 1:1:1:1, and each of the pixels P1 to P4 is in contact with adjacent pixels on all sides in the top view. On the other hand, as shown in FIGS. 3B to 3D, since there is a partition wall 2 between pixels in the structural body S3, it can be said that two adjacent pixels are in contact with each other on a part of their opposite side surfaces. The structural body S3 may not have the partition wall as in the structural body S1 of FIG. 1B. The area where a void is likely to generate is also the same as in the structural body S1. Furthermore, as shown in FIG. 3E, in the structural body S3, for example, a near-infrared cut filter SIR can be provided under the pixels P1 to P3 of color filter. The near-infrared cut filter SIR can be similarly provided in each of the structural bodies shown in FIGS. 1A to 1C and FIGS. 2A to 2C.

In addition, the structural body according to the embodiment of the present invention can also be, for example, a structural body including a three-color type color filter and a white pixel, or a structural body in which, in the above-described structural body, a CMY type color filter is adopted as the three-color type color filter. In addition, in the structural body according to the embodiment of the present invention, an anti-reflection film, a flattening film, a lens, and the like may be provided on the optical filter. A coloring material which absorbs infrared rays may be added to a lens material for forming the lens. The refractive index of the lens material with respect to light having a wavelength of 550 nm is preferably 1.5 to 1.8. The upper limit of the numerical range is more preferably 1.75 or less and still more preferably 1.70 or less. In addition, the lower limit of the numerical range is more preferably 1.55 or more and still more preferably 1.58. In a case of forming a film of the lens material, which has a film thickness of 0.35 μm, the minimum transmittance of the lens material with respect to light having a wavelength of 400 to 700 nm is preferably 90% or more and more preferably 95% or more. The upper limit value of the transmittance is preferably 100% and is practically approximately 98%. In a case of forming a film of the lens material, which has a film thickness of 0.35 μm, the transmittance of the lens material with respect to light having a wavelength of 820 nm is preferably 70% or less, more preferably 60% or less, and still more preferably 50% or less. The lower limit value of the transmittance is preferably 0% and is practically approximately 50%.

In the structural body according to the embodiment of the present invention, the width of at least one of the two pixels is preferably 0.3 to 5.0 μm. In particular, in applications such as single-lens reflex camera, where relatively large-sized pixels are used, the upper limit of the width of each pixel is more preferably 4.0 μm or less, still more preferably 3.5 μm or less, and particularly preferably 3.0 μm or less, respectively. In addition, the lower limit of the width of each pixel in the application is more preferably 1.7 μm or more, still more preferably 2.0 μm or more, and particularly preferably 2.5 μm or more, respectively. On the other hand, in applications such as mobile, where relatively small-sized pixels are used, the upper limit of the width of each pixel is more preferably 1.7 μm or less, still more preferably 1.5 μm or less, and particularly preferably 1.2 μm or less, respectively. In addition, the lower limit of the width of each pixel in the application is more preferably 0.5 μm or more, still more preferably 0.6 μm or more, and particularly preferably 0.7 μm or more, respectively. The thickness of at least one of the two pixels is preferably 0.1 to 2.0 μm. In particular, in the applications where relatively large-sized pixels are used, the upper limit of the thickness of each pixel is more preferably 1.8 μm or less, still more preferably 1.6 μm or less, and particularly preferably 1.4 μm or less, respectively. In addition, the lower limit of the thickness of each pixel in the application is more preferably 0.8 μm or more, still more preferably 0.9 μm or more, and particularly preferably 1.0 μm or more, respectively. On the other hand, in the applications where relatively small-sized pixels are used, the upper limit of the thickness of each pixel is more preferably 0.8 μm or less, still more preferably 0.7 μm or less, and particularly preferably 0.6 μm or less, respectively. In addition, the lower limit of the thickness of each pixel in the application is more preferably 0.2 μm or more, still more preferably 0.3 μm or more, and particularly preferably 0.4 μm or more, respectively. As the width and thickness of each pixel are smaller as described above, the influence of the void generated in the deep layer portion of pixel is larger, and the usefulness of the present invention is greater.

<<Composition for Forming Pixel>>

In the structural body according to the embodiment of the present invention, each pixel includes a pigment, a pigment derivative, and a resin, depending on a desired function. As will be described later in detail, for example, such a pixel is formed by forming a film of a photosensitive composition (hereinafter, also simply referred to as a “composition”) containing a pigment, a pigment derivative, and a resin, and performing treatments such as exposure and development to the film. The structural body according to the embodiment of the present invention is obtained by repeating such a pixel forming step until all the necessary pixels are formed. Hereinafter, the contents of the composition for forming a pixel in the present invention will be described.

<<<Pigment>>>

In the present invention, the photosensitive composition contains a pigment. Examples of the pigment include a white pigment, a black pigment, a chromatic pigment, and a near-infrared absorbing pigment. In the present invention, the white pigment includes not only a pure white pigment but also a bright gray (for example, grayish-white, light gray, and the like) pigment close to white. In addition, the pigment may be an inorganic pigment or an organic pigment, but from the viewpoint that dispersion stability is more easily improved, an organic pigment is preferable. In addition, as the pigment, a pigment having a maximum absorption wavelength in a wavelength range of 400 to 2000 nm is preferable, and a pigment having a maximum absorption wavelength in a wavelength range of 400 to 700 nm is more preferable. In addition, the pigment may be used alone, or may be used in combination with a dye. In addition, as the pigment, a material in which a part of an inorganic pigment or an organic-inorganic pigment is replaced with an organic chromophore can also be used. By substituting an inorganic pigment or an organic-inorganic pigment with an organic chromophore, color tone design can be easily performed.

In a case of forming a pixel of color filter, for example, a predetermined pigment appropriately selected from chromatic pigments is used as the pigment. In addition, in a case of forming a pixel of near-infrared cut filter, a near-infrared absorbing pigment is used as the pigment. In a case of forming a pixel of near-infrared transmission filter, a pigment which exhibits black by combining two or more kinds of chromatic pigments, or a black pigment is used.

The average primary particle diameter of the pigment is preferably 1 to 200 nm. The lower limit is more preferably 5 nm or more and still more preferably 10 nm or more. The upper limit is more preferably 180 nm or less, still more preferably 150 nm or less, and particularly preferably 100 nm or less. In a case where the average primary particle diameter of the pigment is within the above-described range, dispersion stability of the pigment in the photosensitive composition is good. In the present invention, the primary particle diameter of the pigment can be determined from an image obtained by observing primary particles of the pigment using a transmission electron microscope. Specifically, a projected area of the primary particles of the pigment is determined, and the corresponding circle diameter is calculated as the primary particle diameter of the pigment. In addition, the average primary particle diameter in the present invention is the arithmetic average of the primary particle diameters with respect to 400 primary particles of the pigment. In addition, the primary particle of the pigment refers to a particle which is independent without aggregation.

The content of the pigment in one pixel is preferably 25% to 65% by mass. The upper limit is more preferably 60% by mass or less and still more preferably 55% by mass or less. The lower limit is more preferably 25% by mass or more, still more preferably 30% by mass or more, and particularly preferably 35% by mass or more. Examples of the pigment include the following pigments:

(Chromatic Pigment)

The chromatic pigment is not particularly limited, and a known chromatic pigment can be used. Examples of the chromatic pigment include a pigment having a maximum absorption wavelength in a wavelength range of 400 to 700 nm. Examples thereof include a yellow pigment, an orange pigment, a red pigment, a green pigment, a violet pigment, and a blue pigment. Specific examples of these pigments include the following pigments.

Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232 (methine-based), 233 (quinoline-based), 234 (aminoketone-based), 235 (aminoketone-based), 236 (aminoketone-based), and the like (all of which are yellow pigments; hereinafter, also simply referred to as “PY1”);

C. I. Pigment Orange 2, 5, 13, 16, 17:1, 31, 34, 36, 38, 43, 46, 48, 49, 51, 52, 55, 59, 60, 61, 62, 64, 71, 73, and the like (all of which are orange pigments; hereinafter, also simply referred to as “PO2”);

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 269, 270, 272, 279, 291, 294 (xanthene-based, Organo Ultramarine, Bluish Red), 295 (monoazo-based), 296 (diazo-based), 297 (aminoketone-based), and the like (all of which are red pigments; hereinafter, also simply referred to as “PR1”);

C. I. Pigment Green 7, 10, 36, 37, 58, 59, 62, 63, 64 (phthalocyanine-based), 65 (phthalocyanine-based), 66 (phthalocyanine-based), and the like (all of which are green pigments; hereinafter, also simply referred to as “PG7”);

C. I. Pigment Violet 1, 19, 23, 27, 32, 37, 42, 60 (triarylmethane-based), 61 (xanthene-based), and the like (all of which are violet pigments; hereinafter, also simply referred to as “PV1”); and

C. I. Pigment Blue 1, 2, 15, 15:1, 15:2, 15:3, 15:4, 15:6, 16, 22, 29, 60, 64, 66, 79, 80, 87 (monoazo-based), 88 (methine-based), and the like (all of which are blue pigments; hereinafter, also simply referred to as “PB1”).

In addition, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used as the green pigment. Specific examples thereof include the compounds described in WO2015/118720A. In addition, as the green pigment, a compound described in CN2010-6909027A, a phthalocyanine compound described in WO2012/102395A, which has phosphoric acid ester as a ligand, a phthalocyanine compound described in JP2019-008014A, a phthalocyanine compound described in JP2018-180023A, a compound described in JP2019-038958A, and the like can also be used.

In addition, an aluminum phthalocyanine compound having a phosphorus atom can also be used as the blue pigment. Specific examples thereof include the compounds described in paragraphs 0022 to 0030 of JP2012-247591A and paragraph 0047 of JP2011-157478A.

In addition, as the yellow pigment, compounds described in JP2017-201003A, compounds described in JP2017-197719A, compounds described in paragraph Nos. 0011 to 0062 and 0137 to 0276 of JP2017-171912A, compounds described in paragraph Nos. 0010 to 0062 and 0138 to 0295 of JP2017-171913A, compounds described in paragraph Nos. 0011 to 0062 and 0139 to 0190 of JP2017-171914A, compounds described in paragraph Nos. 0010 to 0065 and 0142 to 0222 of JP2017-171915A, quinophthalone compounds described in paragraph Nos. 0011 to 0034 of JP2013-054339A, quinophthalone compounds described in paragraph Nos. 0013 to 0058 of JP2014-026228A, isoindoline compounds described JP2018-062644A, quinophthalone compounds described in JP2018-203798A, quinophthalone compounds described in JP2018-062578A, quinophthalone compounds described in JP6432076B, quinophthalone compounds described in JP2018-155881A, quinophthalone compounds described in JP2018-111757A, quinophthalone compounds described in JP2018-040835A, quinophthalone compounds described in JP2017-197640A, quinophthalone compounds described in JP2016-145282A, quinophthalone compounds described in JP2014-085565A, quinophthalone compounds described in JP2014-021139A, quinophthalone compounds described in JP2013-209614A, quinophthalone compounds described in JP2013-209435A, quinophthalone compounds described in JP2013-181015A, quinophthalone compounds described in JP2013-061622A, quinophthalone compounds described in JP2013-032486A, quinophthalone compounds described in JP2012-226110A, quinophthalone compounds described in JP2008-074987A, quinophthalone compounds described in JP2008-081565A, quinophthalone compounds described in JP2008-074986A, quinophthalone compounds described in JP2008-074985A, quinophthalone compounds described in JP2008-050420A, quinophthalone compounds described in JP2008-031281A, quinophthalone compounds described in JP1973-032765A (JP-548-032765A), quinophthalone compounds described in JP2019-008014A, a compound represented by Formula (QP1), and a compound represented by Formula (QP2) can also be used.

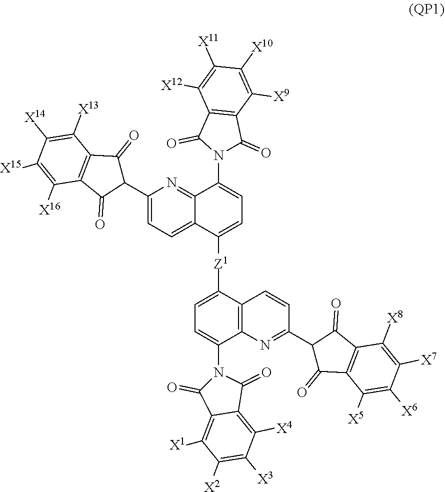

In Formula (QP1), X¹ to X¹⁶ each independently represent a hydrogen atom or a halogen atom, and Z¹ represents an alkylene group having 1 to 3 carbon atoms. Specific examples of the compound represented by Formula (QP1) include compounds described in paragraph No. 0016 of JP6443711B.

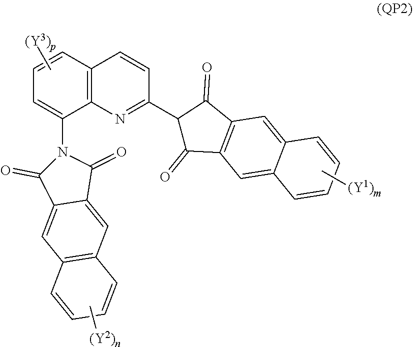

In Formula (QP2), Y¹ to Y³ each independently represent a halogen atom. n and m represent an integer of 0 to 6, and p represents an integer of 0 to 5. (n+m) is 1 or more. Specific examples of the compound represented by Formula (QP2) include compounds described in paragraph Nos. 0047 and 0048 of JP6432077B.

As the red pigment, diketopyrrolopyrrole compounds described in JP2017-201384A, in which the structure has at least one substituted bromine atom, diketopyrrolopyrrole compounds described in paragraph Nos. 0016 to 0022 of JP6248838B, diketopyrrolopyrrole compounds described in WO2012/0102399A, diketopyrrolopyrrole compounds described in WO2012/0117965A, naphtholazo compounds described in JP2012-229344, red coloring materials described in JP6516119B, red coloring material described in JP6525101B, and the like can also be used. In addition, as the red pigment, a compound having a structure that an aromatic ring group in which a group bonded with an oxygen atom, a sulfur atom, or a nitrogen atom is introduced to an aromatic ring is bonded to a diketopyrrolopyrrole skeleton can be used.

In the present invention, the chromatic pigment may be used in combination of two or more kinds thereof. In addition, in a case where the chromatic pigment is used in combination of two or more kinds thereof, the combination of two or more chromatic pigments may form black. Examples of such a combination include the following aspects (1) to (7). In a case where two or more chromatic pigments are contained in the composition and the combination of two or more chromatic pigments forms black, the composition can be preferably used for the near-infrared transmission filter.

(1) aspect in which a red pigment and a blue pigment are contained.

(2) aspect in which a red pigment, a blue pigment, and a yellow pigment are contained.

(3) aspect in which a red pigment, a blue pigment, a yellow pigment, and a violet pigment are contained.

(4) aspect in which a red pigment, a blue pigment, a yellow pigment, a violet pigment, and a green pigment are contained.

(5) aspect in which a red pigment, a blue pigment, a yellow pigment, and a green pigment are contained.

(6) aspect in which a red pigment, a blue pigment, and a green pigment are contained.

(7) aspect in which a yellow pigment and a violet pigment are contained.

(White Pigment)

Examples of the white pigment include titanium oxide, strontium titanate, barium titanate, zinc oxide, magnesium oxide, zirconium oxide, aluminum oxide, barium sulfate, silica, talc, mica, aluminum hydroxide, calcium silicate, aluminum silicate, hollow resin particles, and zinc sulfide. The white pigment is preferably particles having a titanium atom, more preferably titanium oxide. In addition, the white pigment is preferably a particle having a refractive index of 2.10 or more with respect to light having a wavelength of 589 nm. The above-mentioned refractive index is more preferably 2.10 to 3.00 and still more preferably 2.50 to 2.75.

In addition, as the white pigment, the titanium oxide described in “Titanium Oxide-Physical Properties and Applied Technology, written by Manabu Kiyono, pages 13 to 45, published in Jun. 25, 1991, published by Shuppan Co., Ltd.” can also be used.

The white pigment is not limited to a compound formed of a single inorganic substance, and may be particles combined with other materials. For example, it is preferable to use a particle having a pore or other materials therein, a particle having a number of inorganic particles attached to a core particle, or a core-shell composite particle composed of a core particle formed of polymer particles and a shell layer formed of inorganic fine nanoparticles. With regard to the core-shell composite particle composed of a core particle formed of polymer particles and a shell layer formed of inorganic fine nanoparticles, reference can be made to, for example, the descriptions in paragraph Nos. 0012 to 0042 of JP2015-047520A, the contents of which are incorporated herein by reference.

As the white pigment, hollow inorganic particles can also be used. The hollow inorganic particles refer to inorganic particles having a structure with a cavity therein, and the cavity is enclosed by an outer shell. As the hollow inorganic particles, hollow inorganic particles described in JP2011-075786A, WO2013/061621A, JP2015-164881A, and the like can be used, the contents of which are incorporated herein by reference.

(Black Pigment)

The black pigment is not particularly limited, and a known black pigment can be used. Examples thereof include carbon black, titanium black, and graphite, and carbon black or titanium black is preferable and titanium black is more preferable. The titanium black is black particles containing a titanium atom, and is preferably lower titanium oxide or titanium oxynitride. The surface of the titanium black can be modified, as necessary, according to the purpose of improving dispersibility, suppressing aggregating properties, and the like. For example, the surface of the titanium black can be coated with silicon oxide, titanium oxide, germanium oxide, aluminum oxide, magnesium oxide, or zirconium oxide. In addition, a treatment with a water-repellent substance as described in JP2007-302836A can be performed. Examples of the black pigment include Color Index (C. I.) Pigment Black 1 and 7. It is preferable that the titanium black has a small primary particle diameter of the individual particles and has a small average primary particle diameter. Specifically, the average primary particle diameter thereof is preferably 10 to 45 nm. The titanium black can be used as a dispersion. Examples thereof include a dispersion which includes titanium black particles and silica particles and in which the content ratio of Si atoms to Ti atoms is adjusted to a range of 0.20 to 0.50. With regard to the dispersion, reference can be made to the description in paragraphs 0020 to 0105 of JP2012-169556A, the contents of which are incorporated herein by reference. Examples of a commercially available product of the titanium black include Titanium black 10S, 12S, 13R, 13M, 13M-C, 13R-N, 13M-T (trade name; manufactured by Mitsubishi Materials Corporation) and Tilack D (trade name; manufactured by Akokasei Co., Ltd.). In addition, perylene black (Lumogen Black FK4280 and the like) described in paragraphs 0016 to 0020 of JP2017-226821A may be used.

In addition, in the present invention, an organic black colorant can also be used. The organic black colorant may be a pigment or a dye, and a pigment is preferable. Examples of the organic black colorant include a bisbenzofuranone compound, an azomethine compound, a perylene compound, and an azo compound. Among these, a bisbenzofuranone compound or a perylene compound is preferable. Examples of the bisbenzofuranone compound include the compounds described in JP2010-534726A, JP2012-515233A, JP2012-515234A, and the like, and the bisbenzofuranone compound is available, for example, as “Irgaphor Black” manufactured by BASF. Examples of the perylene compound include C. I. Pigment Black 31 and 32. Examples of the azomethine compound include the compounds described in JP1989-170601A (JP-H01-170601A) and JP1990-034664A (JP-H02-034664A), and the azomethine compound is available, for example, “CHROMOFINE BLACK A1103” manufactured by Dainichiseika Color & Chemicals Mfg. Co., Ltd.

(Near-Infrared Absorbing Pigment)

The near-infrared absorbing pigment is preferably an organic pigment. In addition, the near-infrared absorbing pigment preferably has a maximum absorption wavelength in a wavelength range of more than 700 nm and 1400 nm or less. In addition, the maximum absorption wavelength of the near-infrared absorbing pigment is more preferably 1200 nm or less, still more preferably 1000 nm or less, and particularly preferably 950 nm or less. In addition, in the near-infrared absorbing pigment, A₅₅₀/Aₘₐₓ, which is a ratio of an absorbance A550 at a wavelength of 550 nm to an absorbance Amax at the maximum absorption wavelength, is preferably 0.1 or less, more preferably 0.05 or less, still more preferably 0.03 or less, and particularly preferably 0.02 or less. The lower limit is not particularly limited, but for example, may be 0.0001 or more or may be 0.0005 or more. In a case where the ratio of the above-described absorbance is within the above-described range, a near-infrared absorbing pigment excellent in visible light transparency and near-infrared rays shielding property can be obtained. In the present invention, the maximum absorption wavelength of the near-infrared absorbing pigment and values of absorbance at each wavelength are values obtained from an absorption spectrum of a film formed by using a photosensitive composition including the near-infrared absorbing pigment.

The near-infrared absorbing pigment is not particularly limited, and examples thereof include a pyrrolopyrrole compound, a rylene compound, an oxonol compound, a squarylium compound, a cyanine compound, a croconium compound, a phthalocyanine compound, a naphthalocyanine compound, a pyrylium compound, an azurenium compound, an indigo compound, and a pyrromethene compound. Among these, at least one compound selected from a pyrrolopyrrole compound, a squarylium compound, a cyanine compound, a phthalocyanine compound, or a naphthalocyanine compound is preferable, and a pyrrolopyrrole compound or a squarylium compound is more preferable, and a pyrrolopyrrole compound is particularly preferable.

In the present invention, the photosensitive composition can contain a dye. The dye is not particularly limited and a known dye can be used. The dye may be a chromatic dye or may be a near-infrared absorbing dye. Examples of the chromatic dye include a pyrazoleazo compound, an anilinoazo compound, a triarylmethane compound, an anthraquinone compound, an anthrapyridone compound, a benzylidene compound, an oxonol compound, a pyrazolotriazoleazo compound, a pyridoneazo compound, a cyanine compound, a phenothiazine compound, a pyrrolopyrazoleazomethine compound, a xanthene compound, a phthalocyanine compound, a benzopyran compound, an indigo compound, and a pyrromethene compound. In addition, the thiazole compound described in JP2012-158649A, the azo compound described in JP2011-184493A, or the azo compound described in JP2011-145540A can also be used. In addition, as yellow dyes, the quinophthalone compounds described in paragraph Nos. 0011 to 0034 of JP2013-054339A, or the quinophthalone compounds described in paragraph Nos. 0013 to 0058 of JP2014-026228A can be used. In addition, from the viewpoint of improving heat resistance, as the yellow dyes, methine compounds described in JP2019-073695A, JP2019-073696A, JP2019-073697A, and JP2019-073698A can also be suitably used. Examples of the near-infrared absorbing dye include a pyrrolopyrrole compound, a rylene compound, an oxonol compound, a squarylium compound, a cyanine compound, a croconium compound, a phthalocyanine compound, a naphthalocyanine compound, a pyrylium compound, an azurenium compound, an indigo compound, and a pyrromethene compound. In addition, the squarylium compounds described in JP2017-197437A, the squarylium compounds described in paragraph Nos. 0090 to 0107 of WO2017/213047A, the pyrrole ring-containing compounds described in paragraph Nos. 0019 to 0075 of JP2018-054760A, the pyrrole ring-containing compounds described in paragraph Nos. 0078 to 0082 of JP2018-040955A, the pyrrole ring-containing compounds described in paragraph Nos. 0043 to 0069 of JP2018-002773A, the squarylium compounds having an aromatic ring at the α-amide position described in paragraph Nos. 0024 to 0086 of JP2018-041047A, the amide-linked squarylium compounds described in JP2017-179131A, the compounds having a pyrrole bis-type squarylium skeleton or a croconium skeleton described in JP2017-141215A, the dihydrocarbazole bis-type squarylium compounds described in JP2017-082029, the asymmetric compounds described in paragraph Nos. 0027 to 0114 of JP2017-068120A, the pyrrole ring-containing compounds (carbazole type) described in JP2017-067963A, the phthalocyanine compounds described in JP6251530B, and the like can also be used.

The content of the dye in the total solid content of the photosensitive composition is preferably 1% by mass or more, more preferably 5% by mass or more, and particularly preferably 10% by mass or more. The upper limit is not particularly limited, but is preferably 70% by mass or less, more preferably 65% by mass or less, and still more preferably 60% by mass or less.

In addition, the content of the dye is preferably 5 to 50 parts by mass with respect to 100 parts by mass of the pigment. The upper limit is more preferably 45 parts by mass or less and still more preferably 40 parts by mass or less. The lower limit is more preferably 10 parts by mass or more and still more preferably 15 parts by mass or more.

In addition, in the present invention, it is also possible that the photosensitive composition does not substantially contain the dye. The case where the photosensitive composition in the present invention does not substantially include the dye means that the content of the dye in the total solid content of the photosensitive composition in the present invention is preferably 0.1% by mass or less, more preferably 0.05% by mass or less, and particularly preferably 0% by mass.

<<<Pigment Derivative>>>

In the present invention, the photosensitive composition contains a pigment derivative in which the maximum value (εmax) of a molar light absorption coefficient in a wavelength range of 400 to 700 nm is 3000 L·mol⁻¹·cm⁻¹ or less. Since the composition contains the pigment derivative, dispersibility of the pigment in the composition is improved. In addition, since the pigment derivative has an absorption characteristic which satisfies the above-described requirement, as described above, the curing of the composition in the deep layer portion of pixel is promoted as compared with the related art.

In the present invention, the εmax of the pigment derivative is more preferably 1000 L·mol⁻¹·cm⁻¹ or less and still more preferably 100 L·mol⁻¹·cm⁻¹ or less. According to this aspect, adhesiveness of a film to be obtained with a support is easily further improved. The lower limit of εmax is, for example, 1 L·mol⁻¹·cm⁻¹ or more and may be 10 L·mol⁻¹·cm⁻¹ or more. In a case where two or more kinds of pigment derivatives are used, it is preferable that εmax of at least one thereof is 1000 L·mol⁻¹·cm⁻¹ or less, and it is more preferable that εmax of all kinds thereof is 1000 L·mol⁻¹·cm⁻¹ or less. In the present invention, the value of the molar light absorption coefficient of the pigment derivative is a value measured by a method described in Examples described later.

In the present invention, it is also preferable that the pigment derivative satisfies any one of the following spectral characteristics (a) to (d).

(a) maximum value of the molar light absorption coefficient in a wavelength range of more than 700 nm and 750 nm or less is preferably 3000 L·mol⁻¹·cm⁻¹ or less, more preferably 1000 L·mol⁻¹·cm⁻¹ or less, and still more preferably 100 L·mol⁻¹·cm⁻¹ or less.

(b) maximum value of the molar light absorption coefficient in a wavelength range of more than 750 nm and 800 nm or less is preferably 3000 L·mol⁻¹·cm⁻¹ or less, more preferably 1000 L·mol⁻¹·cm⁻¹ or less, and still more preferably 100 L·mol⁻¹·cm⁻¹ or less.

(c) maximum value of the molar light absorption coefficient in a wavelength range of more than 800 nm and 850 nm or less is preferably 3000 L·mol⁻¹·cm⁻¹ or less, more preferably 1000 L·mol⁻¹·cm⁻¹ or less, and still more preferably 100 L·mol⁻¹·cm⁻¹ or less.

(d) maximum value of the molar light absorption coefficient in a wavelength range of more than 850 nm and 900 nm or less is preferably 3000 L·mol⁻¹·cm⁻¹ or less, more preferably 1000 L·mol⁻¹·cm⁻¹ or less, and still more preferably 100 L·mol⁻¹·cm⁻¹ or less.

In the present invention, it is preferable that the pigment derivative includes an aromatic ring. The aromatic ring may be an aromatic hydrocarbon ring or an aromatic heterocyclic ring. In addition, the aromatic ring may be monocyclic or a fused ring. Specifically, the aromatic ring is preferably an aromatic ring selected from a benzene ring, a naphthalene ring, a fluorene ring, a perylene ring, an imidazole ring, a pyrazole ring, an oxazole ring, a thiazole ring, an imidazoline ring, a pyridine ring, a triazole ring, an imidazoline ring, a pyrazine ring, a pyrimidine ring, a pyridazine ring, a quinoline ring, an isoquinoline ring, a quinoxaline ring, a quinazoline ring, a benzimidazole ring, a benzopyrazole ring, a benzoxazole ring, a benzothiazole ring, a benzotriazole ring, an indole ring, an isoindole ring, a triazine ring, a pyrrole ring, a carbazole ring, a benzimidazolinone ring, a phthalimide ring, a phthalocyanine ring, an anthraquinone ring, a diketopyrrolopyrrole ring, an isoindolinone ring, an isoindoline ring, and a quinacridone ring; or a fused ring which includes these aromatic rings. The above-described fused ring may be an aromatic ring or a non-aromatic ring as a whole, but is preferably an aromatic ring.

In addition, the pigment derivative may have only one aromatic ring or fused ring, but for the reason that, as the number of aromatic rings increases, pigment adsorbability is improved and storage stability of the composition is easily improved by n-m interaction, it is preferable to have two or more of these rings.

The above-described aromatic ring or fused ring may further have a substituent. Examples of the substituent include the substituent T described later.

The pigment derivative preferably has a structure which easily interacts with the pigment included in the photosensitive composition or a structure similar to the pigment. According to this aspect, dispersibility of the pigment in the photosensitive composition can be enhanced, and storage stability of the photosensitive composition can be further enhanced. In addition, from the reason that the effects of the present invention are more easily obtained remarkably, the pigment derivative preferably has an aromatic heterocyclic ring, more preferably has a nitrogen-containing aromatic heterocyclic ring, and still more preferably has a triazine ring.

In the present invention, it is particularly preferable that the pigment derivative has a group represented by Formula (A1) including a triazine ring as the aromatic ring.

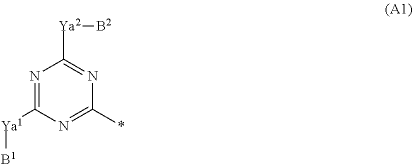

In the formula, * represents a bonding hand,

Ya¹ and Ya² each independently represent —N(Ra¹)— or —O—, where Ra¹ represents a hydrogen atom, an alkyl group, an alkenyl group, an alkynyl group, or an aryl group, and

B¹ and B² each independently represent a hydrogen atom or a substituent.

In Formula (A1), Ya¹ and Ya² each independently represent —N(Ra¹)— or —O—, and from the reason that the effects of the present invention are more easily obtained remarkably, —N(Ra¹)— is more preferable.

Ra¹ represents a hydrogen atom, an alkyl group, an alkenyl group, an alkynyl group, or an aryl group, and a hydrogen atom or an alkyl group is preferable and a hydrogen atom is more preferable.

The alkyl group represented by Ra¹ preferably has 1 to 20 carbon atoms, more preferably has 1 to 15 carbon atoms, and still more preferably has 1 to 8 carbon atoms. The alkyl group may be linear, branched, or cyclic, and is preferably linear or branched and more preferably linear. The alkyl group represented by Ra¹ may further have a substituent. Examples of the substituent include the substituent T described later.

The alkenyl group represented by Ra¹ preferably has 2 to 20 carbon atoms, more preferably has 2 to 12 carbon atoms, and still more preferably has 2 to 8 carbon atoms. The alkenyl group may be linear, branched, or cyclic, and is preferably linear or branched and more preferably linear. The alkenyl group represented by Ra¹ may further have a substituent. Examples of the substituent include the substituent T described later.

The alkynyl group represented by Ra¹ preferably has 2 to 40 carbon atoms, more preferably has 2 to 30 carbon atoms, and still more preferably has 2 to 25 carbon atoms. The alkynyl group may be linear, branched, or cyclic, and is preferably linear or branched and more preferably linear. The alkynyl group represented by Ra¹ may further have a substituent. Examples of the substituent include the substituent T described later.

The aryl group represented by Ra¹ preferably has 6 to 30 carbon atoms, more preferably has 6 to 20 carbon atoms, and still more preferably has 6 to 12 carbon atoms. The aryl group represented by Ra¹ may further have a substituent. Examples of the substituent include the substituent T described later.

In Formula (A1), B¹ and B² each independently represent a hydrogen atom or a substituent. Examples of the substituent include the substituent T described later, and an alkyl group, an aryl group, or a heterocyclic group is preferable, an aryl group or a heterocyclic group is more preferable, and an aryl group is still more preferable from the reason that pigment adsorbability is enhanced and storage stability of the composition is easily improved. In addition, from the reason that color unevenness can be more easily suppressed, at least one of B¹ or B² is also preferably a heterocyclic group. The heterocyclic group is preferably a nitrogen-containing heterocyclic group and more preferably a benzimidazolone group.

The alkyl group, aryl group, and heterocyclic group represented by B¹ and B² may further have a substituent. Examples of the further substituent include an alkyl group (preferably an alkyl group having 1 to 30 carbon atoms), a fluoroalkyl group (preferably a fluoroalkyl group having 1 to 30 carbon atoms), an alkenyl group (preferably an alkenyl group having 2 to 30 carbon atoms), an alkynyl group (preferably an alkynyl group having 2 to 30 carbon atoms), an aryl group (preferably an aryl group having 6 to 30 carbon atoms), an amino group (preferably an amino group having 0 to 30 carbon atoms), an alkoxy group (preferably an alkoxy group having 1 to 30 carbon atoms), an aryloxy group (preferably an aryloxy group having 6 to 30 carbon atoms), a heteroaryloxy group, an acyl group (preferably an acyl group having 1 to 30 carbon atoms), an alkoxycarbonyl group (preferably an alkoxycarbonyl group having 2 to 30 carbon atoms), an aryloxycarbonyl group (preferably an aryloxycarbonyl group having 7 to 30 carbon atoms), an acyloxy group (preferably an acyloxy group having 2 to 30 carbon atoms), an acylamino group (preferably an acylamino group having 2 to 30 carbon atoms), an alkoxycarbonylamino group (preferably an alkoxycarbonylamino group having 2 to 30 carbon atoms), an aryloxycarbonylamino group (preferably an aryloxycarbonylamino group having 7 to 30 carbon atoms), a sulfamoyl group (preferably a sulfamoyl group having 0 to 30 carbon atoms), a carbamoyl group (preferably a carbamoyl group having 1 to 30 carbon atoms), an alkylthio group (preferably an alkylthio group having 1 to 30 carbon atoms), an arylthio group (preferably an arylthio group having 6 to 30 carbon atoms), a heteroarylthio group (preferably a heteroarylthio group having 1 to 30 carbon atoms), an alkylsulfonyl group (preferably an alkylsulfonyl group having 1 to 30 carbon atoms), an arylsulfonyl group (preferably an arylsulfonyl group having 6 to 30 carbon atoms), a heteroarylsulfonyl group (preferably a heteroarylsulfonyl group having 1 to 30 carbon atoms), an alkylsulfinyl group (preferably an alkylsulfinyl group having 1 to 30 carbon atoms), an arylsulfinyl group (preferably an arylsulfinyl group having 6 to 30 carbon atoms), a heteroarylsulfinyl group (preferably a heteroarylsulfinyl group having 1 to 30 carbon atoms), a ureido group (preferably a ureido group having 1 to 30 carbon atoms), a phosphoric acid amide group (preferably a phosphoric acid amide group having 1 to 30 carbon atoms), a hydroxyl group, a carboxyl group, a sulfo group, a phosphoric acid group, a mercapto group, a halogen atom, a cyano group, an alkylsulfino group, an arylsulfino group, a hydrazino group, and an imino group. Among these, an alkyl group, a fluoroalkyl group, an alkoxy group, an amino group, a halogen atom, an alkenyl group, a hydroxyl group, an alkoxycarbonyl group, an acyloxy group, an acylamino group, or a nitro group is preferable.

It is also preferable that the alkyl group, aryl group, and heterocyclic group represented by B¹ and B² do not have the above-described further substituent.

(Substituent T)

Examples of a substituent T include a halogen atom, a cyano group, a nitro group, an alkyl group, an alkenyl group, an alkynyl group, an aryl group, a heterocyclic group, —ORt¹, —CORt¹, —COORt¹, —OCORt¹, —NRt¹Rt², —NHCORt¹, —CONRt¹Rt², —NHCONRt¹Rt², —NHCOORt¹, —SRt¹, —SO₂Rt¹, —SO₂ORt¹, —NHSO₂Rt¹, and —SO₂NRt¹Rt². Rt¹ and Rt² each independently represent a hydrogen atom, an alkyl group, an alkenyl group, an alkynyl group, an aryl group, or a heteroaryl group. Rt¹ and Rt² may be bonded to each other to form a ring.

Examples of the halogen atom include a fluorine atom, a chlorine atom, a bromine atom, and an iodine atom.

The alkyl group preferably has 1 to 30 carbon atoms, more preferably has 1 to 15 carbon atoms, and still more preferably has 1 to 8 carbon atoms. The alkyl group may be linear, branched, or cyclic, and is preferably linear or branched and more preferably linear.

The alkenyl group preferably has 2 to 30 carbon atoms, more preferably has 2 to 12 carbon atoms, and particularly preferably has 2 to 8 carbon atoms. The alkenyl group may be linear, branched, or cyclic, and is preferably linear or branched and more preferably linear.

The alkynyl group preferably has 2 to 30 carbon atoms and more preferably has 2 to 25 carbon atoms. The alkynyl group may be linear, branched, or cyclic, and is preferably linear or branched and more preferably linear.

The aryl group preferably has 6 to 30 carbon atoms, more preferably has 6 to 20 carbon atoms, and still more preferably has 6 to 12 carbon atoms.

The heterocyclic group may be monocyclic or a fused ring. The heterocyclic group is preferably monocyclic or a fused ring having 2 to 4 fused rings. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and more preferably 3 to 12.

The alkyl group, the alkenyl group, the alkynyl group, the aryl group, and the heterocyclic group may have a substituent or may be unsubstituted. Examples of the substituent include the substituent described in the substituent T.

With regard to the pigment derivative of the present invention, specific examples of the aromatic ring, further the group represented by Formula (A1) include groups having the following structures. In the following structural formulae, Me represents a methyl group.

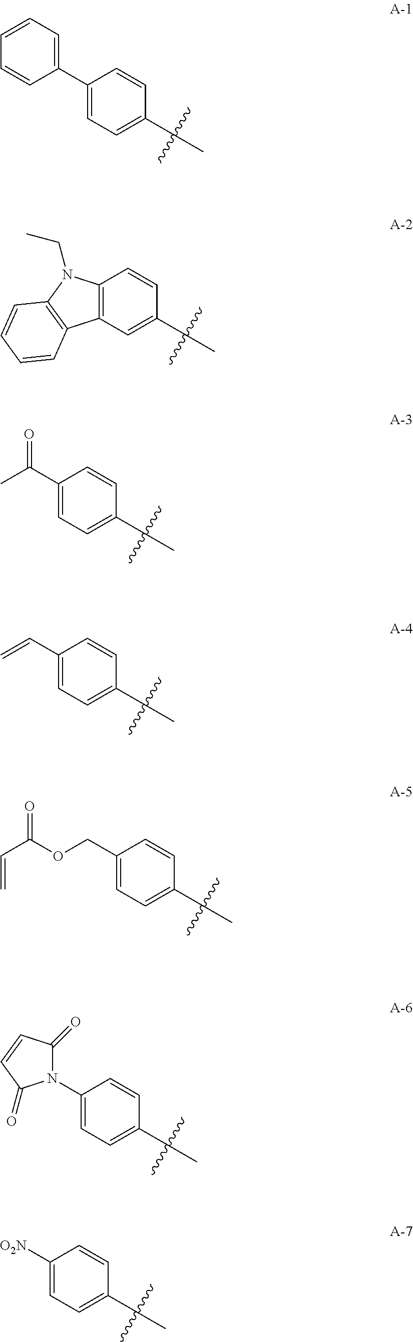

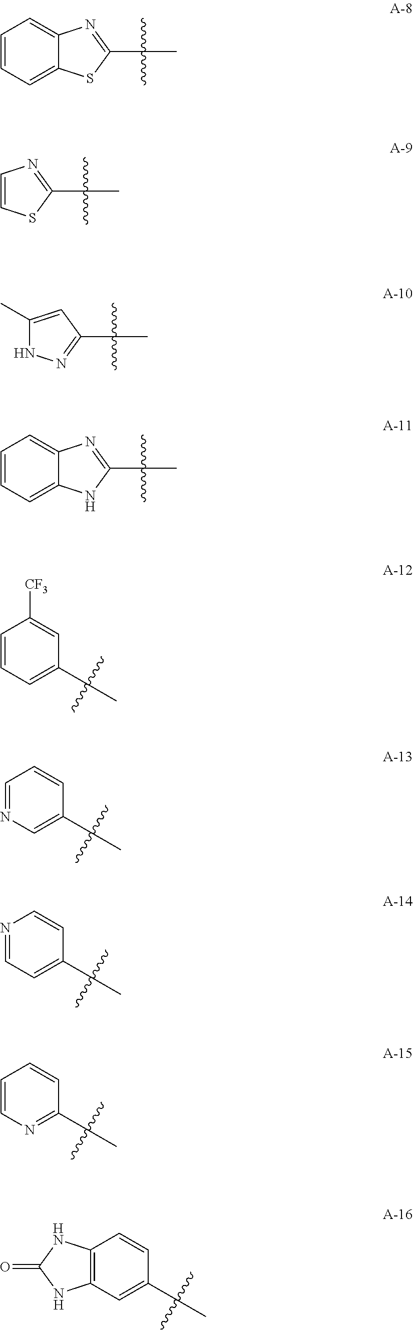

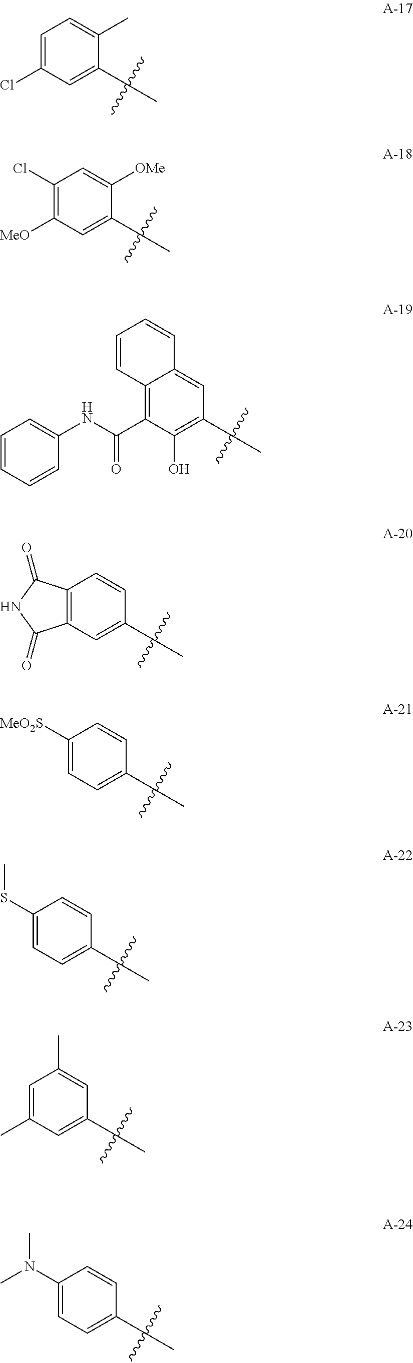

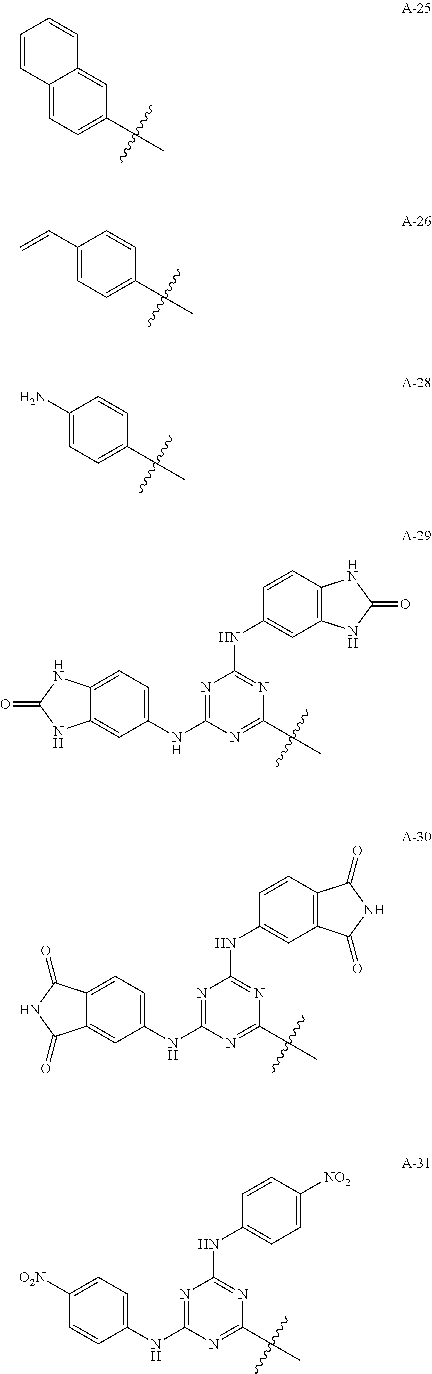

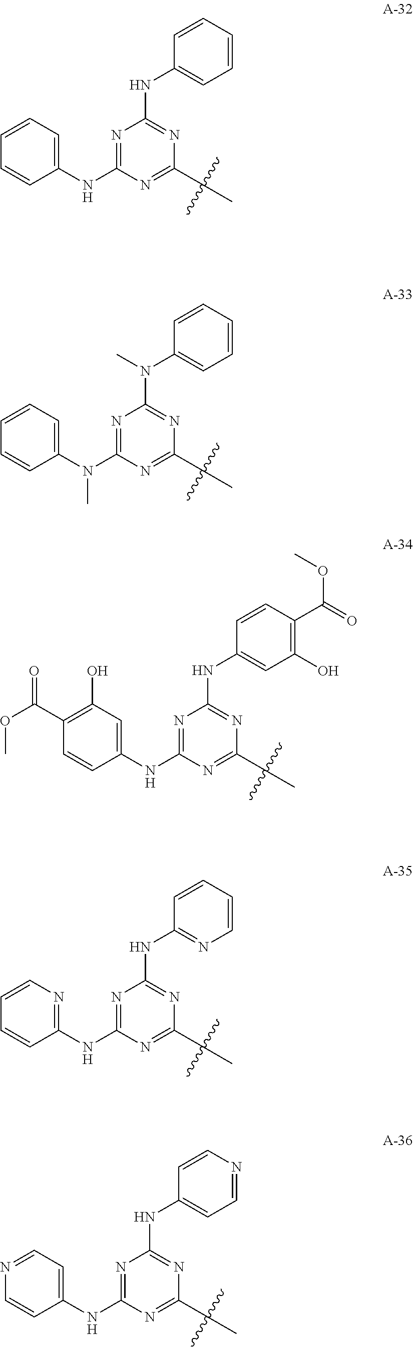 [SMILES: *c1nc(Nc2ccccc2)nc(Nc2ccccc2)n1 ; *c1nc(N(C)c2ccccc2)nc(N(C)c2ccccc2)n1 ; *c1nc(Nc2ccc(C(=O)OC)c(O)c2)nc(Nc2ccc(C(=O)OC)c(O)c2)n1 ; *c1nc(Nc2ccccn2)nc(Nc2ccccn2)n1 ; *c1nc(Nc2ccncc2)nc(Nc2ccncc2)n1]

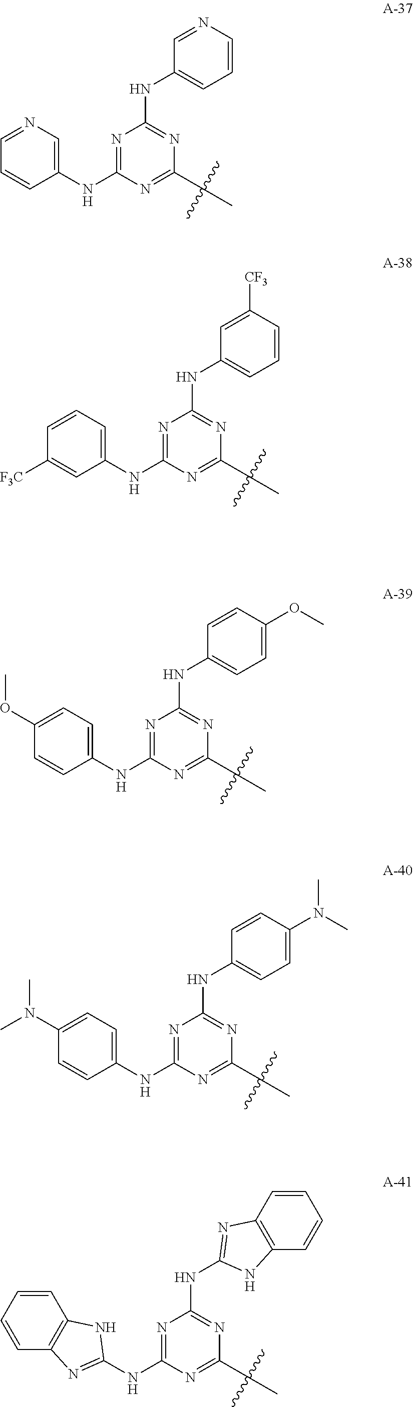

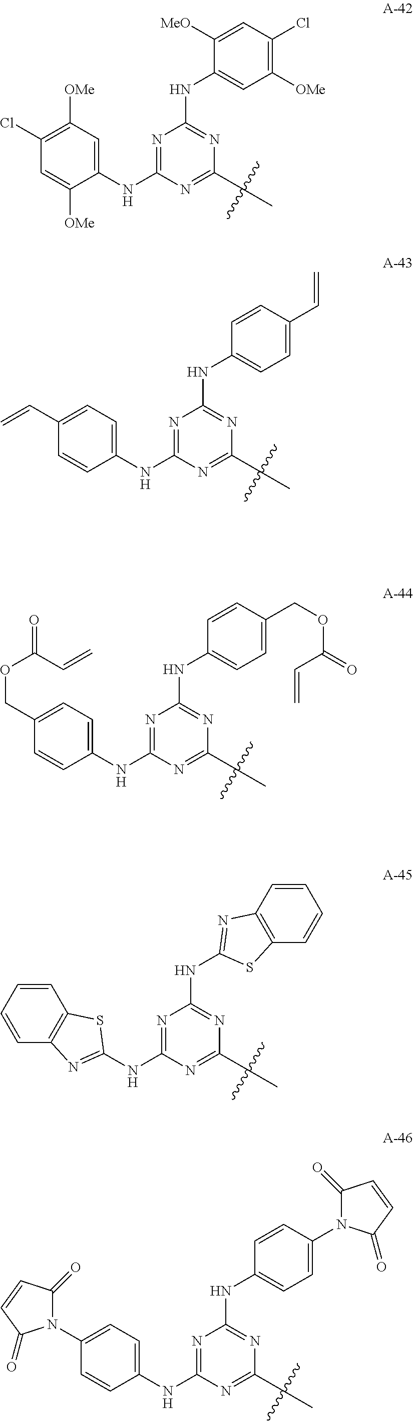 [SMILES: *c1nc(Nc2cc(OC)c(Cl)cc2OC)nc(Nc2cc(OC)c(Cl)cc2OC)n1 ; *c1nc(Nc2ccc(C=C)cc2)nc(Nc2ccc(C=C)cc2)n1 ; *c1nc(Nc2ccc(COC(=O)C=C)cc2)nc(Nc2ccc(COC(=O)C=C)cc2)n1 ; *c1nc(Nc2nc3ccccc3s2)nc(Nc2nc3ccccc3s2)n1 ; *c1nc(Nc2ccc(N3C(=O)C=CC3=O)cc2)nc(Nc2ccc(N3C(=O)C=CC3=O)cc2)n1]

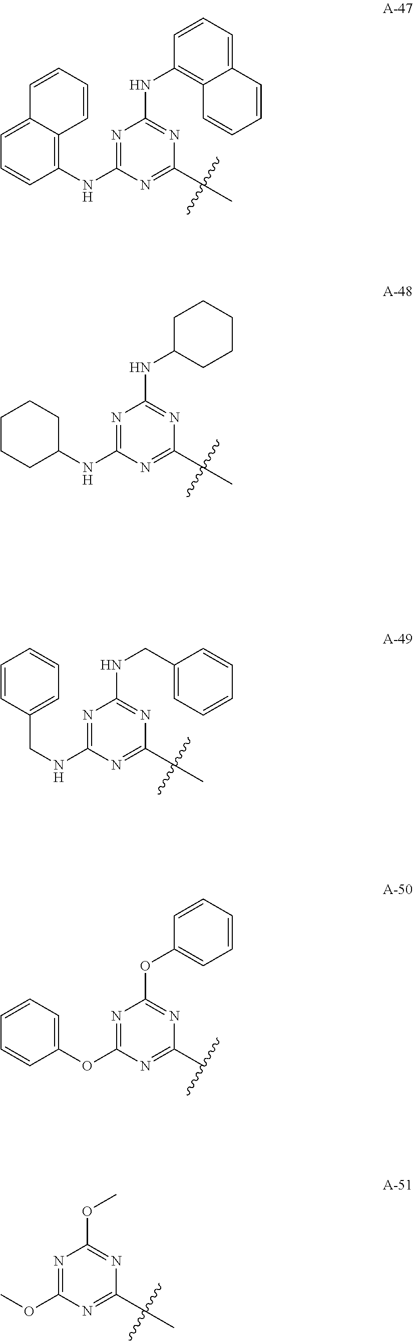 [SMILES: *c1nc(Nc2cccc3ccccc23)nc(Nc2cccc3ccccc23)n1 ; *c1nc(NC2CCCCC2)nc(NC2CCCCC2)n1 ; *c1nc(NCc2ccccc2)nc(NCc2ccccc2)n1 ; *c1nc(Oc2ccccc2)nc(Oc2ccccc2)n1 ; *c1nc(OC)nc(OC)n1]

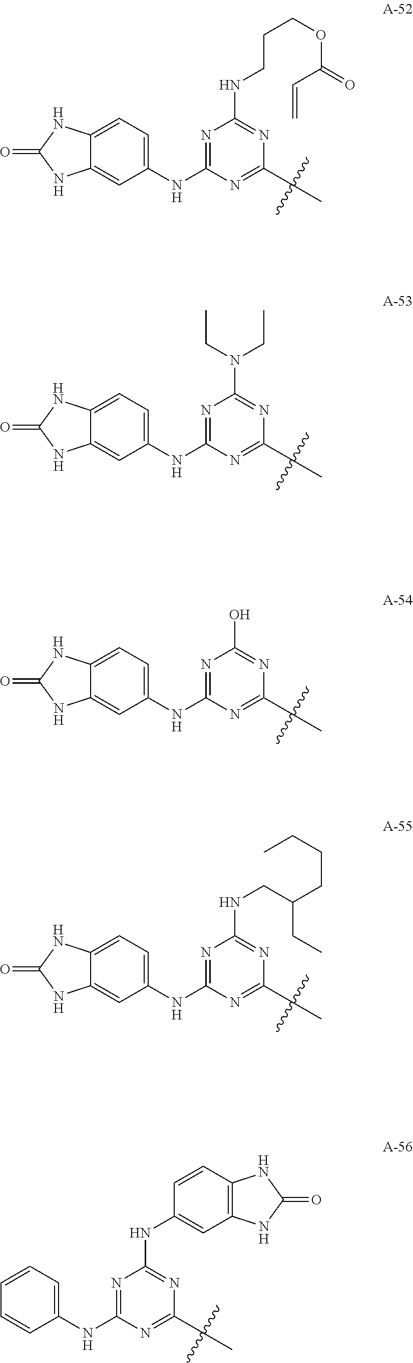 [SMILES: *c1nc(NCCCOC(=O)C=C)nc(Nc2ccc3[nH]c(=O)[nH]c3c2)n1 ; *c1nc(Nc2ccc3[nH]c(=O)[nH]c3c2)nc(N(CC)CC)n1 ; *c1nc(O)nc(Nc2ccc3[nH]c(=O)[nH]c3c2)n1 ; *c1nc(NCC(CC)CCCC)nc(Nc2ccc3[nH]c(=O)[nH]c3c2)n1 ; *c1nc(Nc2ccccc2)nc(Nc2ccc3[nH]c(=O)[nH]c3c2)n1]

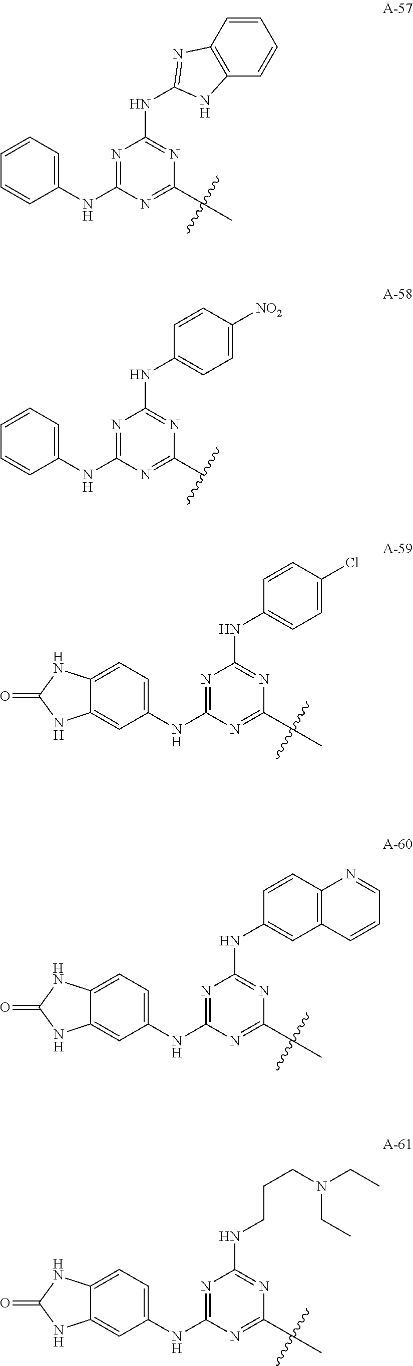 [SMILES: *c1nc(Nc2ccccc2)nc(Nc2nc3ccccc3[nH]2)n1 ; *c1nc(Nc2ccccc2)nc(Nc2ccc([N+](=O)[O-])cc2)n1 ; *c1nc(Nc2ccc(Cl)cc2)nc(Nc2ccc3[nH]c(=O)[nH]c3c2)n1 ; *c1nc(Nc2ccc3ncccc3c2)nc(Nc2ccc3[nH]c(=O)[nH]c3c2)n1 ; *c1nc(NCCCN(CC)CC)nc(Nc2ccc3[nH]c(=O)[nH]c3c2)n1]

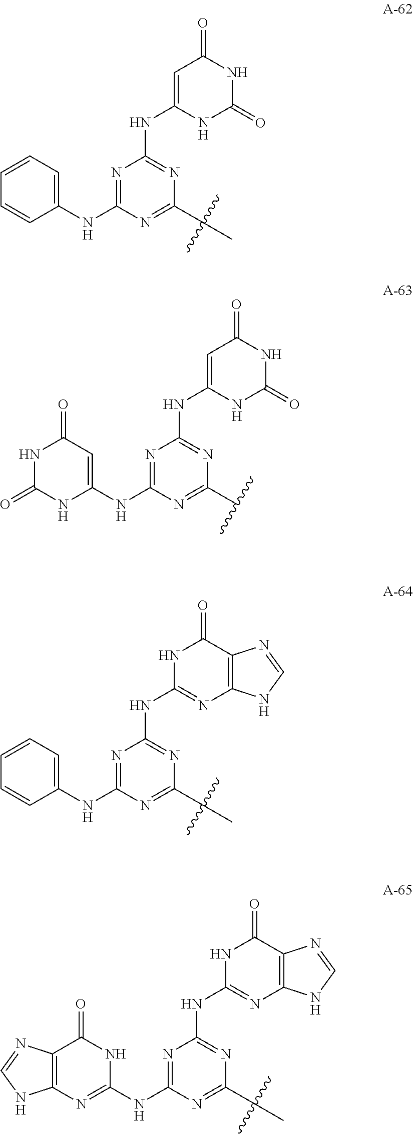 [SMILES: *c1nc(Nc2ccccc2)nc(Nc2cc(=O)[nH]c(=O)[nH]2)n1 ; *c1nc(Nc2cc(=O)[nH]c(=O)[nH]2)nc(Nc2cc(=O)[nH]c(=O)[nH]2)n1 ; *c1nc(Nc2ccccc2)nc(Nc2nc3[nH]cnc3c(=O)[nH]2)n1 ; *c1nc(Nc2nc3[nH]cnc3c(=O)[nH]2)nc(Nc2nc3[nH]cnc3c(=O)[nH]2)n1]

In the present invention, the pigment derivative preferably includes at least one group selected from an acid group and a basic group.

The acid group is preferably at least one selected from a carboxyl group, a sulfo group, a phosphoric acid group, or salts thereof, and more preferably at least one selected from a carboxyl group, a sulfo group, or salts thereof. Examples of an atom or atomic group constituting the salts include alkali metal ions (Li⁺, Na⁺, K⁺, and the like), alkaline earth metal ions (Ca²⁺, Mg²⁺, and the like), an ammonium ion, an imidazolium ion, a pyridinium ion, and a phosphonium ion.

The basic group is preferably at least one selected from an amino group, a pyridyl group, salts thereof, a salt of an ammonium group, or a phthalimidomethyl group, more preferably at least one selected from an amino group, a salt of an amino group, or a salt of an ammonium group, and more preferably an amino group or a salt of an amino group. Examples of the amino group include —NH₂, a dialkylamino group, an alkylarylamino group, a diarylamino group, and a cyclic amino group. The dialkylamino group, alkylarylamino group, diarylamino group, and cyclic amino group may further have a substituent. Examples of the substituent include the substituent described in the substituent T. Examples of an atom or atomic group constituting the salts include a hydroxide ion, a halogen ion, a carboxylate ion, a sulfonate ion, and a phenoxide ion.

In the present invention, the pigment derivative having an aromatic ring is preferably a compound (hereinafter, also referred to as a compound (1)) represented by Formula (1).

A¹-L¹-Z¹ (1)

In Formula (1), A¹ represents a group including an aromatic ring,

L¹ represents a single bond or a divalent linking group, and

Z¹ represents the acid group or the basic group.

Furthermore, from the reason that color unevenness can be more easily suppressed, Z¹ is preferably the basic group, and more preferably a group represented by Formula (Z1).

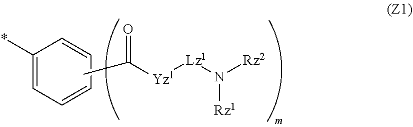

In the formula, * represents a bonding hand,

Yz¹ represents —N(Ry¹)— or —O—, where Ry¹ represents a hydrogen atom, an alkyl group, an alkenyl group, an alkynyl group, or an aryl group,

Lz¹ represents a divalent linking group,

Rz¹ and Rz² each independently represent a hydrogen atom, an alkyl group, an alkenyl group, an alkynyl group, or an aryl group, where Rz¹ and Rz² may be bonded to each other through a divalent group to form a ring, and m represents an integer of 1 to 5.

In Formula (1), the aromatic ring included in A¹ is the same as the above-mentioned aromatic ring preferably included in the pigment derivative. A¹ is preferably the group represented by Formula (A1). Specific examples of A¹ are as shown in the specific examples of the group represented by Formula (A1).

In Formula (1), L¹ represents a single bond or a divalent linking group, and a divalent linking group is preferable. Examples of the divalent linking group represented by L¹ include an alkylene group, an arylene group, a heterocyclic group, —O—, —N(R^{L1})—, —NHCO—, —CONH—, —OCO—, —COO—, —CO—, —SO₂NH—, —SO₂—, and a group formed by a combination of these groups. The alkylene group preferably has 1 to 30 carbon atoms, more preferably has 1 to 15 carbon atoms, still more preferably has 1 to 8 carbon atoms, and particularly preferably has 1 to 5 carbon atoms. The alkylene group may be linear, branched, or cyclic, and is preferably linear or branched and particularly preferably linear. The arylene group preferably has 6 to 30 carbon atoms and more preferably has 6 to 15 carbon atoms. The arylene group is preferably a phenylene group. R^{L1} represents a hydrogen atom, an alkyl group, an alkenyl group, an alkynyl group, or an aryl group, and a hydrogen atom or an alkyl group is preferable and a hydrogen atom is more preferable. The preferred ranges of the alkyl group, alkenyl group, alkynyl group, and aryl group represented by R^{L1} are the same as the ranges described as the preferred ranges of the alkyl group, alkenyl group, alkynyl group, and aryl group of Ra¹.

The divalent linking group represented by L¹ is preferably a group represented by Formula (L1).

-L^{1A}-L^{1B}-L^{1C}- (L1)

In the formula, L^{1A} and L^{1C} each independently represent —O—, —N(R^{L1})—, —NHCO—, —CONH—, —OCO—, —COO—, —CO—, —SO₂NH—, or —SO₂—, and L^{1B} represents a single bond or a divalent linking group.

Examples of the divalent linking group represented by L^{1B} include an alkylene group, an arylene group, a group in which an alkylene group and an arylene group are bonded to each other through a single bond, —O—, —N(R^{L1})—, —NHCO—, —CONH—, —OCO—, —COO—, —CO—, —SO₂NH—, —SO₂—, or a group formed by a combination of these groups, and a group in which alkylene groups or arylene groups are bonded to each other through —O—, —N(R^{L1})—, —NHCO—, —CONH—, —OCO—, —COO—, —CO—, —SO₂NH—, —SO₂—, or a group formed by a combination of these groups.

Specific examples of L¹ include groups having the following structures.

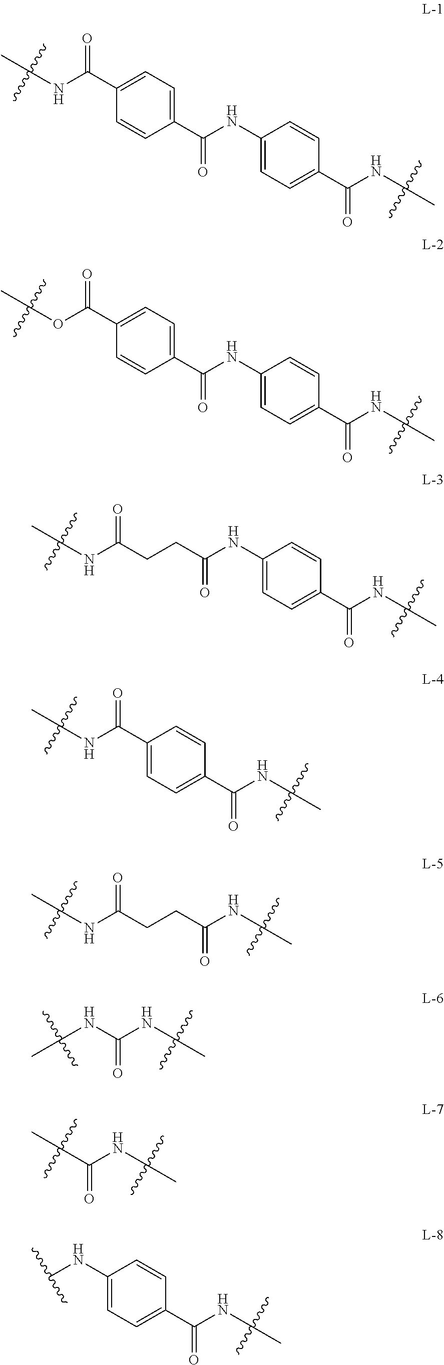

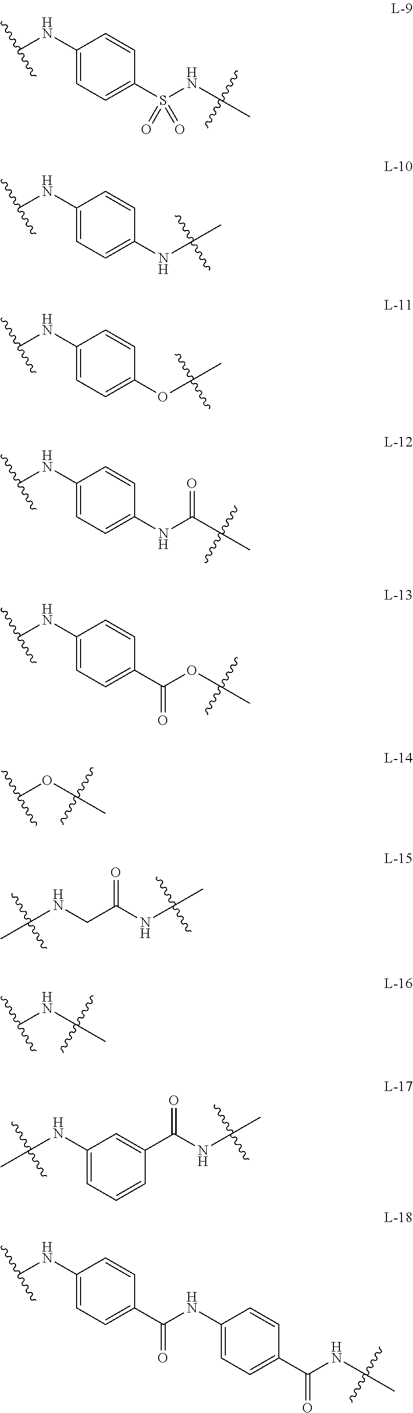

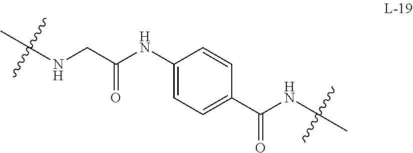 [SMILES: *NCC(=O)Nc1ccc(C(=O)N*)cc1]

In a case where Z¹ in Formula (1) is an acid group, the acid group is preferably at least one selected from a carboxyl group, a sulfo group, a phosphoric acid group, or salts thereof, and more preferably at least one selected from a carboxyl group, a sulfo group, or salts thereof. Examples of an atom or atomic group constituting the salts include alkali metal ions (Li⁺, Na⁺, K⁺, and the like), alkaline earth metal ions (Ca²⁺, Mg²⁺, and the like), an ammonium ion, an imidazolium ion, a pyridinium ion, and a phosphonium ion.

In a case where Z¹ in Formula (1) is a basic group, as described above, Z¹ is preferably a group represented by Formula (Z1).

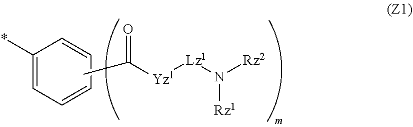

In the formula, * represents a bonding hand,

Yz¹ represents —N(Ry¹)— or —O—, where Ry¹ represents a hydrogen atom, an alkyl group, an alkenyl group, an alkynyl group, or an aryl group,

Lz¹ represents a divalent linking group,

Rz¹ and Rz² each independently represent a hydrogen atom, an alkyl group, an alkenyl group, an alkynyl group, or an aryl group, where Rz¹ and Rz² may be bonded to each other through a divalent group to form a ring, and m represents an integer of 1 to 5.

In Formula (Z1), Yz¹ represents —N(Ry¹)— or —O—, and from the reason that durability is easily improved, —N(Ry¹)— is preferable.

Ry¹ represents a hydrogen atom, an alkyl group, an alkenyl group, an alkynyl group, or an aryl group, and a hydrogen atom or an alkyl group is preferable and a hydrogen atom is more preferable. The preferred ranges of the alkyl group, alkenyl group, alkynyl group, and aryl group represented by Ry¹ are the same as the ranges described as the preferred ranges of the alkyl group, alkenyl group, alkynyl group, and aryl group of Ra¹.

In Formula (Z1), examples of the divalent linking group represented by Lz¹ include an alkylene group, an arylene group, a heterocyclic group, —O—, —N(R^{L1})—, —NHCO—, —CONH—, —OCO—, —COO—, —CO—, —SO₂NH—, —SO₂—, and a group formed by a combination of these groups, and an alkylene group is preferable. The alkylene group preferably has 1 to 30 carbon atoms, more preferably has 1 to 15 carbon atoms, still more preferably has 1 to 8 carbon atoms, and particularly preferably has 1 to 5 carbon atoms. The alkylene group may be linear, branched, or cyclic, and is preferably linear or branched and particularly preferably linear.

In Formula (Z1), Rz¹ and Rz² each independently represent a hydrogen atom, an alkyl group, an alkenyl group, an alkynyl group, or an aryl group, and an alkyl group or an aryl group is preferable and an alkyl group is more preferable. The alkyl group preferably has 1 to 10 carbon atoms, more preferably has 1 to 5 carbon atoms, still more preferably has 1 to 3 carbon atoms, and particularly preferably has 1 or 2 carbon atoms. The alkyl group may be linear, branched, or cyclic, and is preferably linear or branched and more preferably linear. The alkenyl group preferably has 2 to 10 carbon atoms, more preferably has 2 to 8 carbon atoms, and particularly preferably has 2 to 5 carbon atoms. The alkenyl group may be linear, branched, or cyclic, and is preferably linear or branched and more preferably linear. The alkynyl group preferably has 2 to 10 carbon atoms, more preferably has 2 to 8 carbon atoms, and particularly preferably has 2 to 5 carbon atoms. The alkynyl group may be linear, branched, or cyclic, and is preferably linear or branched and more preferably linear. The aryl group preferably has 6 to 30 carbon atoms, more preferably has 6 to 20 carbon atoms, and still more preferably has 6 to 12 carbon atoms.

In Formula (Z1), Rz¹ and Rz² may be bonded to each other through a divalent group to form a ring. Examples of the divalent group include —CH₂—, —O—, and —SO₂—. Specific examples of the ring formed by bonding Rz¹ and Rz² to each other through the divalent group include the following.

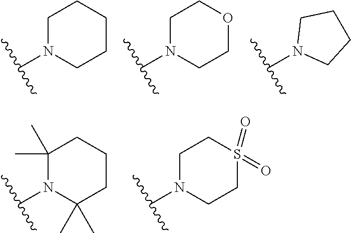

In Formula (Z1), m represents an integer of 1 to 5, and is preferably 1 to 4, more preferably 1 to 3, still more preferably 2 or 3, and particularly preferably 2.

In Formula (1), Z¹ is preferably a group represented by Formula (Z2).

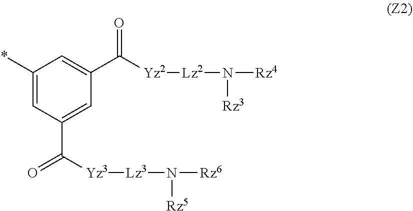

In the formula, * represents a bonding hand,

Yz² and Yz³ each independently represent —N(Ry²)— or —O—, where Ry² represents a hydrogen atom, an alkyl group, an alkenyl group, an alkynyl group, or an aryl group,

Lz² and Lz³ each independently represent a divalent linking group, and

Rz³ to Rz⁶ each independently represent a hydrogen atom, an alkyl group, an alkenyl group, an alkynyl group, or an aryl group, and

Rz³ and Rz⁴, and Rz⁵ and Rz⁶ may be respectively bonded to each other through a divalent group to form a ring.

Yz² and Yz³ in Formula (Z2) have the same meanings as Yz¹ in Formula (Z1), and the preferred ranges are also the same. Ry² represents a hydrogen atom, an alkyl group, an alkenyl group, an alkynyl group, or an aryl group, and a hydrogen atom or an alkyl group is preferable and a hydrogen atom is more preferable. Ry^{e} represents a hydrogen atom, an alkyl group, an alkenyl group, an alkynyl group, or an aryl group, and a hydrogen atom or an alkyl group is preferable and a hydrogen atom is more preferable.

Lz² and Lz³ in Formula (Z2) have the same meanings as Lz¹ in Formula (Z1), and the preferred ranges are also the same. Rz³ to Rz⁶ in Formula (Z2) have the same meanings as Rz¹ and Rz² in Formula (Z1), and the preferred ranges are also the same.

Specific examples of Z¹ include groups having the following structures. In the following structural formulae, Ph represents a phenyl group.

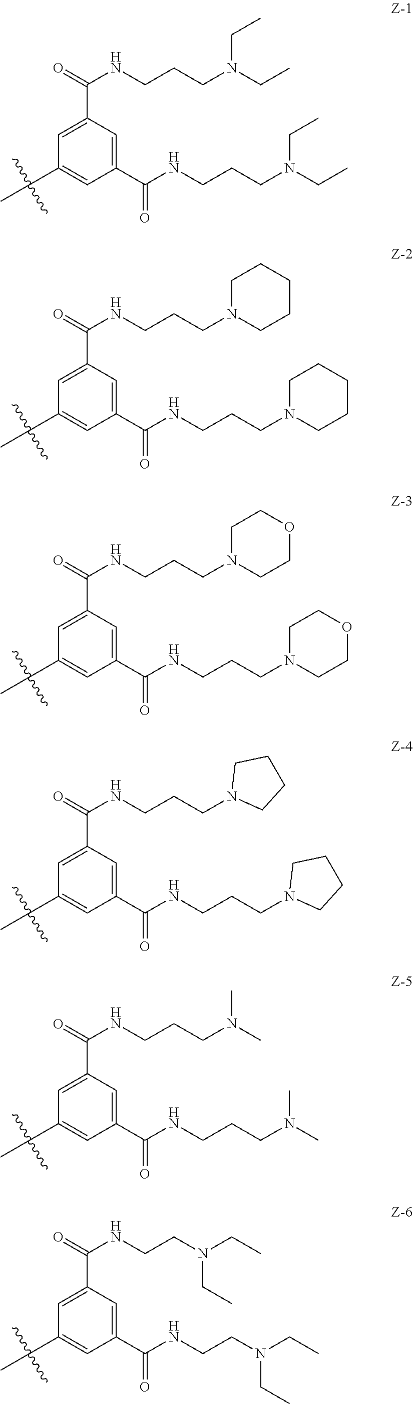 [SMILES: *c1cc(C(=O)NCCCN(CC)CC)cc(C(=O)NCCCN(CC)CC)c1 ; *c1cc(C(=O)NCCCN2CCCCC2)cc(C(=O)NCCCN2CCCCC2)c1 ; *c1cc(C(=O)NCCCN2CCOCC2)cc(C(=O)NCCCN2CCOCC2)c1 ; *c1cc(C(=O)NCCCN2CCCC2)cc(C(=O)NCCCN2CCCC2)c1 ; *c1cc(C(=O)NCCCN(C)C)cc(C(=O)NCCCN(C)C)c1 ; *c1cc(C(=O)NCCN(CC)CC)cc(C(=O)NCCN(CC)CC)c1]

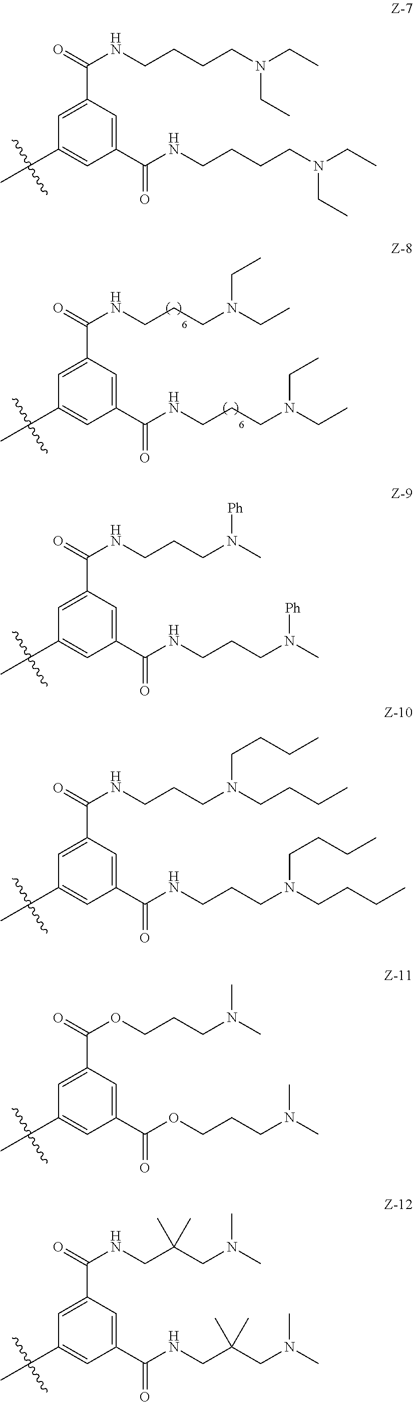 [SMILES: *c1cc(C(=O)NCCCCN(CC)CC)cc(C(=O)NCCCCN(CC)CC)c1 ; *c1cc(C(=O)NCCCN(CC)CC)cc(C(=O)NCCCN(CC)CC)c1 ; *c1cc(C(=O)NCCCN(C)c2ccccc2)cc(C(=O)NCCCN(C)c2ccccc2)c1 ; *c1cc(C(=O)NCCCN(CCCC)CCCC)cc(C(=O)NCCCN(CCCC)CCCC)c1 ; *c1cc(C(=O)OCCCN(C)C)cc(C(=O)OCCCN(C)C)c1 ; *c1cc(C(=O)NCC(C)(C)CN(C)C)cc(C(=O)NCC(C)(C)CN(C)C)c1]

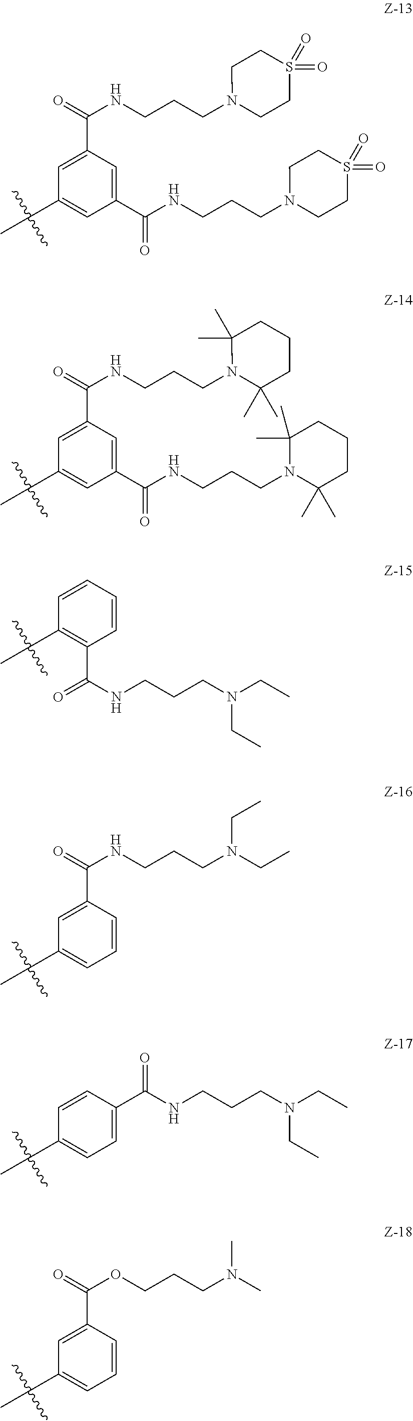 [SMILES: *c1cc(C(=O)NCCCN2CCS(=O)(=O)CC2)cc(C(=O)NCCCN2CCS(=O)(=O)CC2)c1 ; *c1cc(C(=O)NCCCN2C(C)(C)CCCC2(C)C)cc(C(=O)NCCCN2C(C)(C)CCCC2(C)C)c1 ; *c1ccccc1C(=O)NCCCN(CC)CC ; *c1cccc(C(=O)NCCCN(CC)CC)c1 ; *c1ccc(C(=O)NCCCN(CC)CC)cc1 ; *c1cccc(C(=O)OCCCN(C)C)c1]

In the present invention, the compound (1) used in the photosensitive composition is preferably a compound represented by Formula (2). By using such a compound, the effects of the present invention are more remarkably obtained.

A¹-X¹-L²-Z¹ (2)

In Formula (2), A¹ represents a group including an aromatic ring,

X¹ and X² each independently represent a single bond, —O—, —N(R¹)—, —NHCO—, —CONH—, —OCO—, —COO—, —CO—, —SO₂NH—, or —SO₂—, where R¹ represents a hydrogen atom, an alkyl group, an alkenyl group, an alkynyl group, or an aryl group,

L² represents a single bond or a divalent linking group, and

Z¹ represents the group represented by Formula (Z1).

A¹ and Z¹ in Formula (2) have the same meanings as A¹ and Z¹ in Formula (1), and the preferred ranges are also the same.

X¹ and X² in Formula (2) each independently represent a single bond, —O—, —N(R¹)—, —NHCO—, —CONH—, —OCO—, —COO—, —CO—, —SO₂NH—, or —SO₂—, —O—, —N(R¹)—, —NHCO—, —CONH—, —OCO—, —COO—, —CO—, —SO₂NH—, or —SO₂— is preferable. R¹ represents a hydrogen atom, an alkyl group, an alkenyl group, an alkynyl group, or an aryl group, and a hydrogen atom or an alkyl group is preferable and a hydrogen atom is more preferable. The preferred ranges of the alkyl group, alkenyl group, alkynyl group, and aryl group represented by R¹ are the same as the ranges described as the preferred ranges of the alkyl group, alkenyl group, alkynyl group, and aryl group of Ra¹.

L² in Formula (2) represents a single bond or a divalent linking group. Examples of the divalent linking group represented by L² include an alkylene group, an arylene group, a group in which an alkylene group and an arylene group are bonded to each other through a single bond, —O—, —N(R²)—, —NHCO—, —CONH—, —OCO—, —COO—, —CO—, —SO₂NH—, —SO₂—, or a group formed by a combination of these groups, and a group in which alkylene groups or arylene groups are bonded to each other through —O—, —N(R²)—, —NHCO—, —CONH—, —OCO—, —COO—, —CO—, —SO₂NH—, —SO₂—, or a group formed by a combination of these groups. R² represents a hydrogen atom, an alkyl group, an alkenyl group, an alkynyl group, or an aryl group, and a hydrogen atom or an alkyl group is preferable and a hydrogen atom is more preferable. The preferred ranges of the alkyl group, alkenyl group, alkynyl group, and aryl group represented by R² are the same as the ranges described as the preferred ranges of the alkyl group, alkenyl group, alkynyl group, and aryl group of Ra¹.

Specific examples of the compound (1) include the following. In the following table, the symbols described in the columns of structure of A¹, structure of L¹, and structure of Z¹ are the structures exemplified in the specific examples of A¹ (that is, specific examples of the group represented by Formula (A1)), the specific examples of L¹, and the specific examples of Z¹ respectively.

TABLE 1
A¹-L¹-Z¹

| Compound | Structure of | Structure of | Structure of |
|---|---|---|---|
| No. | A¹ | L¹ | Z¹ |
| C-1 | A-1 | L-1 | Z-1 |
| C-2 | A-2 | L-1 | Z-1 |
| C-3 | A-3 | L-1 | Z-1 |
| C-4 | A-4 | L-1 | Z-1 |
| C-5 | A-5 | L-1 | Z-1 |
| C-6 | A-6 | L-1 | Z-1 |
| C-7 | A-7 | L-1 | Z-1 |
| C-8 | A-8 | L-1 | Z-1 |
| C-9 | A-9 | L-1 | Z-1 |
| C-10 | A-10 | L-1 | Z-1 |
| C-11 | A-11 | L-1 | Z-1 |
| C-12 | A-12 | L-1 | Z-1 |
| C-13 | A-13 | L-1 | Z-1 |
| C-14 | A-14 | L-1 | Z-1 |
| C-15 | A-15 | L-1 | Z-1 |
| C-16 | A-16 | L-1 | Z-1 |
| C-17 | A-17 | L-1 | Z-1 |
| C-18 | A-18 | L-1 | Z-1 |
| C-19 | A-19 | L-1 | Z-1 |
| C-20 | A-20 | L-1 | Z-1 |
| C-21 | A-21 | L-1 | Z-1 |
| C-22 | A-22 | L-1 | Z-1 |
| C-23 | A-23 | L-1 | Z-1 |
| C-24 | A-24 | L-1 | Z-1 |
| C-25 | A-25 | L-2 | Z-1 |
| C-26 | A-26 | L-2 | Z-1 |
| C-27 | A-16 | L-3 | Z-1 |
| C-28 | A-16 | L-4 | Z-1 |
| C-29 | A-16 | L-5 | Z-1 |
| C-30 | A-16 | L-6 | Z-1 |
| C-31 | A-7 | L-7 | Z-1 |
| C-32 | A-28 | L-7 | Z-1 |
| C-33 | A-29 | L-8 | Z-1 |
| C-34 | A-30 | L-8 | Z-1 |
| C-35 | A-31 | L-8 | Z-1 |
| C-36 | A-32 | L-8 | Z-1 |
| C-37 | A-33 | L-8 | Z-1 |
| C-38 | A-34 | L-8 | Z-1 |
| C-39 | A-35 | L-8 | Z-1 |
| C-40 | A-36 | L-8 | Z-1 |
| C-41 | A-37 | L-8 | Z-1 |
| C-42 | A-38 | L-8 | Z-1 |
| C-43 | A-39 | L-8 | Z-1 |
| C-44 | A-40 | L-8 | Z-1 |
| C-45 | A-41 | L-8 | Z-1 |
| C-46 | A-42 | L-8 | Z-1 |
| C-47 | A-43 | L-8 | Z-1 |
| C-48 | A-44 | L-8 | Z-1 |
| C-49 | A-45 | L-8 | Z-1 |
| C-50 | A-46 | L-8 | Z-1 |
| C-51 | A-47 | L-8 | Z-1 |
| C-52 | A-48 | L-8 | Z-1 |
| C-53 | A-49 | L-8 | Z-1 |
| C-54 | A-50 | L-8 | Z-1 |
| C-55 | A-51 | L-8 | Z-1 |
| C-56 | A-52 | L-8 | Z-1 |
| C-57 | A-53 | L-8 | Z-1 |
| C-58 | A-54 | L-8 | Z-1 |
| C-59 | A-55 | L-8 | Z-1 |
| C-60 | A-56 | L-8 | Z-1 |
| C-61 | A-57 | L-8 | Z-1 |
| C-62 | A-58 | L-8 | Z-1 |
| C-63 | A-32 | L-9 | Z-1 |
| C-64 | A-32 | L-10 | Z-1 |
| C-65 | A-32 | L-11 | Z-1 |
| C-66 | A-32 | L-12 | Z-1 |
| C-67 | A-32 | L-13 | Z-1 |
| C-68 | A-32 | L-14 | Z-1 |
| C-69 | A-32 | L-15 | Z-1 |
| C-70 | A-32 | L-16 | Z-1 |
| C-71 | A-32 | L-17 | Z-1 |
| C-72 | A-32 | L-18 | Z-1 |
| C-73 | A-32 | L-19 | Z-1 |
| C-74 | A-32 | L-8 | Z-2 |
| C-75 | A-32 | L-8 | Z-3 |
| C-76 | A-32 | L-8 | Z-4 |
| C-77 | A-32 | L-8 | Z-5 |
| C-78 | A-32 | L-8 | Z-6 |
| C-79 | A-32 | L-8 | Z-7 |
| C-80 | A-32 | L-8 | Z-8 |
| C-81 | A-32 | L-8 | Z-9 |
| C-82 | A-32 | L-8 | Z-10 |
| C-83 | A-32 | L-8 | Z-11 |
| C-84 | A-32 | L-8 | Z-12 |
| C-85 | A-32 | L-8 | Z-13 |
| C-86 | A-32 | L-8 | Z-14 |
| C-87 | A-32 | L-8 | Z-15 |
| C-88 | A-32 | L-8 | Z-16 |
| C-89 | A-32 | L-8 | Z-17 |
| C-90 | A-32 | L-8 | Z-18 |
| C-91 | A-16 | L-1 | Z-17 |
| C-92 | A-15 | L-1 | Z-17 |
| C-93 | A-59 | L-8 | Z-1 |
| C-94 | A-60 | L-8 | Z-1 |
| C-95 | A-61 | L-8 | Z-1 |
| C-96 | A-62 | L-8 | Z-1 |
| C-97 | A-63 | L-8 | Z-1 |
| C-98 | A-64 | L-8 | Z-1 |
| C-99 | A-65 | L-8 | Z-1 |

The content of the pigment derivative in the total solid content of the photosensitive composition is preferably 0.3% to 20% by mass. The lower limit is more preferably 0.6% by mass or more and still more preferably 0.9% by mass or more. The upper limit is more preferably 15% by mass or less, still more preferably 12.5% by mass or less, and particularly preferably 10% by mass or less.

In addition, the mass ratio of the content of the pigment derivative in the total solid content of the composition and the content of the pigment in the total solid content of the composition is preferably 3:97 to 20:80. The upper limit of the mass ratio is more preferably 15:85 or less, and still more preferably 13:87 or less. The lower limit of the mass ratio is more preferably 5:95 or more, and still more preferably 8:92 or more. In other words, the content of the pigment derivative is preferably 3 to 25 parts by mass with respect to 100 parts by mass of the pigment. The upper limit is more preferably 17.6 parts by mass or less and still more preferably 14.9 parts by mass or less. The lower limit is more preferably 5.3 parts by mass or more and still more preferably 8.7 parts by mass or more.

In addition, the total content (pigment concentration) of the pigment and the pigment derivative in the total solid content of the composition is preferably 25% to 65% by mass. The lower limit is more preferably 30% by mass or more, still more preferably 35% by mass or more, and particularly preferably 40% by mass or more. The upper limit is more preferably 63% by mass or less and still more preferably 60% by mass or less.

The content of a certain solid component in the total solid content of the composition is substantially equal to the content of the solid component in pixels formed by curing the composition.

The pigment derivative may be used singly or in combination of two or more kinds thereof. In a case where two or more kinds thereof are used in combination, the total amount thereof is preferably within the above-described range.

In the present invention, the photosensitive composition may contain the pigment derivative in which the maximum value (εmax) of a molar light absorption coefficient in a wavelength range of 400 to 700 nm is 3000 L·mol⁻¹·cm⁻¹ or less, and a pigment derivative in which max is more than 3000 L·mol⁻¹·cm⁻¹ in combination. In a case of using these pigment derivatives in combination, the content of the pigment derivative in which εmax is 3000 L·mol⁻¹·cm⁻¹ or less is preferably 40% by mass or more, more preferably 60% by mass or more, and still more preferably 80% by mass with respect to all the pigment derivatives.

<<Polymerizable Compound>>

The pixel in the structural body according to the embodiment of the present invention preferably contains a polymerizable compound. As the polymerizable compound, a known compound which is cross-linkable by a radical, an acid, or heat can be used. In the present invention, the polymerizable compound is preferably, for example, a compound having an ethylenically unsaturated bonding group. Examples of the ethylenically unsaturated bonding group include a vinyl group, a (meth)allyl group, and a (meth)acryloyl group. The polymerizable compound used in the present invention is preferably a radically polymerizable compound.

Any chemical forms of a monomer, a prepolymer, an oligomer, or the like may be used as the polymerizable compound, but a monomer is preferable. The molecular weight of the polymerizable compound is preferably 100 to 3000. The upper limit is more preferably 2000 or less and still more preferably 1500 or less. The lower limit is more preferably 150 or more and still more preferably 250 or more.

The polymerizable compound is preferably a compound including 3 or more ethylenically unsaturated bonding groups, more preferably a compound including 3 to 15 ethylenically unsaturated bonding groups, and still more preferably a compound having 3 to 6 ethylenically unsaturated bonding groups. In addition, the polymerizable compound is preferably a trifunctional to pentadecafunctional (meth)acrylate compound and more preferably a trifunctional to hexafunctional (meth)acrylate compound. Specific examples of the polymerizable compound include the compounds described in paragraph Nos. 0095 to 0108 of JP2009-288705A, paragraph No. 0227 of JP2013-029760A, paragraph Nos. 0254 to 0257 of JP2008-292970A, paragraph Nos. 0034 to 0038 of JP2013-253224A, paragraph No. 0477 of JP2012-208494A, JP2017-048367A, JP6057891B, and JP6031807B, the contents of which are incorporated herein by reference.

As the polymerizable compound, dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which these (meth)acryloyl groups are bonded through an ethylene glycol and/or a propylene glycol residue (for example, SR454 and SR499 which are commercially available products from Sartomer) is preferable. In addition, as the polymerizable compound, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), 8UH-1006 and 8UH-1012 (manufactured by Taisei Fine Chemical Co., Ltd.), Light Acrylate POB-A0 (manufactured by KYOEISHA CHEMICAL Co., Ltd.), and the like can also be used.

In addition, as the polymerizable compound, it is also preferable to use a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

For example, in the present invention, compounds having the following structures can be used as the polymerizable compound.

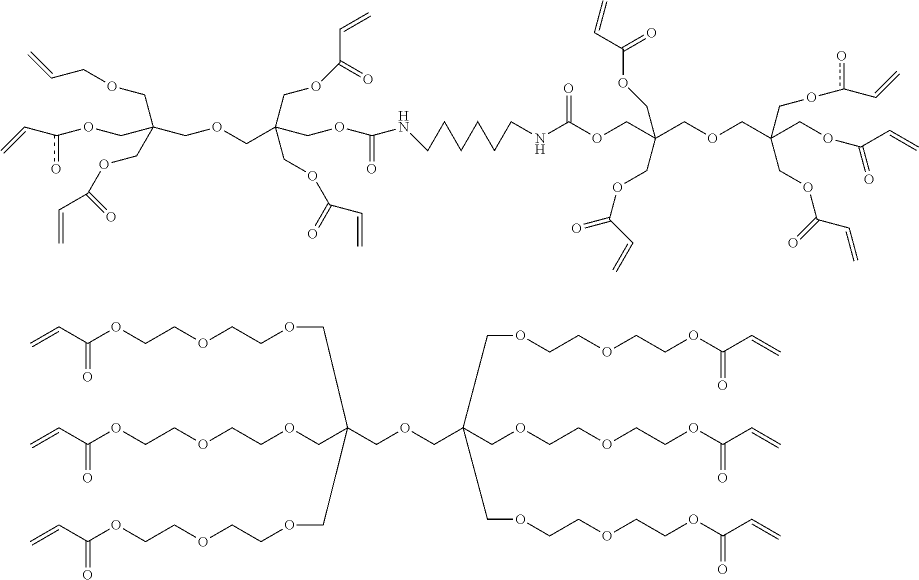

In addition, in the present invention, a mixture of two kinds of compounds having the following structures (molar ratio of left side and right side: 7:3) can also be used as the polymerizable compound.

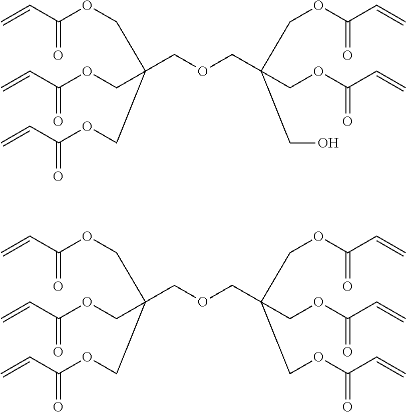

As the polymerizable compound, a compound having an acid group can also be used. By using a polymerizable compound having an acid group, the polymerizable compound in an unexposed area is easily removed during development and the generation of a development residue can be suppressed. Examples of the acid group include a carboxyl group, a sulfo group, and a phosphoric acid group, and a carboxyl group is preferable. Examples of a commercially available product of the polymerizable compound having an acid group include ARONIX M-510, M-520, and ARONIX TO-2349 (manufactured by TOAGOSEI CO., LTD). The acid value of the polymerizable compound having an acid group is preferably 0.1 to 40 mgKOH/g and more preferably 5 to 30 mgKOH/g. In a case where the acid value of the polymerizable compound is 0.1 mgKOH/g or more, solubility in a developer is good, and in a case where the acid value of the polymerizable compound is 40 mgKOH/g or less, it is advantageous in production and handling.

The polymerizable compound is preferably a compound having a caprolactone structure. Examples of the polymerizable compound having a caprolactone structure include DPCA-20, DPCA-30, DPCA-60, and DPCA-120, each of which is commercially available as KAYARAD DPCA series from Nippon Kayaku Co., Ltd.

As the polymerizable compound, a polymerizable compound having an alkyleneoxy group can also be used. The polymerizable compound having an alkyleneoxy group is preferably a polymerizable compound having an ethyleneoxy group and/or a propyleneoxy group, more preferably a polymerizable compound having an ethyleneoxy group, and still more preferably a trifunctional to hexafunctional (meth)acrylate compound having 4 to 20 ethyleneoxy groups. Examples of a commercially available product of the polymerizable compound having an alkyleneoxy group include SR-494 manufactured by Sartomer, which is a tetrafunctional (meth)acrylate having 4 ethyleneoxy groups, and KAYARAD TPA-330 manufactured by Nippon Kayaku Co., Ltd., which is a trifunctional (meth)acrylate having 3 isobutyleneoxy groups.

As the polymerizable compound, a polymerizable compound having a fluorene skeleton can also be used. Examples of a commercially available product of the polymerizable compound having a fluorene skeleton include OGSOL EA-0200, EA-0300 (manufactured by Osaka Gas Chemicals Co., Ltd., (meth)acrylate monomer having a fluorene skeleton).

As the polymerizable compound, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

The urethane acrylates described in JP1973-041708B (JP-S48-041708B), JP1976-037193A (JP-S51-037193A), JP1990-032293B (JP-H02-032293B), or JP1990-016765B (JP-H02-016765B), or the urethane compounds having an ethylene oxide skeleton described in JP1983-049860B (JP-S58-049860B), JP1981-017654B (JP-S56-017654B), JP1987-039417B (JP-S62-039417B), or JP1987-039418B (JP-S62-039418B) are also suitable as the polymerizable compound. In addition, the polymerizable compounds having an amino structure or a sulfide structure in the molecule, described in JP1988-277653A (JP-S63-277653A), JP1988-260909A (JP-S63-260909A), or JP1989-105238A (JP-H01-105238A), are also preferably used. In addition, as the polymerizable compound, commercially available products such as UA-7200 (manufactured by Shin-Nakamura Chemical Co., Ltd.), DPHA-40H (manufactured by Nippon Kayaku Co., Ltd.), and UA-306H, UA-306T, UA-3061, AH-600, T-600, AI-600, and LINC-202UA (manufactured by KYOEISHA CHEMICAL Co., Ltd.) can also be used.

The content of the polymerizable compound in the total solid content of the photosensitive composition is preferably 0.1% to 50% by mass. The lower limit is more preferably 0.5% by mass or more and still more preferably 1% by mass or more. The upper limit is more preferably 45% by mass or less and still more preferably 40% by mass or less. The polymerizable compound may be used singly or in combination of two or more kinds thereof. In a case where two or more kinds thereof are used in combination, the total thereof is preferably within the above-described range.

<<Oxime-Based Photopolymerization Initiator>>

In the present invention, the photosensitive composition can contain an oxime-based photopolymerization initiator as a photopolymerization initiator. Examples of the oxime-based photopolymerization initiator include a compound (oxime compound) having an oxime site in the molecule.

The oxime-based photopolymerization initiator used in the present invention is preferably a photoradical polymerization initiator. In addition, the oxime-based photopolymerization initiator is preferably a compound having photosensitivity to light in a range from the ultraviolet range to the visible range. The oxime-based photopolymerization initiator is preferably a compound having a maximum absorption wavelength in a wavelength range of 350 to 500 nm and more preferably a compound having a maximum absorption wavelength in a wavelength range of 360 to 480 nm. In addition, from the viewpoint of sensitivity, the molar light absorption coefficient of the oxime compound at a wavelength of 365 nm or 405 nm is preferably high, more preferably 1000 to 300000, still more preferably 2000 to 300000, and particularly preferably 5000 to 200000. The molar light absorption coefficient of the oxime compound can be measured using a known method. For example, the molar light absorption coefficient is preferably measured by a spectrophotometer (Cary-5 spectrophotometer, manufactured by Varian) using an ethyl acetate solvent at a concentration of 0.01 g/L.

Examples of the oxime-based photopolymerization initiator include the compounds described in JP2001-233842A, the compounds described in JP2000-080068A, the compounds described in JP2006-342166A, the compounds described in J. C. S. Perkin II (1979, pp. 1653-1660), the compounds described in J. C. S. Perkin II (1979, pp. 156-162), the compounds described in Journal of Photopolymer Science and Technology (1995, pp. 202-232), the compounds described in JP2000-066385A, the compounds described in JP2000-080068A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, and the compounds described in paragraph Nos. 0025 to 0038 of WO2017/164127A. Specific examples of the oxime-based photopolymerization initiator include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one, and 2-ethoxycarbonyloxyimino-1-phenylpropan-1-one. Examples of a commercially available product include IRGACURE-OXEOL IRGACURE-OXE02, IRGACURE-OXE03, and IRGACURE-OXE04 (all of which are manufactured by BASF), TR-PBG-304 (manufactured by TRONLY), and ADEKA OPTOMER N-1919 (manufactured by ADEKA Corporation; photopolymerization initiator 2 described in JP2012-014052A).

In addition, as the oxime-based photopolymerization initiator, it is also preferable to use an oxime compound having no colorability or an oxime compound having high transparency and being difficult to discolor. Examples of a commercially available product include ADEKA ARKLS NCI-730, NCI-831, and NCI-930 (all of which are manufactured by ADEKA Corporation).

In the present invention, as the oxime-based photopolymerization initiator, an oxime compound having a fluorene ring can also be used. Specific examples of the oxime compound having a fluorene ring include the compounds described in JP2014-137466A. The contents thereof are incorporated herein by reference.

In the present invention, as the oxime-based photopolymerization initiator, an oxime compound having a fluorine atom can also be used. Specific examples of the oxime compound having a fluorine atom include the compounds described in JP2010-262028A, the compounds 24, and 36 to 40 described in JP2014-500852A, and the compound (C-3) described in JP2013-164471A. The contents thereof are incorporated herein by reference.

In the present invention, as the oxime-based photopolymerization initiator, an oxime compound having a nitro group can also be used. The oxime compound having a nitro group is also preferably used in the form of a dimer. Specific examples of the oxime compound having a nitro group include the compounds described in paragraph Nos. 0031 to 0047 of JP2013-114249A and paragraph Nos. 0008 to 0012 and 0070 to 0079 of JP2014-137466A, the compounds described in paragraph Nos. 0007 to 0025 of JP4223071B, and ADEKA ARKLS NCI-831 (manufactured by ADEKA Corporation).

In the present invention, as the oxime-based photopolymerization initiator, an oxime compound having a benzofuran skeleton can also be used. Specific examples thereof include OE-01 to OE-75 described in WO2015/036910A.

In the present invention, as the oxime-based photopolymerization initiator, a bifunctional or trifunctional or higher oxime-based photopolymerization initiator may be used. By using such an oxime-based photopolymerization initiator, two or more radicals are generated from one molecule of the oxime-based photopolymerization initiator, and as a result, good sensitivity is obtained. In addition, in a case of using a compound having an asymmetric structure as the oxime-based photopolymerization initiator, crystallinity is reduced so that solubility in a solvent or the like is improved, precipitation is to be difficult over time, and temporal stability of the photosensitive composition can be improved. Specific examples of the bifunctional or trifunctional or higher oxime-based photopolymerization initiator include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A; the compound (E) and compound (G) described in JP2013-522445A; Cmpd 1 to 7 described in WO2016/034963A; the oxime-based photopolymerization initiators described in paragraph No. 0007 of JP2017-523465A; the oxime-based photopolymerization initiators described in paragraph Nos. 0020 to 0033 of JP2017-167399A; and the photopolymerization initiator (A) described in paragraph Nos. 0017 to 0026 of JP2017-151342A.

Specific examples of the oxime-based photopolymerization initiator which are preferably used in the present invention are shown below, but the present invention is not limited thereto.

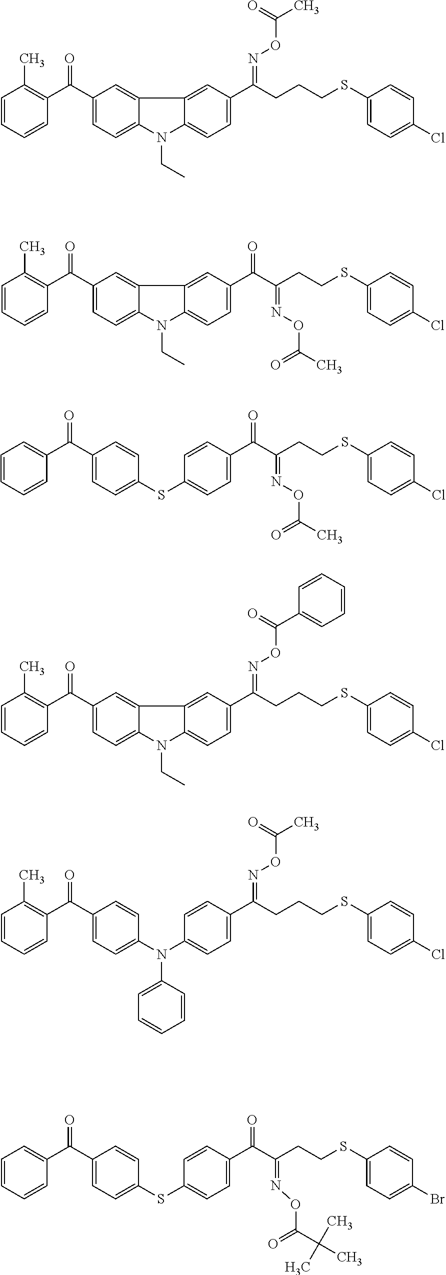 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

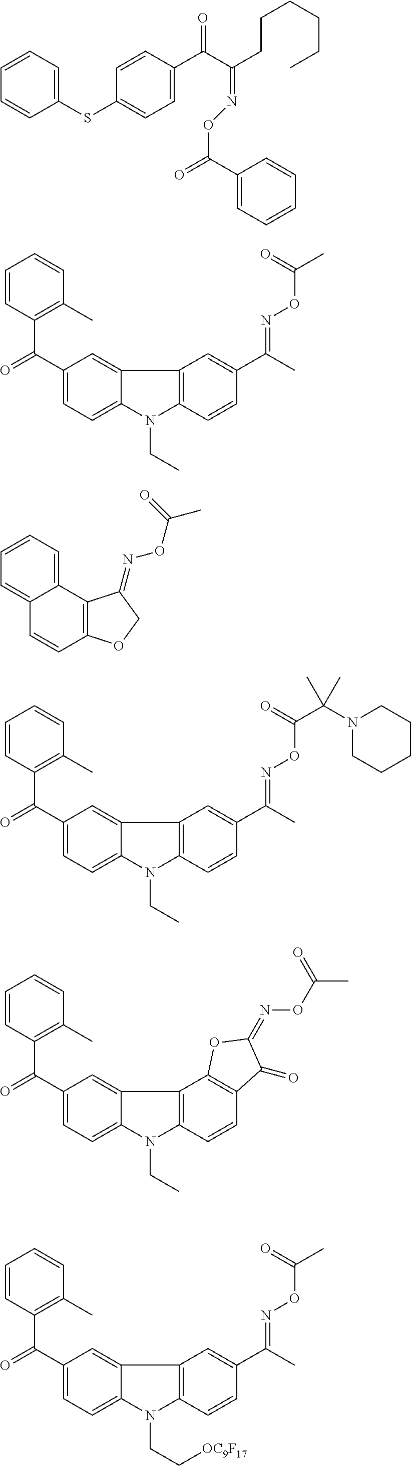

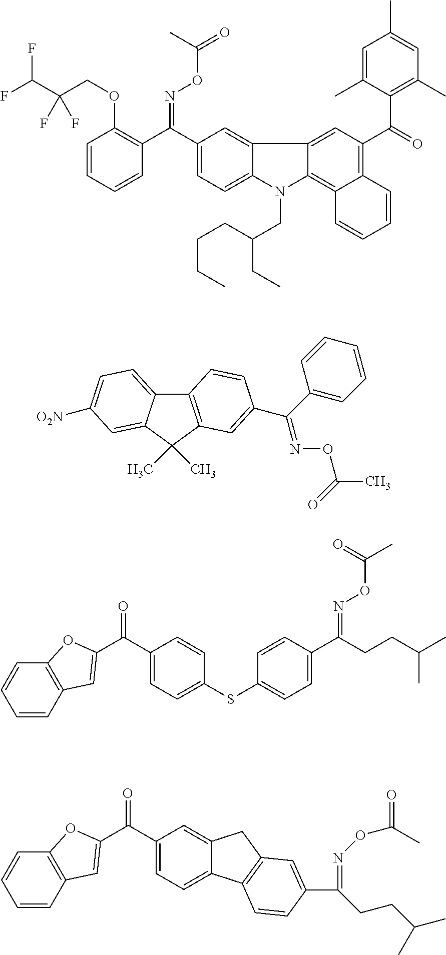 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21 ; CC(=O)O/N=C(\c1ccccc1)c1ccc2c(c1)C(C)(C)c1cc([N+](=O)[O-])ccc1-2 ; CC(=O)O/N=C(\CCC(C)C)c1ccc(Sc2ccc(C(=O)c3cc4ccccc4o3)cc2)cc1 ; CC(=O)O/N=C(\CCC(C)C)c1ccc2c(c1)Cc1cc(C(=O)c3cc4ccccc4o3)ccc1-2]

The content of the oxime-based photopolymerization initiator in the total solid content of the photosensitive composition is preferably 0.1% to 30% by mass. The lower limit is more preferably 0.5% by mass or more and still more preferably 1% by mass or more. The upper limit is more preferably 20% by mass or less and still more preferably 15% by mass or less. In the present invention, the oxime-based photopolymerization initiator may be used singly or in combination of two or more kinds thereof. In a case where two or more kinds thereof are used, the total amount thereof is preferably within the above-described range.

<<Other Photopolymerization Initiators>>

In the present invention, the photosensitive composition can contain, as a photopolymerization initiator, a photopolymerization initiator (other photopolymerization initiators) in addition to the oxime-based photopolymerization initiator. Examples of the other photopolymerization initiators include halogenated hydrocarbon derivatives (for example, a compound having a triazine skeleton and a compound having an oxadiazole skeleton), an acylphosphine compound, hexaaryl biimidazole, an organic peroxide, a thio compound, a ketone compound, an aromatic onium salt, an α-hydroxyketone compound, and an α-aminoketone compound. From the viewpoint of exposure sensitivity, as the other photopolymerization initiators, a trihalomethyl triazine compound, a benzyl dimethyl ketal compound, an α-hydroxyketone compound, an α-aminoketone compound, an acylphosphine compound, a phosphine oxide compound, a metallocene compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, and a compound selected from an α-hydroxyketone compound, an α-aminoketone compound, and an acylphosphine compound is more preferable.

Examples of a commercially available product of the α-hydroxyketone compound include IRGACURE-184, DAROCUR-1173, IRGACURE-500, IRGACURE-2959, and IRGACURE-127 (all manufactured by BASF). Examples of a commercially available product of the α-aminoketone compound include IRGACURE-907, IRGACURE-369, IRGACURE-379, and IRGACURE-379EG (all manufactured by BASF). Examples of a commercially available product of the acylphosphine compound include IRGACURE-819 and DAROCUR-TPO (both manufactured by BASF).

In a case where the photosensitive composition in the present invention contains other photopolymerization initiators, the content of the other photopolymerization initiators in the total solid content of the composition is preferably 0.1% to 30% by mass. The lower limit is more preferably 0.5% by mass or more and still more preferably 1% by mass or more. The upper limit is more preferably 20% by mass or less and still more preferably 15% by mass or less.

In addition, the content of the other photopolymerization initiators is preferably 1 to 100 parts by mass with respect to 100 parts by mass of the oxime-based photopolymerization initiator. The upper limit is more preferably 90 parts by mass or less and still more preferably 80 parts by mass or less. The lower limit is more preferably 5 parts by mass or more and still more preferably 10 parts by mass or more.

In addition, in the present invention, the total content of the oxime-based initiator and other photopolymerization initiators in the total solid content of the photosensitive composition is preferably 0.1% to 30% by mass. The lower limit is more preferably 0.5% by mass or more and still more preferably 1% by mass or more. The upper limit is more preferably 20% by mass or less and still more preferably 15% by mass or less.

In the present invention, it is also preferable that the photosensitive composition does not substantially contain the other photopolymerization initiators. According to this aspect, it is easy to form a film having more excellent adhesiveness. The case where the photosensitive composition in the present invention does not substantially include the other photopolymerization initiators means that the content of the other photopolymerization initiators in the total solid content of the composition is preferably 0.05% by mass or less, more preferably 0.01% by mass or less, and particularly preferably 0% by mass.

<<Resin>>

In the present invention, the photosensitive composition contains a resin. The resin is blended in, for example, an application for dispersing particles such as a pigment in a photosensitive composition or an application as a binder. Mainly, a resin which is used for dispersing particles such as a pigment is also referred to as a dispersant. However, such applications of the resin are only exemplary, and the resin can also be used for other purposes in addition to such applications.

The weight-average molecular weight (Mw) of the resin is preferably 3000 to 2000000. The upper limit is more preferably 1000000 or less and still more preferably 500000 or less. The lower limit is more preferably 4000 or more and still more preferably 5000 or more.

Examples of the resin include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, and a styrene resin. These resins may be used singly or as a mixture of two or more kinds thereof. In addition, the resins described in paragraph Nos. 0041 to 0060 of JP2017-206689A, and the resins described in paragraph Nos. 0022 to 0071 of JP2018-010856A can also be used.

In the present invention, as the resin, a resin having an acid group can be preferably used. According to this aspect, developability of the photosensitive composition can be improved, and pixels having excellent rectangularity can be easily formed. Examples of the acid group include a carboxyl group, a phosphoric acid group, a sulfo group, and a phenolic hydroxyl group, and a carboxyl group is preferable. The resin having an acid group can be used, for example, as an alkali-soluble resin.

The resin having an acid group preferably includes a repeating unit having an acid group in the side chain, and more preferably includes 5% to 70% by mole of repeating units having an acid group in the side chain with respect to the total repeating units of the resin. The upper limit of the content of the repeating unit having an acid group in the side chain is still more preferably 50% by mole or less and particularly preferably 30% by mole or less. The lower limit of the content of the repeating unit having an acid group in the side chain is still more preferably 10% by mole or more and particularly preferably 20% by mole or more.

As the resin having an acid group, for example, an ether dimer described in JP2013-029760A can also be used. The contents thereof are incorporated herein by reference.

It is also preferable that the resin used in the present invention includes a repeating unit derived from a compound represented by Formula (X).

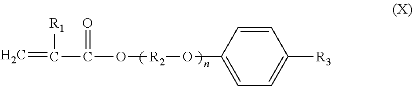

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may include a benzene ring. n represents an integer of 1 to 15.

With regard to the resin having an acid group, reference can be made to the description in paragraph Nos. 0558 to 0571 of JP2012-208494A (paragraph Nos. 0685 to 0700 of the corresponding US2012/0235099A) and the description in paragraph Nos. 0076 to 0099 of JP2012-198408A, the contents of which are incorporated herein by reference. A commercially available product can also be used as the resin having an acid group.

The acid value of the resin having an acid group is preferably 30 to 500 mgKOH/g. The lower limit is more preferably 50 mgKOH/g or more and still more preferably 70 mgKOH/g or more. The upper limit is more preferably 400 mgKOH/g or less, still more preferably 300 mgKOH/g or less, and particularly preferably 200 mgKOH/g or less. The weight-average molecular weight (Mw) of the resin having an acid group is preferably 5000 to 100000. In addition, the number-average molecular weight (Mn) of the resin having an acid group is preferably 1000 to 20000.

Examples of the resin having an acid group include a resin having the following structures.

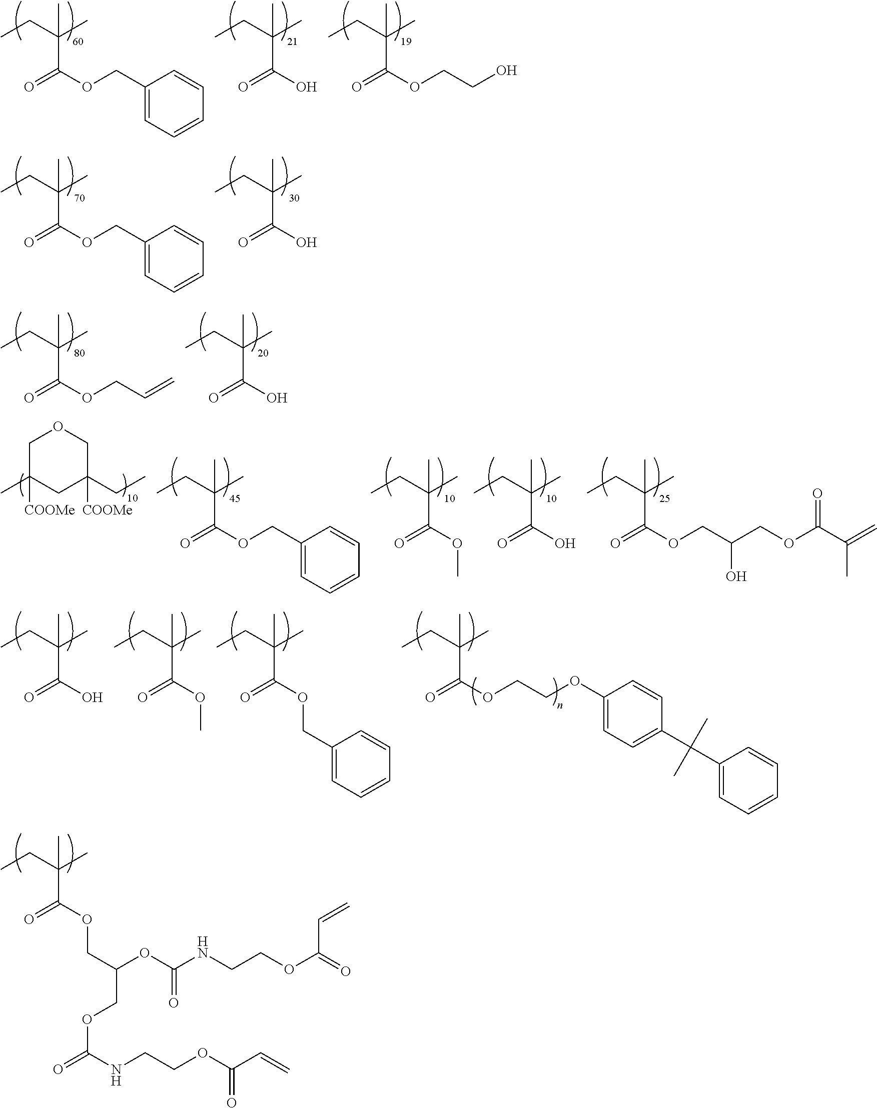

In the present invention, the photosensitive composition can also contain a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70% by mole or more in a case where the total amount of the acid group and the basic group is 100% by mole, and more preferably a resin substantially consisting of only an acid group. The acid group included in the acidic dispersant (acidic resin) is preferably a carboxyl group. The acid value of the acidic dispersant (acidic resin) is preferably 40 to 105 mgKOH/g, more preferably 50 to 105 mgKOH/g, and still more preferably 60 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50% by mole in a case where the total amount of the acid group and the basic group is 100% by mole. The basic group included in the basic dispersant is preferably an amino group.

The resin used as a dispersant preferably includes a repeating unit having an acid group. In a case where the resin used as a dispersant includes a repeating unit having an acid group, the generation of the development residue can be further suppressed in the formation of a pattern by a photolithography method.

It is also preferable that the resin used as a dispersant is a graft resin. With regard to details of the graft resin, reference can be made to the description in paragraph Nos. 0025 to 0094 of JP2012-255128A, the contents of which are incorporated herein by reference. In addition, the resin used as a dispersant is preferably a resin including a hindered amine quaternary salt. With regard to details of such a resin, reference can be made to the description in JP2019-095548A, the contents of which are incorporated herein by reference.

It is also preferable that the resin used as a dispersant is a polyimine-based dispersant including a nitrogen atom in at least one of the main chain or the side chain. As the polyimine-based dispersant, a resin having a main chain which has a partial structure having a functional group of pKa14 or less, and a side chain which has 40 to 10000 atoms, in which at least one of the main chain or the side chain has a basic nitrogen atom, is preferable. The basic nitrogen atom is not particularly limited as long as it is a nitrogen atom exhibiting basicity. With regard to the polyimine-based dispersant, reference can be made to the description in paragraph Nos. 0102 to 0166 of JP2012-255128A, the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraph Nos. 0196 to 0209 of JP2013-043962A.

In addition, the above-described resin (alkali-soluble resin) having an acid group can also be used as a dispersant.

In addition, it is also preferable that the resin used as a dispersant is a resin including a repeating unit having an ethylenically unsaturated bonding group in the side chain. The content of the repeating unit having an ethylenically unsaturated bonding group in the side chain is preferably 10% by mole or more, more preferably 10% to 80% by mole, and still more preferably 20% to 70% by mole with respect to the total repeating units of the resin.

A commercially available product is also available as the dispersant, and specific examples thereof include DISPERBYK series (for example, DISPERBYK-111, 161, and the like) manufactured by BYK Chemie, and Solsperse series (for example, Solsperse 76500) manufactured by Lubrizol Corporation. The dispersing agents described in paragraph Nos. 0041 to 0130 of JP2014-130338A can also be used, the contents of which are incorporated herein by reference. The resin described as a dispersant can be used for an application other than the dispersant. For example, the resin can also be used as a binder.

In the present invention, in a case where the photosensitive composition contains a resin, the content of the resin in the total solid content of the photosensitive composition is preferably 5% to 50% by mass. The lower limit is more preferably 10% by mass or more and still more preferably 15% by mass or more. The upper limit is more preferably 40% by mass or less, still more preferably 35% by mass or less, and particularly preferably 30% by mass or less. In addition, the content of the resin having an acid group, in the total solid content of the photosensitive composition, is preferably 5% to 50% by mass. The lower limit is more preferably 10% by mass or more and still more preferably 15% by mass or more. The upper limit is more preferably 40% by mass or less, still more preferably 35% by mass or less, and particularly preferably 30% by mass or less. In addition, from the reason that excellent developability is easily obtained, the content of the resin having an acid group in the total amount of the resin is preferably 30% by mass or more, more preferably 50% by mass or more, still more preferably 70% by mass or more, and particularly preferably 80% by mass or more. The upper limit may be 100% by mass, 95% by mass, or 90% by mass or less.

In addition, from the viewpoint of curability, developability, and film-forming property, the total content of the polymerizable compound and resin in the total solid content of the photosensitive composition is preferably 10% to 65% by mass. The lower limit is more preferably 15% by mass or more, still more preferably 20% by mass or more, and particularly preferably 30% by mass or more. The upper limit is more preferably 60% by mass or less, still more preferably 50% by mass or less, and particularly preferably 40% by mass or less. In addition, the photosensitive composition preferably contains 30 to 300 parts by mass of the resin with respect to 100 parts by mass of the polymerizable compound. The lower limit is more preferably 50 parts by mass or more and still more preferably 80 parts by mass or more. The upper limit is more preferably 250 parts by mass or less and still more preferably 200 parts by mass or less.

<<Compound Having Cyclic Ether Group>>

In the present invention, the photosensitive composition can contain a compound having a cyclic ether group. Examples of the cyclic ether group include an epoxy group and an oxetanyl group. The compound having a cyclic ether group is preferably a compound having an epoxy group. Examples of the compound having an epoxy group include a compound having one or more epoxy groups in one molecule, and a compound having two or more epoxy groups in one molecule is preferable. It is preferable to have 1 to 100 epoxy groups in one molecule. The upper limit of the number of epoxy groups may be, for example, 10 or less or 5 or less. The lower limit of the epoxy group is more preferably 2 or more. As the compound having an epoxy group, the compounds described in paragraph Nos. 0034 to 0036 of JP2013-011869A, paragraph Nos. 0147 to 0156 of JP2014-043556A, and paragraph Nos. 0085 to 0092 of JP2014-089408A, and the compounds described in JP2017-179172A can also be used. The contents thereof are incorporated herein by reference.

The compound having an epoxy group may be a low-molecular-weight compound (for example, having a molecular weight of less than 2000, and further, a molecular weight of less than 1000) or a high-molecular-weight compound (macromolecule) (for example, having a molecular weight of 1000 or more, and in a case of a polymer, having a weight-average molecular weight of 1000 or more). The weight-average molecular weight of the compound having an epoxy group is preferably 200 to 100000 and more preferably 500 to 50000. The upper limit of the weight-average molecular weight is still more preferably 10000 or less, particularly preferably 5000 or less, and even more preferably 3000 or less.

As the compound having an epoxy group, an epoxy resin can be preferably used. Examples of the epoxy resin include an epoxy resin which is a glycidyl etherified product of a phenol compound, an epoxy resin which is a glycidyl etherified product of various novolak resins, an alicyclic epoxy resin, an aliphatic epoxy resin, a heterocyclic epoxy resin, a glycidyl ester-based epoxy resin, a glycidyl amine-based epoxy resin, an epoxy resin obtained by glycidylating halogenated phenols, a condensate of a silicon compound having an epoxy group and another silicon compound, and a copolymer of a polymerizable unsaturated compound having an epoxy group and another polymerizable unsaturated compound. The epoxy equivalent of the epoxy resin is preferably 310 to 3300 g/eq, more preferably 310 to 1700 g/eq, and still more preferably 310 to 1000 g/eq.

Examples of a commercially available product of the compound having a cyclic ether group include EHPE 3150 (manufactured by DAICEL-ALLNEX LTD.), EPICLON N-695 (manufactured by DIC Corporation), and MARPROOF G-0150M, G-0105SA, G-0130SP, G-0250SP, G-1005S, G-1005SA, G-1010S, G-2050M, G-01100, and G-01758 (all of which are manufactured by NOF Corporation, an epoxy group-containing polymer).

In the present invention, in a case where the photosensitive composition contains a compound having a cyclic ether group, the content of the compound having a cyclic ether group in the total solid content of the photosensitive composition is preferably 0.1% to 20% by mass. The lower limit is, for example, more preferably 0.5% by mass or more and still more preferably 1% by mass or more. The upper limit is, for example, more preferably 15% by mass or less and still more preferably 10% by mass or less. The compound having a cyclic ether group may be used singly or in combination of two or more kinds thereof. In a case of using two or more kinds thereof, the total amount thereof is preferably within the above-described range.

<<Silane Coupling Agent>>

In the present invention, the photosensitive composition can contain a silane coupling agent. According to this aspect, adhesiveness of a film to be obtained with a support can be further improved. In the present invention, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group, and an amino group, a (meth)acryloyl group, or an epoxy group is preferable. Specific examples of the silane coupling agent include the compounds described in paragraph Nos. 0018 to 0036 of JP2009-288703A and the compounds described in paragraph Nos. 0056 to 0066 of JP2009-242604A, the contents of which are incorporated herein by reference.

Examples of the silane coupling agent include a compound having the following structure.

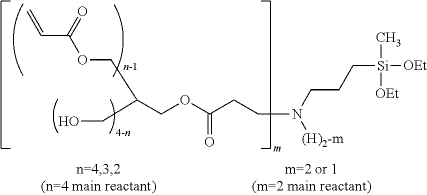

The content of the silane coupling agent in the total solid content of the photosensitive composition is preferably 0.1% to 5% by mass. The upper limit is more preferably 3% by mass or less and still more preferably 2% by mass or less. The lower limit is more preferably 0.5% by mass or more and still more preferably 1% by mass or more. The silane coupling agent may be used singly or in combination of two or more kinds thereof. In a case of using two or more kinds thereof, the total amount thereof is preferably within the above-described range.

<<Surfactant>>

In the present invention, the photosensitive composition can contain a surfactant. As the surfactant, various surfactants such as a fluorine-based surfactant, a nonionic surfactant, a cationic surfactant, an anionic surfactant, and a silicon-based surfactant can be used. With regard to the surfactant, reference can be made to the description in paragraph Nos. 0238 to 0245 of WO2015/166779A, the contents of which are incorporated herein by reference.

In the present invention, it is preferable that the surfactant is a fluorine-based surfactant. By containing a fluorine-based surfactant in the photosensitive composition, liquid characteristics (particularly, fluidity) are further improved, and liquid saving properties can be further improved. In addition, it is possible to form a film with a small thickness unevenness.

The fluorine content in the fluorine-based surfactant is suitably 3% to 40% by mass, and more preferably 5% to 30% by mass and particularly preferably 7% to 25% by mass. The fluorine-based surfactant in which the fluorine content is within the above-described range is effective in terms of the evenness of the thickness of the coating film or liquid saving properties and the solubility of the surfactant in the photosensitive composition is also good.

Examples of the fluorine-based surfactant include surfactants described in paragraph Nos. 0060 to 0064 of JP2014-041318A (paragraph Nos 0060 to 0064 of the corresponding WO2014/017669A) and the like, and surfactants described in paragraph Nos 0117 to 0132 of JP2011-132503A, the contents of which are incorporated herein by reference. Examples of a commercially available product of the fluorine-based surfactant include MEGAFACE F171, F172, F173, F176, F177, F141, F142, F143, F144, R30, F437, F475, F479, F482, F554, F780, EXP, and MFS-330 (all of which are manufactured by DIC Corporation), FLUORAD FC430, FC431, and FC171 (all of which are manufactured by Sumitomo 3M), SURFLON S-382, SC-101, SC-103, SC-104, SC-105, SC-1068, SC-381, SC-383, and S-393, and KH-40 (all of which are manufactured by AGC SEIMI CHEMICAL CO., LTD.), and PolyFox PF636, PF656, PF6320, PF6520, and PF7002 (all of which are manufactured by OMNOVA).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily, Feb. 22, 2016; Nikkei Business Daily, Feb. 23, 2016) such as MEGAFACE DS-21.

In addition, it is also preferable that a polymer of a fluorine atom-containing vinyl ether compound having a fluorinated alkyl group or a fluorinated alkylene ether group, and a hydrophilic vinyl ether compound is used as the fluorine-based surfactant. With regard to such a fluorine-based surfactant, reference can be made to the description in JP2016-216602A, the contents of which are incorporated herein by reference.

A block polymer can also be used as the fluorine-based surfactant. Examples thereof include the compounds described in JP2011-089090A. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. The following compounds are also exemplified as the fluorine-based surfactant used in the present invention.

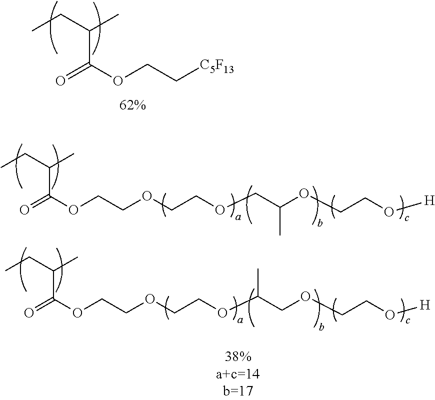

The weight-average molecular weight of the above-described compound is preferably 3000 to 50000, and is, for example, 14000. In the compound, “%” representing the proportion of a repeating unit is mol %.

In addition, as the fluorine-based surfactant, a fluorine-containing polymer having an ethylenically unsaturated bonding group in the side chain can also be used. Specific examples thereof include the compounds described in paragraph Nos. 0050 to 0090 and paragraph Nos. 0289 to 0295 of JP2010-164965A, and for example, MEGAFACE RS-101, RS-102, RS-718K, and RS-72-K manufactured by DIC Corporation. As the fluorine-based surfactant, the compounds described in paragraph Nos. 0015 to 0158 of JP2015-117327A can also be used.

The content of the surfactant in the total solid content of the photosensitive composition is preferably 0.001% by mass to 5.0% by mass and more preferably 0.005% to 3.0% by mass. The surfactant may be used singly or in combination of two or more kinds thereof. In a case of using two or more kinds thereof, the total amount thereof is preferably within the above-described range.

<<Ultraviolet Absorber>>

In the present invention, the photosensitive composition can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, or the like can be used. With regard to details thereof, reference can be made to the description in paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. Specific examples of the ultraviolet absorber include a compound having the following structures. Examples of a commercially available product of the ultraviolet absorber include UV-503 (manufactured by Daito Chemical Co., Ltd). In addition, examples of the benzotriazole compound include MYUA series manufactured by Miyoshi Oil & Fat Co., Ltd. (The Chemical Daily, Feb. 1, 2016).

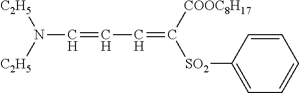

The content of the ultraviolet absorber in the total solid content of the photosensitive composition is preferably 0.01% to 10% by mass and more preferably 0.01% to 5% by mass. In the present invention, the ultraviolet absorber may be used singly or in combination of two or more kinds thereof. In a case where two or more kinds thereof are used, the total amount thereof is preferably within the above-described range.

<<Solvent>>

In the present invention, the photosensitive composition can contain a solvent. Examples of the solvent which can be used include an organic solvent. Basically, the solvent is not particularly limited as long as it satisfies solubility of the respective components or coatability of the photosensitive composition. Examples of the organic solvent include an ester-based solvent, a ketone-based solvent, an alcohol-based solvent, an amide-based solvent, an ether-based solvent, and a hydrocarbon-based solvent. With regard to details thereof, reference can be made to the description in paragraph No. 0223 of WO2015/166779A, the contents of which are incorporated herein by reference. In addition, an ester-based solvent substituted with a cyclic alkyl group or a ketone-based solvent substituted with a cyclic alkyl group can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether (PGME), propylene glycol monomethyl ether acetate (PGMEA), 3-methoxy-N,N-dimethylpropanamide, and 3-butoxy-N,N-dimethylpropanamide. In this case, it may be preferable that the content of aromatic hydrocarbons (such as benzene, toluene, xylene, and ethylbenzene) as the solvent is low (for example, 50 parts per million (ppm) by mass or less, 10 ppm by mass or less, or 1 ppm by mass or less with respect to the total amount of the organic solvent) in consideration of environmental aspects and the like.

The content of the solvent in the photosensitive composition is preferably 10% to 95% by mass, more preferably 20% to 90% by mass, and still more preferably 30% to 90% by mass.

<<Other Components>>

In the present invention, optionally, the photosensitive composition may further contain a polymerization inhibitor, a sensitizer, a curing accelerator, a filler, a thermal curing accelerator, a plasticizer, and other auxiliary agents (for example, conductive particles, a filler, an antifoaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph No. 0183 of JP2012-003225A (corresponding to paragraph No. 0237 of US2013/0034812A) and paragraph Nos. 0101 to 0104 and 0107 to 0109 of JP2008-250074A, the contents of which are incorporated herein by reference. In addition, in the present invention, optionally, the photosensitive composition may contain a potential antioxidant. Examples of the potential antioxidant include a compound in which a site functioning as an antioxidant is protected by a protecting group, and the protecting group is eliminated by heating the compound at 100° C. to 250° C. or heating the compound at 80° C. to 200° C. in the presence of an acid or basic catalyst so that the compound functions as an antioxidant. Examples of the potential antioxidant include the compounds described in WO2014/021023A, WO2017/030005A, and JP2017-008219A. Examples of a commercially available product thereof include ADEKA ARKLS GPA-5001 (manufactured by ADEKA Corporation).

In addition, in the present invention, in order to adjust the refractive index of the film to be obtained, the photosensitive composition may contain a metal oxide. Examples of the metal oxide include TiO₂, ZrO₂, Al₂O₃, and SiO₂. The primary particle diameter of the metal oxide is preferably 1 to 100 nm, more preferably 3 to 70 nm, and most preferably 5 to 50 nm. The metal oxide may have a core-shell structure, and in this case, the core portion may be hollow.

In the photosensitive composition in the present invention, the content of free metal which is not bonded to or coordinated with a pigment or the like is preferably 100 ppm or less, more preferably 50 ppm or less, and still more preferably 10 ppm or less, it is particularly preferable to not contain the free metal substantially. According to this aspect, stabilization of pigment dispersibility (restraint of aggregation), improvement of spectral characteristics due to improvement of dispersibility, stabilization of curable components, restraint of conductivity fluctuation due to elution of metal atoms and metal ions, improvement of display characteristics, and the like can be achieved. In addition, the effects described in JP2012-153796A, JP2000-345085A, JP2005-200560A, JP1996-043620A (JP-H08-043620A), JP2004-145078A, JP2014-119487A, JP2010-083997A, JP2017-090930A, JP2018-025612A, JP2018-025797A, JP2017-155228A, JP2018-036521A, and the like can also be obtained. Examples of the types of the above-described free metals include Na, K, Ca, Sc, Ti, Mn, Cu, Zn, Fe, Cr, Co, Mg, Al, Sn, Zr, Ga, Ge, Ag, Au, Pt, Cs, Ni, Cd, Pb, and Bi. In addition, in the composition, the content of free halogen which is not bonded to or coordinated with a pigment or the like is preferably 100 ppm or less, more preferably 50 ppm or less, and still more preferably 10 ppm or less, it is particularly preferable to not contain the free halogen substantially. Examples of a method for reducing free metals and halogens in the composition include washing with ion exchange water, filtration, ultrafiltration, and purification with an ion exchange resin.

In addition, it is preferable that the photosensitive composition does not substantially contain terephthalic acid ester.

<<Storage Container>>

A storage container for the photosensitive composition is not particularly limited, and a known storage container can be used. In addition, as the storage container, it is also preferable to use a multilayer bottle having an inner wall constituted with six layers from six kinds of resins or a bottle having a 7-layer structure from 6 kinds of resins for the purpose of suppressing incorporation of impurities into raw materials or photosensitive compositions. Examples of such a container include the containers described in JP2015-123351A. In addition, for the purpose of preventing metal elution from the container inner wall, improving storage stability of the composition, and suppressing the alteration of components, it is also preferable that the inner wall of the storage container is formed of glass, stainless steel, or the like.

<Method for Forming Pixel>

The pixel in the structural body according to the embodiment of the present invention can be formed by a photolithography method using the photosensitive composition containing the above-described pixel components. Pattern formation by the photolithography method preferably includes a step of forming a photosensitive composition layer on a support with the photosensitive composition, a step of patternwise exposing the photosensitive composition layer, and a step of removing an unexposed area of the photosensitive composition layer by development to form a pattern (pixel). A step (pre-baking step) of baking the photosensitive composition layer and a step (post-baking step) of baking the developed pattern (pixel) may be provided, optionally.

In addition, from the viewpoint of flatness of a base of the photosensitive composition layer, it is also preferable to form an undercoat layer on the support before forming the photosensitive composition layer. Details of the undercoat layer are described in WO2018/062130A, the contents of which are incorporated herein by reference.

<<Method for Preparing Composition>>

The photosensitive composition for forming the pixel in the structural body according to the embodiment of the present invention can be prepared by mixing the above-described components. In the preparation of the photosensitive composition, all the components may be dissolved and/or dispersed at the same time in a solvent to prepare the photosensitive composition, or the respective components may be appropriately left in two or more solutions or dispersion liquids and mixed to prepare the photosensitive composition upon use (during coating), as desired.

In addition, in the preparation of the photosensitive composition, a process for dispersing the pigment is preferably included. In the process for dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the pigment, a refining treatment of particles in a salt milling step may be performed. With regard to the materials, equipment, treatment conditions, and the like used in the salt milling step, reference can be made to, for example, the description in JP2015-194521A and JP2012-046629A.

It is preferable that, in the preparation of the photosensitive composition, the photosensitive composition is filtered through a filter for the purpose of removing foreign matters, reducing defects, or the like. As the filter, any filters that have been used in the related art for filtration use and the like may be used without particular limitation. Examples of the filter include filters formed of materials including, for example, a fluororesin such as polytetrafluoroethylene (PTFE), a polyamide-based resin such as nylon (for example, nylon-6 and nylon-6,6), and a polyolefin resin (including a polyolefin resin having a high-density or an ultrahigh molecular weight) such as polyethylene and polypropylene (PP). Among these materials, polypropylene (including a high-density polypropylene) and nylon are preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NIEY and the like), Toyo Roshi Kaisha., Ltd., Nihon Entegris K. K. (formerly Nippon Microlith Co., Ltd.), Kitz Micro Filter Corporation, and the like can be used.

In addition, it is preferable that a fibrous filter material is used as the filter. Examples of the fibrous filter material include a polypropylene fiber, a nylon fiber, and a glass fiber. Examples of a commercially available product include SBP type series (SBP008 and the like), TPR type series (TPR002, TPR005, and the like), or SHPX type series (SHPX003 and the like), all manufactured by Roki Techno Co., Ltd.

In a case of using a filter, different filters (for example, a first filter, a second filter, and the like) may be combined. In this case, the filtration with each of the filters may be performed once or may be performed twice or more times. In addition, filters having different pore sizes within the above-described range may be combined. In addition, the filtration through the first filter may be performed with only a dispersion liquid, the other components may be mixed therewith, and then the filtration through the second filter may be performed.

<<Step of Forming Photosensitive Composition Layer>>

In the step of forming a photosensitive composition layer, the photosensitive composition layer is formed on a support using the photosensitive composition. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, an undercoat layer may be provided on the silicon substrate so as to improve adhesiveness to an upper layer, prevent the diffusion of materials, or planarize the surface of the substrate.

As a method for applying the photosensitive composition, a known method can be used. Examples thereof include a dropping method (drop casting); a slit coating method; a spray method; a roll coating method; a spin coating method (spin coating); a cast coating method; a slit and spin method; a pre-wet method (for example, a method described in JP2009-145395A), various printing methods such as an ink jet (for example, on-demand type, piezo type, thermal type), a discharge printing such as nozzle jet, a flexo printing, a screen printing, a gravure printing, a reverse offset printing, and a metal mask printing; a transfer method using molds and the like; and a nanoimprint method. A method for applying the ink jet is not particularly limited, and examples thereof include a method described in “Extension of Use of Ink Jet—Infinite Possibilities in Patent—” (February, 2005, S. B. Research Co., Ltd.) (particularly pp. 115 to 133) and methods described in JP2003-262716A, JP2003-185831A, JP2003-261827A, JP2012-126830A, and JP2006-169325A. In addition, with regard to the method for applying the photosensitive composition, reference can be made to the description in WO2017/030174A and WO2017/018419A, the contents of which are incorporated herein by reference.

The photosensitive composition layer formed on the support may be dried (pre-baked). In a case of producing a film by a low-temperature process, pre-baking may not be performed. In a case of performing the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. The pre-baking time is preferably 10 to 300 seconds, more preferably 40 to 250 seconds, and still more preferably 80 to 220 seconds. The pre-baking can be performed using a hot plate, an oven, or the like.

<<Exposing Step>>

Next, the photosensitive composition layer is patternwise exposed (exposing step). For example, the photosensitive composition layer can be subjected to patternwise exposure by performing exposure using a stepper exposure machine or a scanner exposure machine through a mask having a predetermined mask pattern. Thus, the exposed portion can be cured.

Examples of the radiation (light) which can be used during the exposure include g-rays and i-rays. In addition, light (preferably light having a wavelength of 180 to 300 nm) having a wavelength of 300 nm or less can be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the photosensitive composition layer may be irradiated with light continuously to expose the photosensitive composition layer, or the photosensitive composition layer may be irradiated with light in a pulse to expose the photosensitive composition layer (pulse exposure). The pulse exposure refers to an exposing method in which light irradiation and resting are repeatedly performed in a short cycle (for example, millisecond-level or less). In a case of the pulse exposure, the pulse width is preferably 100 nanoseconds (ns) or less, more preferably 50 nanoseconds or less, and still more preferably 30 nanoseconds or less. The lower limit of the pulse width is not particularly limited, and may be 1 femtosecond (fs) or more or 10 femtoseconds or more. The frequency is preferably 1 kHz or more, more preferably 2 kHz or more, and still more preferably 4 kHz or more. The upper limit of the frequency is preferably 50 kHz or less, more preferably 20 kHz or less, and still more preferably 10 kHz or less. The maximum instantaneous illuminance is preferably 50000000 W/m² or more, more preferably 100000000 W/m² or more, and still more preferably 200000000 W/m² or more. In addition, the upper limit of the maximum instantaneous illuminance is preferably 1000000000 W/m² or less, more preferably 800000000 W/m² or less, and still more preferably 500000000 W/m² or less. The pulse width refers to a time during which light is irradiated in a pulse period. In addition, the frequency refers to the number of pulse periods per second. In addition, the maximum instantaneous illuminance refers to an average illuminance within the period of light irradiation in the pulse period. In addition, the pulse period refers to a period in which light irradiation and resting in the pulse exposure are defined as one cycle.

The irradiation dose (exposure dose) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

<<Developing Step>>

Next, the unexposed area of the photosensitive composition layer is removed by development to form a pattern (pixel). The removal of the unexposed area of the photosensitive composition layer by development can be carried out using a developer. Thus, the photosensitive composition layer of the unexposed area in the exposing step is eluted into the developer, and as a result, only a photocured portion remains. As the developer, an organic alkaline developer causing no damage on a base of element, circuit, or the like is desirable. The temperature of the developer is preferably, for example, 20° C. to 30° C. The development time is preferably 20 to 180 seconds. In addition, in order to improve residue removing properties, a step of removing the developer by shaking off per 60 seconds and supplying a fresh developer may be repeated multiple times.

As the developer, an aqueous alkaline solution (alkaline developer) obtained by diluting an alkali agent with pure water is preferable. Examples of the alkali agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkali agent is preferably a compound having a high molecular weight. The concentration of the alkali agent in the aqueous alkaline solution is preferably 0.001% to 10% by mass and more preferably 0.01% to 1% by mass. In addition, the developer may further contain a surfactant. Examples of the surfactant include the surfactants described above, and the surfactant is preferably a nonionic surfactant. From the viewpoint of transportation, storage, and the like, the developer may be first produced as a concentrated liquid and then diluted to a concentration required upon use. The dilution ratio is not particularly limited, and can be set to, for example, a range of 1.5 to 100 times. In addition, it is also preferable to wash (rinse) with pure water after development. In addition, it is preferable that the rinsing is performed by supplying a rinsing liquid to the photosensitive composition layer after development while rotating the support on which the photosensitive composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to carry out an additional exposure treatment or a heating treatment (post-baking) after carrying out drying. The additional exposure treatment or the post-baking is a heating treatment after development in order to complete curing, and the heating temperature is preferably, for example, 100° C. to 240° C. and more preferably 200° C. to 240° C. The post-baking can be performed continuously or batchwise by using a heating unit such as a hot plate, a convection oven (hot-air circulating dryer), and a high-frequency heater so that the film after development satisfies the conditions.

In a case of carrying out the additional exposure treatment, light used for the exposure is preferably light having a wavelength of 400 nm or less. In addition, the additional exposure treatment may be carried out by the method described in KR10-2017-122130A.

Through the above-described steps, one pixel is formed. In a case of forming next pixel, the above-described coating, exposure, and development are repeated.

### EXAMPLES

Hereinafter, the present invention will be described in more detail with reference to the examples. The materials, the amounts of materials to be used, the proportions, the treatment details, the treatment procedure, or the like shown in the examples below may be modified appropriately as long as the modifications do not depart from the spirit of the present invention. Therefore, the scope of the present invention is not limited to the specific examples shown below. “Parts” and “%” are on a mass basis unless otherwise stated. A weight-average molecular weight and a number-average molecular weight are values in terms of polystyrene through measurement by the GPC method as described above.

<Production of Composition for Undercoat Layer>

The following raw materials were mixed to produce a composition for forming an undercoat layer.

| | | |
|---|---|---|
| Resin A described below (54% by mass PGME solution) | 0.7 | parts by mass |
| Surfactant A (0.2% by mass PGMEA solution) | 0.8 | parts by mass |
| The details of the raw materials are as follows. | | |
| PGMEA | 98.5 | parts by mass |
| Resin A: CYCLOMER P (ACA) 230AA (manufactured by DAICEL-ALLNEX | | |
| LTD.; acid value = 30 mgKOH/g, Mw = 15000) | | |
| Surfactant A: following mixture (Mw = 14000; “%” representing the proportion of a | | |
| repeating unit is % by mass) | | |

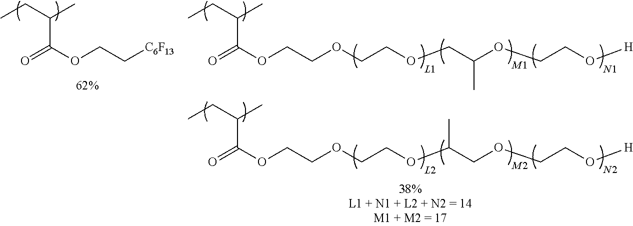

<Production of Photosensitive Composition>

Using the following raw materials, various compositions shown in Tables 2 to 10 were produced by the procedure and formulation described later.

<<Raw Material>>

### <<<Coloring Material: Pigment and Dye>>>

PR122: C. I. Pigment Red 122
PR177: C. I. Pigment Red 177
PR254: C. I. Pigment Red 254
PR272: C. I. Pigment Red 272
PG7: C. I. Pigment Green 7
PG36: C. I. Pigment Green 36
PG58: C. I. Pigment Green 58
PB15:6: C. I. Pigment Blue 15:6
P071: C. I. Pigment Orange 71
PV23: C. I. Pigment Violet 23
PY139: C. I. Pigment Yellow 139
PY150: C. I. Pigment Yellow 150
PY185: C. I. Pigment Yellow 185
TiO₂: TTO-51(C) (manufactured by ISHIHARA SANGYO KAISHA, LTD.)
A1 phthalocyanine: compound having the following structure

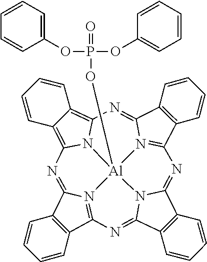

Xanthene: compound having the following structure

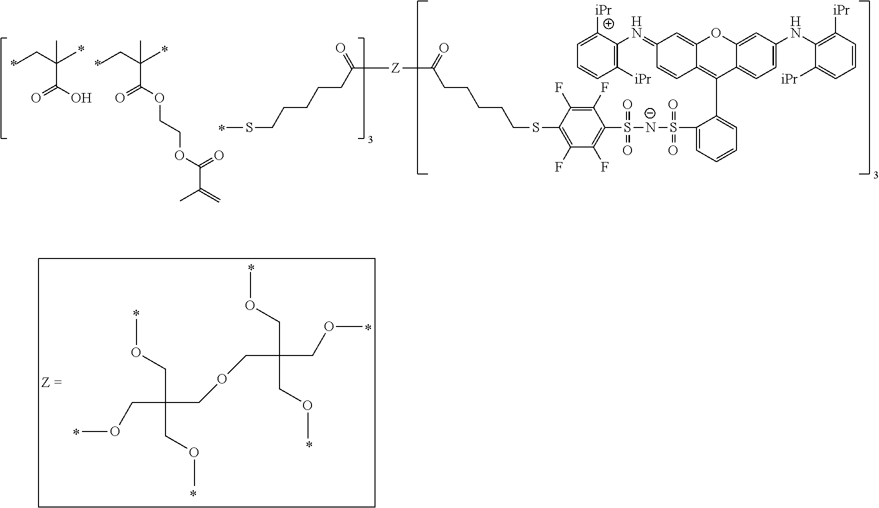

IR coloring agent 1: compound having the following structure

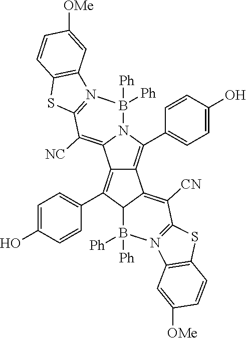

IR coloring agent 2: compound having the following structure

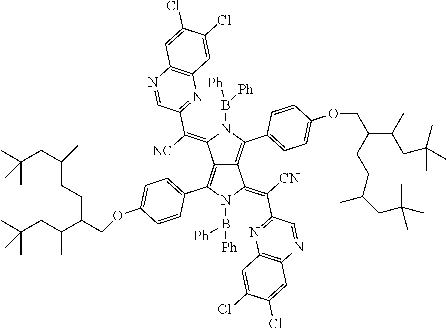 [SMILES: CC(CCC(COc1ccc(-c2c3/c(=C(\C#N)c4cnc5cc(Cl)c(Cl)cc5n4)n(B(c4ccccc4)c4ccccc4)c(-c4ccc(OCC(CCC(C)CC(C)(C)C)C(C)CC(C)(C)C)cc4)c3/c(=C(\C#N)c3cnc4cc(Cl)c(Cl)cc4n3)n2B(c2ccccc2)c2ccccc2)cc1)C(C)CC(C)(C)C)CC(C)(C)C]

IR coloring agent 3: compound having the following structure

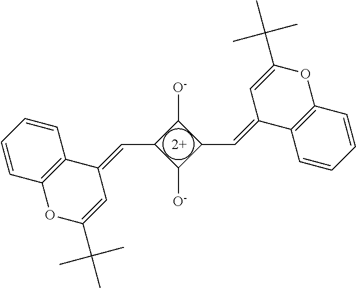

Perylene black: compound having the following structure

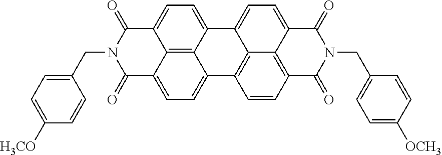 [SMILES: COc1ccc(CN2C(=O)c3ccc4c5ccc6c7c(ccc(c8ccc(c3c48)C2=O)c75)C(=O)N(Cc2ccc(OC)cc2)C6=O)cc1]

Bisbenzofuranone: compound having the following structure

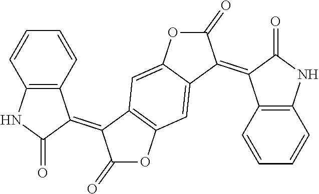 [SMILES: O=C1Nc2ccccc2/C1=C1/C(=O)Oc2cc3c(cc21)OC(=O)/C3=C1\C(=O)Nc2ccccc21]

<<<Pigment Derivative of Examples>>>

With regard to each pigment derivative described below, the maximum value (max) of a molar light absorption coefficient in a wavelength range of 400 to 700 nm was measured as follows. 20 mg of each compound was dissolved in 200 mL of methanol, and methanol was added to 2 mL of this solution so as to be 50 mL. The absorbance of this solution was measured in a wavelength range of 200 to 800 nm using Cary 5000 UV-Vis-NIR spectrophotometer (manufactured by Agilent Technologies, Inc.), and the maximum value of this measured value was standardized by molar concentration to calculate εmax.
Pigment derivative 1: compound C-1 in Table 1 described above (max: 100 L·mol⁻¹·cm⁻¹ or less, basic)
Pigment derivative 2: compound C-20 in Table 1 described above (εmax: more than 1000 L·mol⁻¹·cm⁻¹ and 3000 L·mol⁻¹·cm⁻¹ or less, basic)
Pigment derivative 3: compound C-36 in Table 1 described above (εmax: 100 L·mol⁻¹·cm⁻¹ or less, basic)
Pigment derivative 4: compound C-51 in Table 1 described above (εmax: more than 100 L·mol⁻¹·cm⁻¹ and 1000 L·mol⁻¹·cm⁻¹ or less, basic)
Pigment derivative 5: compound C-87 in Table 1 described above (εmax: 100 L·mol⁻¹·cm⁻¹ or less, basic)
Pigment derivative 6: compound having the following structure (εmax: 100 L·mol⁻¹·cm⁻¹ or less, acidic)
Pigment derivative 7: compound having the following structure (εmax: 100 L·mol⁻¹·cm⁻¹ or less, acidic)
Pigment derivative 8: compound having the following structure (εmax: 100 L·mol⁻¹·cm⁻¹ or less, acidic)
Pigment derivative 9: compound having the following structure (εmax: 100 L·mol⁻¹·cm⁻¹ or less, acidic)
Pigment derivative 10: compound having the following structure (εmax: 100 L·mol⁻¹·cm⁻¹ or less, acidic)
Pigment derivative A: compound having the following structure (yellow, basic)

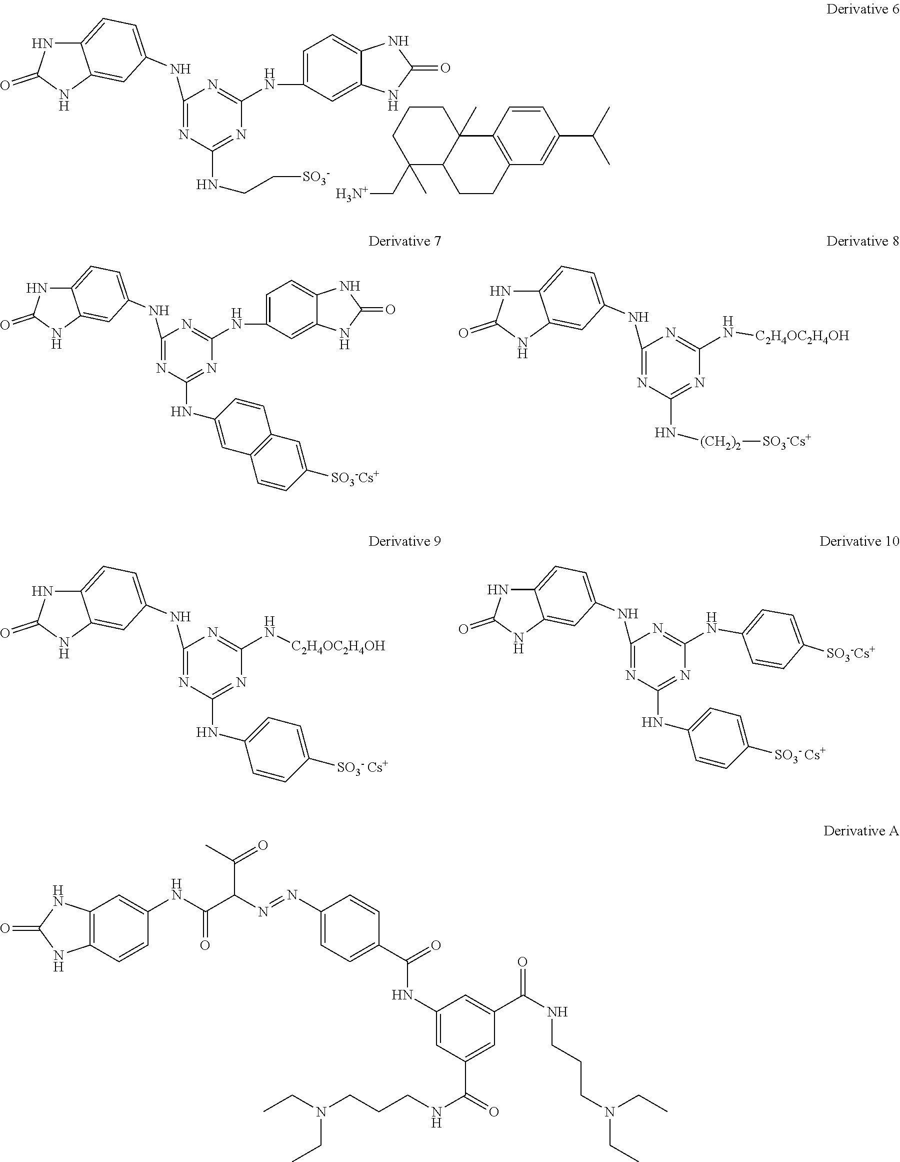

<<<Pigment Derivative of Comparative Examples>>>

With regard to each pigment derivative described below, εmax was measured in the same manner as in the pigment derivatives of Examples. All pigment derivatives were colored, and εmax thereof was more than 3000 L·mol⁻¹·cm⁻¹.
Comparative derivative 1: compound having the following structure (yellow, basic)
Comparative derivative 2: compound having the following structure (red, basic)
Comparative derivative 3: compound having the following structure (yellow, basic)
Comparative derivative 4: compound having the following structure (blue, basic)
Comparative derivative 5: compound having the following structure (violet, basic)

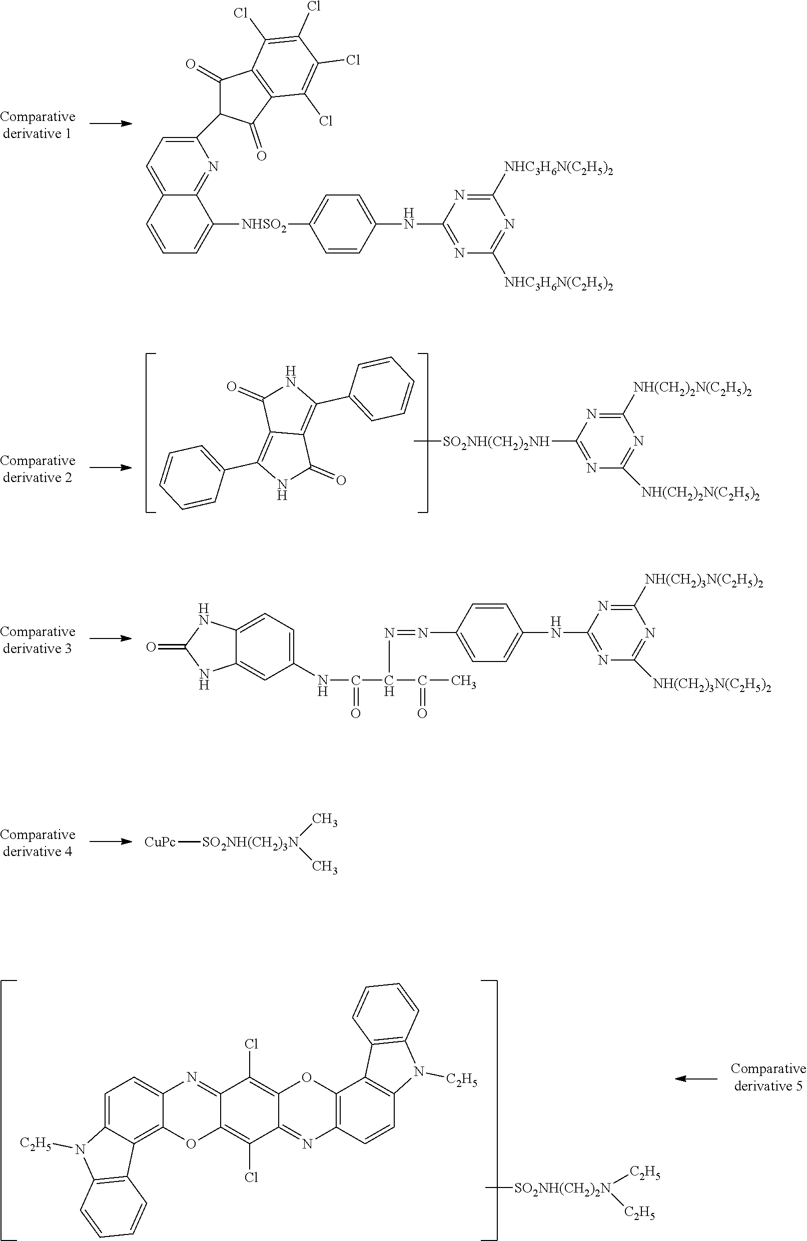

<<<Dispersant>>>
Dispersant 1: compound having the following structure (acidic; the numerical value described together with the main chain indicates a molar ratio of a repeating unit, and the numerical value described together with the side chain indicates the number of repeating units)

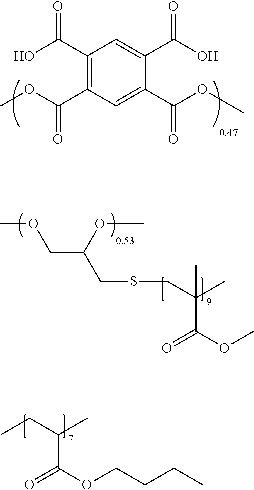

Dispersant 2: compound having the following structure (the numerical value described together with the main chain indicates a molar ratio of a repeating unit, and the numerical value described together with the side chain indicates the number of repeating units; Mw: 20000, C═C value: 0.4 mmol/g, acid value: 70 mgKOH/g)

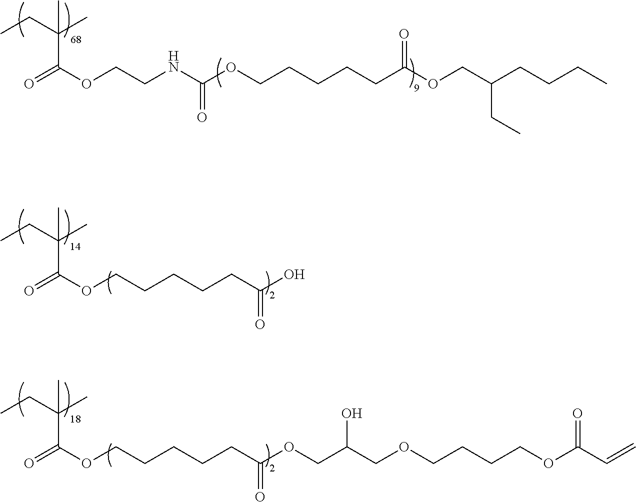

Dispersant 3: compound having the following structure (k:l:m:n=25:40:5:30 (polymerization molar ratio), p=60, q=60, weight-average molecular weight: 10,000, basic)

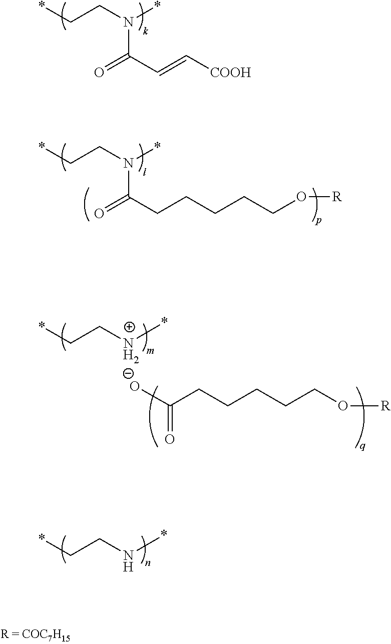

<<<Resin>>>
Resin 1: compound having the following structure (the numerical value described together with the main chain indicates a molar ratio of a repeating unit)

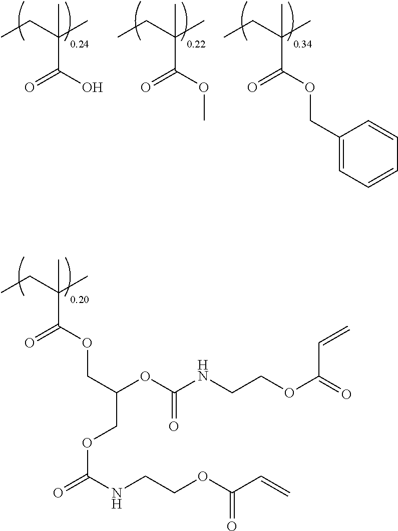

Resin 2: compound having the following structure (the numerical value described together with the main chain indicates a molar ratio of a repeating unit)

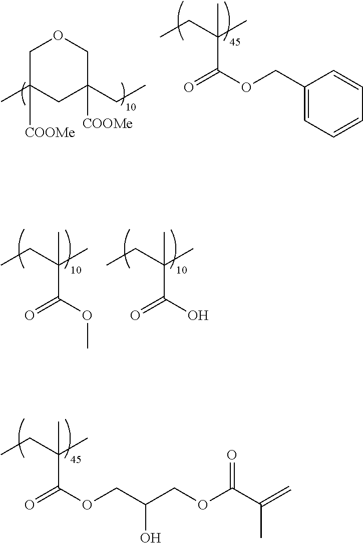

<<<Polymerizable Monomer>>>
Polymerizable monomer 1: compound having the following structure

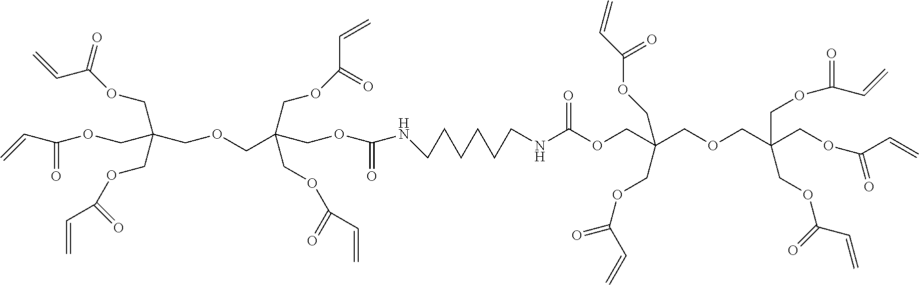 [SMILES: C=CC(=O)OCC(COCC(COC(=O)C=C)(COC(=O)C=C)COC(=O)NCCCCCCNC(=O)OCC(COCC(COC(=O)C=C)(COC(=O)C=C)COC(=O)C=C)(COC(=O)C=C)COC(=O)C=C)(COC(=O)C=C)COC(=O)C=C]

Polymerizable monomer 2: compound having the following structure

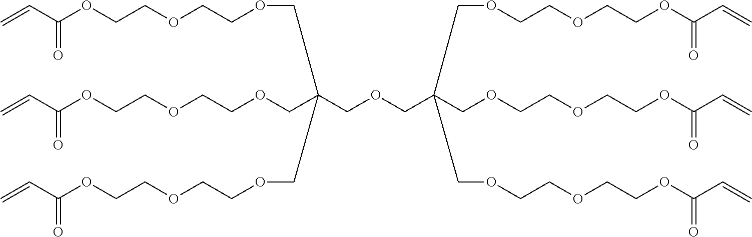 [SMILES: C=CC(=O)OCCOCCOCC(COCCOCCOC(=O)C=C)(COCCOCCOC(=O)C=C)COCC(COCCOCCOC(=O)C=C)(COCCOCCOC(=O)C=C)COCCOCCOC(=O)C=C]

Polymerizable monomer 3: mixture of two compounds having the following structures (molar ratio of left side and right side: 7:3)

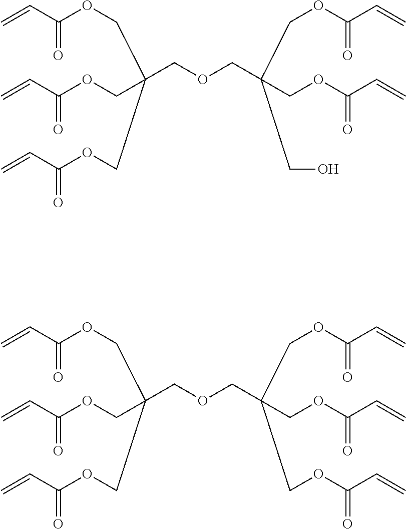

<<<Photopolymerization Initiator>>>
Photopolymerization initiator 1: compound having the following structure

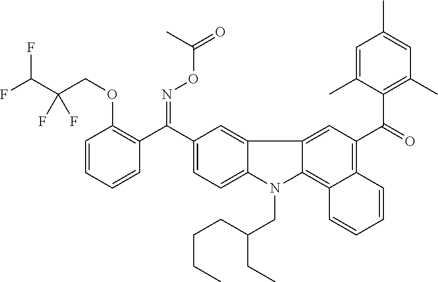 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21]

Photopolymerization initiator 2: compound having the following structure

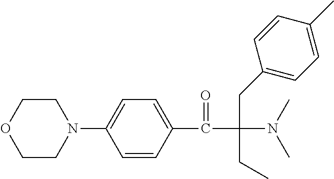 [SMILES: CCC(Cc1ccc(C)cc1)(C(=O)c1ccc(N2CCOCC2)cc1)N(C)C]

Photopolymerization initiator 3: compound having the following structure

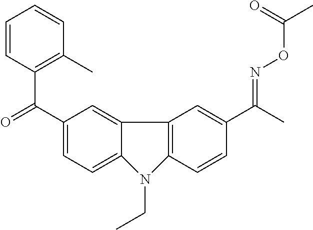 [SMILES: CCn1c2ccc(C(=O)c3ccccc3C)cc2c2cc(/C(C)=N/OC(C)=O)ccc21]

<<<Surfactant>>>
Surfactant 1: mixture of two compounds having the following structures (Mw=14000, described in % by mass)

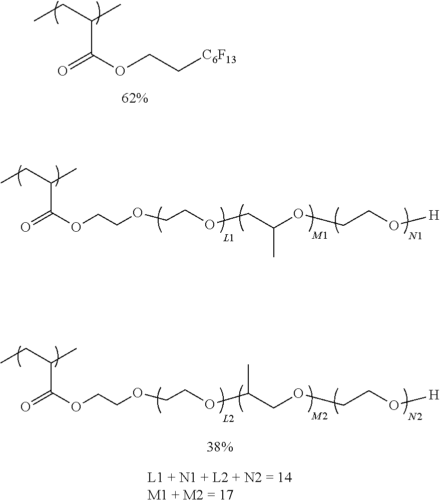

<<<Ultraviolet Absorber>>>
Ultraviolet absorber 1: compound having the following structure

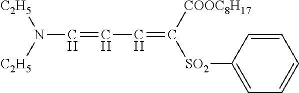

<<<Epoxy Resin>>>
Epoxy resin 1: EHPE 3150 (manufactured by DAICEL-ALLNEX LTD.; 1,2-epoxy-4-(2-oxiranyl)cyclohexane adduct of 2,2′-bis(hydroxymethyl)-1-butanol)

<<<Silane Coupling Agent>>>
Silane coupling agent 1: compound having the following structure (Mw=14000, described in % by mass)

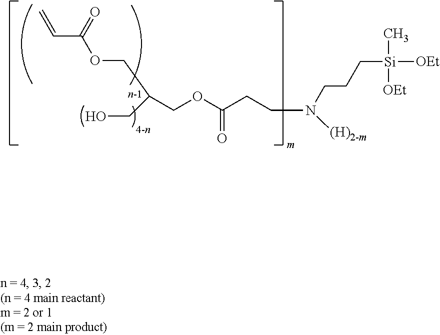

<<<Solvent>>>
PGMEA: propylene glycol monomethyl ether acetate
EEP: ethyl 3-ethoxypropionate

<<Green Composition G1>>

(Production of Pigment Dispersion Liquid G1)

A mixed solution obtained by mixing the following raw materials was mixed and dispersed for 3 hours using a beads mill (zirconia beads having a diameter of 0.1 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was dispersed under a pressure of 2000 kg/cm³ at a flow rate of 500 g/min. This dispersion treatment was repeated up to 10 times, thereby obtaining a pigment dispersion liquid G1.

Raw Materials of Dispersion Liquid:

| | |
|---|---|
| PG58 | 8.5 parts by mass |
| PY185 | 2.9 parts by mass |
| Pigment derivative 1 | 1.6 parts by mass |
| Dispersant 1 | 4.7 parts by mass |
| PGMEA | 82.3 parts by mass |

(Production of Green Composition G1)

Subsequently, after stirring a mixed solution obtained by mixing the following raw materials, the obtained mixed solution was filtered through a nylon filter (manufactured by Pall Corporation) having a pore size of 0.45 μm to obtain a green composition G1.

Raw Materials of Composition:

| | |
|---|---|
| Pigment dispersion liquid G1 | 69.0 parts by mass |
| Resin 1 (40% by mass PGMEA solution) | 1.2 parts by mass |
| Polymerizable monomer 1 | 1.1 parts by mass |
| Photopolymerization initiator 1 | 0.5 parts by mass |
| Surfactant 1 (1% by mass PGME solution) | 4.2 parts by mass |
| Ultraviolet absorber 1 | 0.5 parts by mass |
| Epoxy resin 1 | 0.2 parts by mass |
| PGMEA | 23.3 parts by mass |

<<Green Composition G4>>

(Production of Pigment Dispersion Liquid G4)

Raw materials having the same components and formulation as the raw materials of the pigment dispersion liquid G1 were used, except that the type of the green pigment was changed to PG36. A pigment dispersion liquid G4 was obtained by the same procedure as the method for producing the pigment dispersion liquid G1.

(Production of Green Composition G4)

Subsequently, after stirring a mixed solution obtained by mixing the following raw materials, the obtained mixed solution was filtered through a nylon filter (manufactured by Pall Corporation) having a pore size of 0.45 μm to obtain a green composition G4.

Raw Materials of Composition:

| | |
|---|---|
| Pigment dispersion liquid G4 | 46.0 parts by mass |
| Resin 1 (40% by mass PGMEA solution) | 8.6 parts by mass |
| Polymerizable monomer 1 | 1.7 parts by mass |
| Photopolymerization initiator 1 | 0.8 parts by mass |
| Surfactant 1 (1% by mass PGMEA solution) | 4.2 parts by mass |
| Ultraviolet absorber 1 | 0.8 parts by mass |
| Epoxy resin 1 | 0.2 parts by mass |
| PGMEA | 37.7 parts by mass |

<<Green Composition G5>>

(Production of Pigment Dispersion Liquid G5)

Using the same raw materials as the raw materials of the pigment dispersion liquid G4, a pigment dispersion liquid G5 was obtained by the same procedure as the method for producing the pigment dispersion liquid G4.

(Production of Green Composition G5)

Subsequently, after stirring a mixed solution obtained by mixing the following raw materials, the obtained mixed solution was filtered through a nylon filter (manufactured by Pall Corporation) having a pore size of 0.45 μm to obtain a green composition G5.

Raw Materials of Composition:

| | |
|---|---|
| Pigment dispersion liquid G5 | 28.8 parts by mass |
| Resin 1 (40% by mass PGMEA solution) | 14.0 parts by mass |
| Polymerizable monomer 1 | 2.1 parts by mass |
| Photopolymerization initiator 1 | 1.0 part by mass |
| Surfactant 1 (1% by mass PGMEA solution) | 4.2 parts by mass |
| Ultraviolet absorber 1 | 1.1 parts by mass |
| Epoxy resin 1 | 0.2 parts by mass |
| PGMEA | 48.6 parts by mass |

<<Green Composition G20>>

(Production of Pigment Dispersion Liquid G20)

A pigment dispersion liquid G20 was obtained by the same procedure as the method for producing the pigment dispersion liquid G1, except that the raw materials of the dispersion liquid were changed to the following raw materials.

Raw Materials of Dispersion Liquid:

| | |
|---|---|
| PG58 | 8.1 parts by mass |
| PY185 | 1.5 parts by mass |
| PY150 | 1.8 parts by mass |
| Pigment derivative 1 | 1.6 parts by mass |
| Dispersant 1 | 4.7 parts by mass |
| PGMEA | 82.3 parts by mass |

(Production of Green Composition G20)

A green composition G20 was obtained by the same procedure as the method for producing the green composition G1, except that the pigment dispersion liquid G1 was changed to the pigment dispersion liquid G20.

<<Green Composition G21>>

(Production of Pigment Dispersion Liquid G21)

A pigment dispersion liquid G21 was obtained by the same procedure as the method for producing the pigment dispersion liquid G1, except that the raw materials of the dispersion liquid were changed to the following raw materials.

Raw Materials of Dispersion Liquid:

| | |
|---|---|
| PG36 | 8.0 parts by mass |
| PY185 | 1.5 parts by mass |
| PY150 | 1.9 parts by mass |
| Pigment derivative 1 | 1.6 parts by mass |
| Dispersant 1 | 4.7 parts by mass |
| PGMEA | 82.3 parts by mass |

(Production of Green Composition G21)

Subsequently, after stirring a mixed solution obtained by mixing the following raw materials, the obtained mixed solution was filtered through a nylon filter (manufactured by Pall Corporation) having a pore size of 0.45 μm to obtain a green composition G21.

Raw Materials of Composition:

| | |
|---|---|
| Pigment dispersion liquid G21 | 69.0 parts by mass |
| Resin 1 (40% by mass PGMEA solution) | 1.2 parts by mass |
| Polymerizable monomer 1 | 1.1 parts by mass |
| Photopolymerization initiator 3 | 0.5 parts by mass |
| Surfactant 1 (1% by mass PGMEA solution) | 4.2 parts by mass |
| Ultraviolet absorber 1 | 0.5 parts by mass |
| Epoxy resin 1 | 0.2 parts by mass |
| PGMEA | 23.3 parts by mass |

<<Green Composition G22>>

(Production of Pigment Dispersion Liquid G22)

A pigment dispersion liquid G22 was obtained by the same procedure as the method for producing the pigment dispersion liquid G21, except that the raw materials of the dispersion liquid were changed to the following raw materials.

Raw Materials of Dispersion Liquid:

| | |
|---|---|
| PG36 | 8.5 parts by mass |
| PY185 | 2.9 parts by mass |
| Pigment derivative 1 | 0.7 parts by mass |
| Pigment derivative A | 0.9 parts by mass |
| Dispersant 1 | 4.7 parts by mass |
| PGMEA | 82.3 parts by mass |

(Production of Green Composition G22)

A green composition G22 was obtained by the same procedure as the method for producing the green composition G21, except that the pigment dispersion liquid G21 was changed to the pigment dispersion liquid G22.

<<Green Composition G23>>

(Production of Pigment Dispersion Liquid G23)

A pigment dispersion liquid G23 was obtained by the same procedure as the method for producing the pigment dispersion liquid G22, except that the formulation of the pigment derivative occupying 1.6 parts by mass of the pigment dispersion liquid was changed as follows.

| | |
|---|---|
| Pigment derivative 1 | 1.0 part by mass |
| Pigment derivative A | 0.6 parts by mass |

(Production of Green Composition G23)

A green composition G23 was obtained by the same procedure as the method for producing the green composition G21, except that the pigment dispersion liquid G21 was changed to the pigment dispersion liquid G23.

<<Green Composition G24>>

(Production of Pigment Dispersion Liquid G24)

A pigment dispersion liquid G24 was obtained by the same procedure as the method for producing the pigment dispersion liquid G21, except that the raw materials of the dispersion liquid were changed to the following raw materials.

Raw Materials of Dispersion Liquid:

| | |
|---|---|
| PG36 | 8.0 parts by mass |
| PY185 | 0.9 parts by mass |
| PY150 | 2.5 parts by mass |
| Pigment derivative 1 | 1.0 part by mass |
| Pigment derivative A | 0.6 parts by mass |
| Dispersant 1 | 4.7 parts by mass |
| PGMEA | 82.3 parts by mass |

(Production of Green Composition G24)

A green composition G24 was obtained by the same procedure as the method for producing the green composition G21, except that the pigment dispersion liquid G21 was changed to the pigment dispersion liquid G24.

<<Green Compositions G2, G3, and G6 to G19, and Compositions of Comparative Examples>>

Green compositions G2, G3, and G6 to G19, and green compositions of Comparative Examples (comparative compositions G1 to G3, and G6 to G14) were obtained by the same components, formulation, and procedure as in the case of the green composition G1, except that the types of the components of the dispersion liquid and the composition were changed as shown in Table 2. Regarding the coloring material, the corresponding components were changed for each of the columns of “Coloring material 1”, “Coloring material 2”, and “Coloring material 3” in the table. The same applies to other compositions.

In addition, a comparative composition G4 was obtained by the same components, formulation, and procedure as the case of the green composition G4, except that the type of the pigment derivative was changed as shown in Table 2. In addition, a comparative composition G5 was obtained by the same components, formulation, and procedure as the case of the green composition G5, except that the type of the pigment derivative was changed as shown in Table 2.

Table 2 shows the characteristic components of each of the above-described green compositions. In Table 2, the description of the surfactant, the ultraviolet absorber, the epoxy resin, and PGMEA is omitted because these components are common components in all the compositions. In addition, for each composition, the total content (pigment concentration) of the pigment and the pigment derivative with respect to the total solid content of the composition is also shown in the table. Each numerical value in parentheses in the item of the pigment derivative represents a proportion (parts by mass) of the pigment derivative 1 or the pigment derivative A in the dispersion liquid.

TABLE 2
Green composition

| | Solid content in pigment dispersion liquid | | | | | Solid content in additive | | | |
|---|---|---|---|---|---|---|---|---|---|
| | Coloring | Coloring | Coloring | | | | Polymerizable | | Pigment |
| | material 1 | material 2 | material 3 | Pigment derivative | Dispersant | Resin | monomer | Initiator | concentration |
| Composition G1 | PG58 | PY185 | — | Derivative 1 | Dispersant 1 | Resin 1 | Monomer 1 | Initiator 1 | 60 |
| Composition G2 | PG36 | PY150 | — | Derivative 1 | Dispersant 1 | Resin 2 | Monomer 3 | Initiator 3 | |
| Composition G3 | PG36 | PY185 | — | Derivative 1 | Dispersant 1 | Resin 1 | Monomer 1 | Initiator 3 | |
| Composition G4 | PG36 | PY185 | — | Derivative 1 | Dispersant 1 | Resin 1 | Monomer 1 | Initiator 1 | 40 |
| Composition G5 | PG36 | PY185 | — | Derivative 1 | Dispersant 1 | Resin 1 | Monomer 1 | Initiator 1 | 25 |
| Composition G6 | PG36 | PY185 | — | Derivative 2 | Dispersant 1 | Resin 1 | Monomer 3 | Initiator 2 | 60 |
| Composition G7 | PG36 | PY185 | — | Derivative 3 | Dispersant 1 | Resin 2 | Monomer 1 | Initiator 1 | |
| Composition G8 | PG36 | PY185 | — | Derivative 4 | Dispersant 1 | Resin 1 | Monomer 1 | Initiator 2 | |
| Composition G9 | PG36 | PY185 | — | Derivative 5 | Dispersant 1 | Resin 1 | Monomer 2 | Initiator 3 | |
| Composition G10 | PG36 | PY185 | — | Derivative 1 | Dispersant 2 | Resin 2 | Monomer 3 | Initiator 1 | |
| Composition G11 | PG36 | PY185 | — | Derivative 2 | Dispersant 2 | Resin 1 | Monomer 1 | Initiator 3 | |
| Composition G12 | PG36 | PY185 | — | Derivative 3 | Dispersant 2 | Resin 2 | Monomer 3 | Initiator 3 | |
| Composition G13 | PG36 | PY185 | — | Derivative 4 | Dispersant 2 | Resin 2 | Monomer 2 | Initiator 1 | |
| Composition G14 | PG36 | PY185 | — | Derivative 5 | Dispersant 2 | Resin 1 | Monomer 1 | Initiator 3 | |
| Composition G15 | PG36 | PY185 | — | Derivative 6 | Dispersant 3 | Resin 2 | Monomer 3 | Initiator 1 | |
| Composition G16 | PG36 | PY185 | — | Derivative 7 | Dispersant 3 | Resin 1 | Monomer 1 | Initiator 2 | |
| Composition G17 | PG36 | PY185 | — | Derivative 8 | Dispersant 3 | Resin 1 | Monomer 3 | Initiator 3 | |
| Composition G18 | PG36 | PY185 | — | Derivative 9 | Dispersant 3 | Resin 2 | Monomer 1 | Initiator 2 | |
| Composition G19 | PG36 | PY185 | — | Derivative 10 | Dispersant 3 | Resin 1 | Monomer 1 | Initiator 2 | |
| Composition G20 | PG58 | PY185 | PY150 | Derivative 1 | Dispersant 1 | Resin 1 | Monomer 1 | Initiator 1 | |
| Composition G21 | PG36 | PY185 | PY150 | Derivative 1 | Dispersant 1 | Resin 1 | Monomer 1 | Initiator 3 | |
| Composition G22 | PG36 | PY185 | — | Derivative 1 (0.7) | Dispersant 1 | Resin 1 | Monomer 1 | Initiator 3 | |
| | | | | Derivative A (0.9) | | | | | |
| Composition G23 | PG36 | PY185 | — | Derivative 1 (1.0) | Dispersant 1 | Resin 1 | Monomer 1 | Initiator 3 | |
| | | | | Derivative A (0.6) | | | | | |
| Composition G24 | PG36 | PY185 | PY150 | Derivative 1 (1.0) | Dispersant 1 | Resin 1 | Monomer 1 | Initiator 3 | |
| | | | | Derivative A (0.06) | | | | | |
| Comparative | PG58 | PY185 | — | Comparative | Dispersant 1 | Resin 1 | Monomer 1 | Initiator 1 | 60 |
| composition G1 | | | | derivative 1 | | | | | |
| Comparative | PG36 | PY150 | — | Comparative | Dispersant 1 | Resin 1 | Monomer 1 | Initiator 1 | |
| composition G2 | | | | derivative 1 | | | | | |
| Comparative | PG36 | PY185 | — | Comparative | Dispersant 1 | Resin 1 | Monomer 1 | Initiator 1 | |
| composition G3 | | | | derivative 1 | | | | | |
| Comparative | PG36 | PY185 | — | Comparative | Dispersant 1 | Resin 1 | Monomer 1 | Initiator 1 | 40 |
| composition G4 | | | | derivative 1 | | | | | |
| Comparative | PG36 | PY185 | — | Comparative | Dispersant 1 | Resin 1 | Monomer 1 | Initiator 1 | 25 |
| composition G5 | | | | derivative 1 | | | | | |
| Comparative | PG36 | PY185 | — | Comparative | Dispersant 1 | Resin 1 | Monomer 1 | Initiator 1 | 60 |
| composition G6 | | | | derivative 2 | | | | | |
| Comparative | PG36 | PY185 | — | Comparative | Dispersant 1 | Resin 1 | Monomer 1 | Initiator 1 | |
| composition G7 | | | | derivative 3 | | | | | |
| Comparative | PG36 | PY185 | — | Comparative | Dispersant 1 | Resin 1 | Monomer 1 | Initiator 1 | |
| composition G8 | | | | derivative 4 | | | | | |
| Comparative | PG36 | PY185 | — | Comparative | Dispersant 1 | Resin 1 | Monomer 1 | Initiator 1 | |
| composition G9 | | | | derivative 5 | | | | | |
| Comparative | PG36 | PY185 | — | Comparative | Dispersant 2 | Resin 1 | Monomer 1 | Initiator 1 | |
| composition G10 | | | | derivative 1 | | | | | |
| Comparative | PG36 | PY185 | — | Comparative | Dispersant 2 | Resin 1 | Monomer 1 | Initiator 1 | |
| composition G11 | | | | derivative 2 | | | | | |
| Comparative | PG36 | PY185 | — | Comparative | Dispersant 2 | Resin 1 | Monomer 1 | Initiator 1 | |
| composition G12 | | | | derivative 3 | | | | | |
| Comparative | PG36 | PY185 | — | Comparative | Dispersant 2 | Resin 1 | Monomer 1 | Initiator 1 | |
| composition G13 | | | | derivative 4 | | | | | |
| Comparative | PG36 | PY185 | — | Comparative | Dispersant 2 | Resin 1 | Monomer 1 | Initiator 1 | |
| composition G14 | | | | derivative 5 | | | | | |

<<Red Composition R1>>

(Production of Pigment Dispersion Liquid R1)

A mixed solution obtained by mixing the following raw materials was mixed and dispersed for 3 hours using a beads mill (zirconia beads having a diameter of 0.1 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was dispersed under a pressure of 2000 kg/cm³ at a flow rate of 500 g/min. This dispersion treatment was repeated up to 10 times, thereby obtaining a pigment dispersion liquid R1.

Raw Materials of Dispersion Liquid:

| | |
|---|---|
| PR254 | 10.5 parts by mass |
| PY139 | 0.9 parts by mass |
| Pigment derivative 1 | 1.6 parts by mass |
| Dispersant 1 | 4.7 parts by mass |
| PGMEA | 82.3 parts by mass |

(Production of Red Composition R1)

Subsequently, after stirring a mixed solution obtained by mixing the following raw materials, the obtained mixed solution was filtered through a nylon filter (manufactured by Pall Corporation) having a pore size of 0.45 μm to obtain a red composition R1.

Raw Materials of Composition:

| | |
|---|---|
| Pigment dispersion liquid R1 | 58.9 parts by mass |
| Resin 1 (40% by mass PGMEA solution) | 2.0 parts by mass |
| Polymerizable monomer 1 | 0.9 parts by mass |
| Photopolymerization initiator 1 | 0.5 parts by mass |
| Surfactant 1 (1% by mass PGMEA solution) | 4.2 parts by mass |
| Ultraviolet absorber 1 | 0.1 parts by mass |
| Epoxy resin 1 | 0.1 parts by mass |
| PGMEA | 33.3 parts by mass |

<<Red Composition R2>>

(Production of Pigment Dispersion Liquid R2)

Raw materials having the same components and formulation as the raw materials of the pigment dispersion liquid R1 were used, except that, with regard to the pigment, half of PR254 was changed to P071. A pigment dispersion liquid R2 was obtained by the same procedure as the method for producing the pigment dispersion liquid R1.

(Production of Red Composition R2)

Subsequently, after stirring a mixed solution obtained by mixing the following raw materials, the obtained mixed solution was filtered through a nylon filter (manufactured by Pall Corporation) having a pore size of 0.45 μm to obtain a red composition R2.

Raw Materials of Composition:

| | |
|---|---|
| Pigment dispersion liquid R2 | 58.9 parts by mass |
| Resin 2 (40% by mass PGMEA solution) | 2.0 parts by mass |
| Polymerizable monomer 2 | 0.9 parts by mass |
| Photopolymerization initiator 3 | 0.5 parts by mass |
| Surfactant 1 (1% by mass PGMEA solution) | 4.2 parts by mass |
| Ultraviolet absorber 1 | 0.1 parts by mass |
| Epoxy resin 1 | 0.1 parts by mass |
| PGMEA | 33.3 parts by mass |

<<Red Composition R4>>

(Production of Pigment Dispersion Liquid R4)

Using the same raw materials as the raw materials of the pigment dispersion liquid R1, a pigment dispersion liquid R4 was obtained by the same procedure as the method for producing the pigment dispersion liquid R1.

(Production of Red Composition R4)

Subsequently, after stirring a mixed solution obtained by mixing the following raw materials, the obtained mixed solution was filtered through a nylon filter (manufactured by Pall Corporation) having a pore size of 0.45 μm to obtain a red composition R4.

Raw Materials of Composition:

| | |
|---|---|
| Pigment dispersion liquid R4 | 39.3 parts by mass |
| Resin 1 (40% by mass PGMEA solution) | 8.5 parts by mass |
| Polymerizable monomer 1 | 1.3 parts by mass |
| Photopolymerization initiator 1 | 0.7 parts by mass |
| Surfactant 1 (1% by mass PGMEA solution) | 4.2 parts by mass |
| Ultraviolet absorber 1 | 0.4 parts by mass |
| Epoxy resin 1 | 0.1 parts by mass |
| PGMEA | 45.5 parts by mass |

<<Red Composition R5>>

(Production of Pigment Dispersion Liquid R5)

Using the same raw materials as the raw materials of the pigment dispersion liquid R1, a pigment dispersion liquid R5 was obtained by the same procedure as the method for producing the pigment dispersion liquid R1.

(Production of Red Composition R5)

Subsequently, after stirring a mixed solution obtained by mixing the following raw materials, the obtained mixed solution was filtered through a nylon filter (manufactured by Pall Corporation) having a pore size of 0.45 μm to obtain a red composition R5.

Raw Materials of Composition:

| | |
|---|---|
| Pigment dispersion liquid R5 | 24.5 parts by mass |
| Resin 1 (40% by mass PGMEA solution) | 13.2 parts by mass |
| Polymerizable monomer 1 | 1.6 parts by mass |
| Photopolymerization initiator 1 | 0.8 parts by mass |
| Surfactant 1 (1% by mass PGMEA solution) | 4.2 parts by mass |
| Ultraviolet absorber 1 | 0.6 parts by mass |
| Epoxy resin 1 | 0.1 parts by mass |
| PGMEA | 55.0 parts by mass |

<<Red Compositions R3 and R6 to R19, and Compositions of Comparative Examples>>

Red compositions R3 and R6 to R19, and red compositions of Comparative Examples (comparative compositions R1 to R3, and R6 to R14) were obtained by the same components, formulation, and procedure as in the case of the red composition R1, except that the types of the components of the dispersion liquid and the composition were changed as shown in Table 3.

In addition, a comparative composition R4 was obtained by the same components, formulation, and procedure as the case of the red composition R4, except that the type of the pigment derivative was changed as shown in Table 3. In addition, a comparative composition R5 was obtained by the same components, formulation, and procedure as the case of the red composition R5, except that the type of the pigment derivative was changed as shown in Table 3.

Table 3 shows the characteristic components of each of the above-described red compositions. In Table 3, the description of the surfactant, the ultraviolet absorber, the epoxy resin, and PGMEA is omitted because these components are common components in all the compositions. In addition, for each composition, the pigment concentration is also shown in the table.

TABLE 3
Red composition

| | Solid content in pigment dispersion liquid | | | | | Solid content in additive | | | |
|---|---|---|---|---|---|---|---|---|---|
| | Coloring | Coloring | Coloring | Pigment | | | Polymerizable | | Pigment |
| | material 1 | material 2 | material 3 | derivative | Dispersant | Resin | monomer | Initiator | concentration |
| Composition R1 | PR254 | PY139 | — | Derivative 1 | Dispersant 1 | Resin 1 | Monomer 1 | Initiator 1 | |
| Composition R2 | PR254 | PY139 | PO71 | Derivative 1 | Dispersant 1 | Resin 2 | Monomer 2 | Initiator 3 | 60 |
| Composition R3 | PR272 | PY139 | — | Derivative 1 | Dispersant 1 | Resin 2 | Monomer 3 | Initiator 3 | |
| Composition R4 | PR254 | PY139 | | Derivative 1 | Dispersant 1 | Resin 1 | Monomer 1 | Initiator 1 | 40 |
| Composition R5 | PR254 | PY139 | | Derivative 1 | Dispersant 1 | Resin 1 | Monomer 1 | Initiator 1 | 25 |
| Composition R6 | PR254 | PY139 | | Derivative 2 | Dispersant 1 | Resin 1 | Monomer 2 | Initiator 2 | 60 |
| Composition R7 | PR254 | PY139 | | Derivative 3 | Dispersant 1 | Resin 1 | Monomer 1 | Initiator 1 | |
| Composition R8 | PR254 | PY139 | | Derivative 4 | Dispersant 1 | Resin 2 | Monomer 3 | Initiator 2 | |
| Composition R9 | PR254 | PY139 | | Derivative 5 | Dispersant 1 | Resin 1 | Monomer 1 | Initiator 3 | |
| Composition R10 | PR254 | PY139 | | Derivative 1 | Dispersant 2 | Resin 2 | Monomer 1 | Initiator 1 | |
| Composition R11 | PR254 | PY139 | | Derivative 2 | Dispersant 2 | Resin 1 | Monomer 3 | Initiator 3 | |
| Composition R12 | PR254 | PY139 | | Derivative 3 | Dispersant 2 | Resin 2 | Monomer 3 | Initiator 3 | |
| Composition R13 | PR254 | PY139 | | Derivative 4 | Dispersant 2 | Resin 1 | Monomer 1 | Initiator 1 | |
| Composition R14 | PR254 | PY139 | | Derivative 5 | Dispersant 2 | Resin 1 | Monomer 3 | Initiator 3 | |
| Composition R15 | PR254 | PY139 | | Derivative 6 | Dispersant 3 | Resin 2 | Monomer 1 | Initiator 1 | |
| Composition R16 | PR254 | PY139 | | Derivative 7 | Dispersant 3 | Resin 1 | Monomer 2 | Initiator 2 | |
| Composition R17 | PR254 | PY139 | | Derivative 8 | Dispersant 3 | Resin 1 | Monomer 3 | Initiator 3 | |
| Composition R18 | PR254 | PY139 | | Derivative 9 | Dispersant 3 | Resin 2 | Monomer 2 | Initiator 2 | |
| Composition R19 | PR254 | PY139 | | Derivative 10 | Dispersant 3 | Resin 1 | Monomer 1 | Initiator 2 | |
| Comparative | PR254 | PY139 | — | Comparative | Dispersant 1 | Resin 1 | Monomer 1 | Initiator 1 | 60 |
| composition R1 | | | | derivative 1 | | | | | |
| Comparative | PR254 | PY139 | PO71 | Comparative | Dispersant 1 | Resin 1 | Monomer 1 | Initiator 1 | |
| composition R2 | | | | derivative 1 | | | | | |
| Comparative | PR272 | PY139 | — | Comparative | Dispersant 1 | Resin 1 | Monomer 1 | Initiator 1 | |
| composition R3 | | | | derivative 1 | | | | | |
| Comparative | PR254 | PY139 | | Comparative | Dispersant 1 | Resin 1 | Monomer 1 | Initiator 1 | 40 |
| composition R4 | | | | derivative 1 | | | | | |
| Comparative | PR254 | PY139 | | Comparative | Dispersant 1 | Resin 1 | Monomer 1 | Initiator 1 | 25 |
| composition R5 | | | | derivative 1 | | | | | |
| Comparative | PR254 | PY139 | | Comparative | Dispersant 1 | Resin 1 | Monomer 1 | Initiator 1 | 60 |
| composition R6 | | | | derivative 2 | | | | | |
| Comparative | PR254 | PY139 | | Comparative | Dispersant 1 | Resin 1 | Monomer 1 | Initiator 1 | |
| composition R7 | | | | derivative 3 | | | | | |
| Comparative | PR254 | PY139 | | Comparative | Dispersant 1 | Resin 1 | Monomer 1 | Initiator 1 | |
| composition R8 | | | | derivative 4 | | | | | |
| Comparative | PR254 | PY139 | | Comparative | Dispersant 1 | Resin 1 | Monomer 1 | Initiator 1 | |
| composition R9 | | | | derivative 5 | | | | | |
| Comparative | PR254 | PY139 | | Comparative | Dispersant 2 | Resin 1 | Monomer 1 | Initiator 1 | |
| composition R10 | | | | derivative 1 | | | | | |
| Comparative | PR254 | PY139 | | Comparative | Dispersant 2 | Resin 1 | Monomer 1 | Initiator 1 | |
| composition R11 | | | | derivative 2 | | | | | |
| Comparative | PR254 | PY139 | | Comparative | Dispersant 2 | Resin 1 | Monomer 1 | Initiator 1 | |
| composition R12 | | | | derivative 3 | | | | | |
| Comparative | PR254 | PY139 | | Comparative | Dispersant 2 | Resin 1 | Monomer 1 | Initiator 1 | |
| composition R13 | | | | derivative 4 | | | | | |
| Comparative | PR254 | PY139 | | Comparative | Dispersant 2 | Resin 1 | Monomer 1 | Initiator 1 | |
| composition R14 | | | | derivative 5 | | | | | |

<<Blue Composition B1>>

(Production of Pigment Dispersion Liquid B1)

A mixed solution obtained by mixing the following raw materials was mixed and dispersed for 3 hours using a beads mill (zirconia beads having a diameter of 0.1 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was dispersed under a pressure of 2000 kg/cm³ at a flow rate of 500 g/min. This dispersion treatment was repeated up to 10 times, thereby obtaining a pigment dispersion liquid B1.

Raw Materials of Dispersion Liquid:

| | |
|---|---|
| PB15:6 | 9.6 parts by mass |
| PV23 | 2.4 parts by mass |
| Pigment derivative 1 | 1.0 part by mass |
| Dispersant 1 | 4.7 parts by mass |
| PGMEA | 82.3 parts by mass |

(Production of Blue Composition B1)

Subsequently, after stirring a mixed solution obtained by mixing the following raw materials, the obtained mixed solution was filtered through a nylon filter (manufactured by Pall Corporation) having a pore size of 0.45 μm to obtain a blue composition B1.

Raw Materials of Composition:

| | |
|---|---|
| Pigment dispersion liquid B1 | 54.1 parts by mass |
| Resin 1 (40% by mass PGMEA solution) | 1.0 part by mass |
| Polymerizable monomer 1 | 0.9 parts by mass |
| Photopolymerization initiator 1 | 0.6 parts by mass |
| Surfactant 1 (1% by mass PGMEA solution) | 4.2 parts by mass |
| Ultraviolet absorber 1 | 0.1 parts by mass |
| Epoxy resin 1 | 0.1 parts by mass |
| PGMEA | 39.0 parts by mass |

<<Blue Composition B3>>

(Production of Pigment Dispersion Liquid B3)

Using the same raw materials as the raw materials of the pigment dispersion liquid B1, a pigment dispersion liquid B3 was obtained by the same procedure as the method for producing the pigment dispersion liquid B1.

(Production of Blue Composition B3)

Subsequently, after stirring a mixed solution obtained by mixing the following raw materials, the obtained mixed solution was filtered through a nylon filter (manufactured by Pall Corporation) having a pore size of 0.45 μm to obtain a blue composition B3.

Raw Materials of Composition:

| | |
|---|---|
| Pigment dispersion liquid B3 | 36.0 parts by mass |
| Resin 1 (40% by mass PGMEA solution) | 6.6 parts by mass |
| Polymerizable monomer 1 | 1.3 parts by mass |
| Photopolymerization initiator 1 | 0.9 parts by mass |
| Surfactant 1 (1% by mass PGMEA solution) | 4.2 parts by mass |
| Ultraviolet absorber 1 | 0.4 parts by mass |
| Epoxy resin 1 | 0.1 parts by mass |
| PGMEA | 50.5 parts by mass |

<<Blue Composition B4>>

(Production of Pigment Dispersion Liquid B4)

Using the same raw materials as the raw materials of the pigment dispersion liquid B1, a pigment dispersion liquid B4 was obtained by the same procedure as the method for producing the pigment dispersion liquid B1.

(Production of Blue Composition B4)

Subsequently, after stirring a mixed solution obtained by mixing the following raw materials, the obtained mixed solution was filtered through a nylon filter (manufactured by Pall Corporation) having a pore size of 0.45 μm to obtain a blue composition B4.

Raw Materials of Composition:

| | |
|---|---|
| Pigment dispersion liquid B4 | 22.5 parts by mass |
| Resin 1 (40% by mass PGMEA solution) | 10.7 parts by mass |
| Polymerizable monomer 1 | 1.6 parts by mass |
| Photopolymerization initiator 1 | 1.2 parts by mass |
| Surfactant 1 (1% by mass PGMEA solution) | 4.2 parts by mass |
| Ultraviolet absorber 1 | 0.6 parts by mass |
| Epoxy resin 1 | 0.1 parts by mass |
| PGMEA | 59.1 parts by mass |

<<Blue Compositions B2 and B5 to B18, and Compositions of Comparative Examples>>

Blue compositions R2 and B5 to B18, and blue compositions of Comparative Examples (comparative compositions B1, B2, and B5 to B13) were obtained by the same components, formulation, and procedure as in the case of the blue composition B1, except that the types of the components of the dispersion liquid and the composition were changed as shown in Table 4.

In addition, a comparative composition B3 was obtained by the same components, formulation, and procedure as the case of the blue composition B3, except that the type of the pigment derivative was changed as shown in Table 4. In addition, a comparative composition B4 was obtained by the same components, formulation, and procedure as the case of the blue composition B4, except that the type of the pigment derivative was changed as shown in Table 4.

Table 4 shows the characteristic components of each of the above-described blue compositions. In Table 4, the description of the surfactant, the ultraviolet absorber, the epoxy resin, and PGMEA is omitted because these components are common components in all the compositions. In addition, for each composition, the pigment concentration is also shown in the table.

TABLE 4
Blue composition

| | Solid content in pigment dispersion liquid | | | | Solid content in additive | | | |
|---|---|---|---|---|---|---|---|---|
| | Coloring | Coloring | Pigment | | | Polymerizable | | Pigment |
| | material 1 | material 2 | derivative | Dispersant | Resin | monomer | Initiator | concentration |
| Composition B1 | PB15:6 | PV23 | Derivative 1 | Dispersant 1 | Resin 1 | Monomer 1 | Initiator 1 | 60 |
| Composition B2 | PB15:6 | Xanthene | Derivative 1 | Dispersant 1 | Resin 2 | Monomer 3 | Initiator 3 | |
| Composition B3 | PB15:6 | PV23 | Derivative 1 | Dispersant 1 | Resin 1 | Monomer 1 | Initiator 1 | 40 |
| Composition B4 | PB15:6 | PV23 | Derivative 1 | Dispersant 1 | Resin 1 | Monomer 1 | Initiator 1 | 25 |
| Composition B5 | PB15:6 | PV23 | Derivative 2 | Dispersant 1 | Resin 1 | Monomer 1 | Initiator 2 | 60 |
| Composition B6 | PB15:6 | PV23 | Derivative 3 | Dispersant 1 | Resin 2 | Monomer 2 | Initiator 1 | |
| Composition B7 | PB15:6 | PV23 | Derivative 4 | Dispersant 1 | Resin 1 | Monomer 1 | Initiator 3 | |
| Composition B8 | PB15:6 | PV23 | Derivative 5 | Dispersant 1 | Resin 2 | Monomer 1 | Initiator 1 | |
| Composition B9 | PB15:6 | PV23 | Derivative 1 | Dispersant 2 | Resin 1 | Monomer 2 | Initiator 2 | |
| Composition B10 | PB15:6 | PV23 | Derivative 2 | Dispersant 2 | Resin 2 | Monomer 1 | Initiator 1 | |
| Composition B11 | PB15:6 | PV23 | Derivative 3 | Dispersant 2 | Resin 2 | Monomer 3 | Initiator 1 | |
| Composition B12 | PB15:6 | PV23 | Derivative 4 | Dispersant 2 | Resin 2 | Monomer 1 | Initiator 3 | |
| Composition B13 | PB15:6 | PV23 | Derivative 5 | Dispersant 2 | Resin 1 | Monomer 1 | Initiator 1 | |
| Composition B14 | PB15:6 | PV23 | Derivative 6 | Dispersant 3 | Resin 1 | Monomer 3 | Initiator 2 | |
| Composition B15 | PB15:6 | PV23 | Derivative 7 | Dispersant 3 | Resin 1 | Monomer 1 | Initiator 3 | |
| Composition B16 | PB15:6 | PV23 | Derivative 8 | Dispersant 3 | Resin 2 | Monomer 3 | Initiator 2 | |
| Composition B17 | PB15:6 | PV23 | Derivative 9 | Dispersant 3 | Resin 1 | Monomer 1 | Initiator 1 | |
| Composition B18 | PB15:6 | PV23 | Derivative 10 | Dispersant 3 | Resin 1 | Monomer 2 | Initiator 3 | |
| Comparative | PB15:6 | PV23 | Comparative | Dispersant 1 | Resin 1 | Monomer 1 | Initiator 1 | 60 |
| composition B1 | | | derivative 1 | | | | | |
| Comparative | PB15:6 | Xanthene | Comparative | Dispersant 1 | Resin 1 | Monomer 1 | Initiator 1 | |
| composition B2 | | | derivative 1 | | | | | |
| Comparative | PB15:6 | PV23 | Comparative | Dispersant 1 | Resin 1 | Monomer 1 | Initiator 1 | 40 |
| composition B3 | | | derivative 1 | | | | | |
| Comparative | PB15:6 | PV23 | Comparative | Dispersant 1 | Resin 1 | Monomer1 | Initiator 1 | 25 |
| composition B4 | | | derivative 1 | | | | | |
| Comparative | PB15:6 | PV23 | Comparative | Dispersant 1 | Resin 1 | Monomer 1 | Initiator 1 | 60 |
| composition B5 | | | derivative 2 | | | | | |
| Comparative | PB15:6 | PV23 | Comparative | Dispersant 1 | Resin 1 | Monomer 1 | Initiator 1 | |
| composition B6 | | | derivative 3 | | | | | |
| Comparative | PB15:6 | PV23 | Comparative | Dispersant 1 | Resin 1 | Monomer 1 | Initiator 1 | |
| composition B7 | | | derivative 4 | | | | | |
| Comparative | PB15:6 | PV23 | Comparative | Dispersant 1 | Resin 1 | Monomer 1 | Initiator 1 | |
| composition B8 | | | derivative 5 | | | | | |
| Comparative | PB15:6 | PV23 | Comparative | Dispersant 2 | Resin 1 | Monomer 1 | Initiator 1 | |
| composition B9 | | | derivative 1 | | | | | |
| Comparative | PB15:6 | PV23 | Comparative | Dispersant 2 | Resin 1 | Monomer 1 | Initiator 1 | |
| composition B10 | | | derivative 2 | | | | | |
| Comparative | PB15:6 | PV23 | Comparative | Dispersant 2 | Resin 1 | Monomer 1 | Initiator 1 | |
| composition B11 | | | derivative 3 | | | | | |
| Comparative | PB15:6 | PV23 | Comparative | Dispersant 2 | Resin 1 | Monomer 1 | Initiator 1 | |
| composition B12 | | | derivative 4 | | | | | |
| Comparative | PB15:6 | PV23 | Comparative | Dispersant 2 | Resin 1 | Monomer 1 | Initiator 1 | |
| composition B13 | | | derivative 5 | | | | | |

<<Yellow Composition Y1>>

(Production of Pigment Dispersion Liquid Y1)

A mixed solution obtained by mixing the following raw materials was mixed and dispersed for 3 hours using a beads mill (zirconia beads having a diameter of 0.1 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was dispersed under a pressure of 2000 kg/cm³ at a flow rate of 500 g/min. This dispersion treatment was repeated up to 10 times, thereby obtaining a pigment dispersion liquid Y1.

Raw Materials of Dispersion Liquid:

| | |
|---|---|
| PY150 | 10.0 parts by mass |
| Pigment derivative 3 | 1.1 parts by mass |
| Dispersant 2 | 6.7 parts by mass |
| PGMEA | 82.2 parts by mass |

(Production of Yellow Composition Y1)

Subsequently, after stirring a mixed solution obtained by mixing the following raw materials, the obtained mixed solution was filtered through a nylon filter (manufactured by Pall Corporation) having a pore size of 0.45 μm to obtain a yellow composition Y1.

Raw Materials of Composition:

| | |
|---|---|
| Pigment dispersion liquid Y1 | 53.8 parts by mass |
| Resin 2 (40% by mass PGMEA solution) | 3.3 parts by mass |
| Polymerizable monomer 2 | 2.4 parts by mass |
| Photopolymerization initiator 3 | 0.9 parts by mass |
| Surfactant 1 (1% by mass PGMEA solution) | 4.2 parts by mass |
| Ultraviolet absorber 1 | 0.7 parts by mass |
| PGMEA | 34.7 parts by mass |

<<Compositions of Yellow Composition Y2 and Comparative Examples>>

A yellow composition Y2 and yellow compositions of Comparative Examples (comparative compositions Y1 and Y2) were obtained by the same components, formulation, and procedure as in the case of the yellow composition Y1, except that the types of the components of the dispersion liquid and the composition were changed as shown in Table 5.

Table 5 shows the characteristic components of each of the above-described yellow compositions. In Table 5, the description of the surfactant, the ultraviolet absorber, and PGMEA is omitted because these components are common components in all the compositions. In addition, for each composition, the pigment concentration is also shown in the table.

TABLE 5
Yellow composition

| | Solid content in pigment dispersion liquid | | | Solid content in additive | | | |
|---|---|---|---|---|---|---|---|
| | Coloring | Pigment | | | Polymerizable | | Pigment |
| | material 1 | derivative | Dispersant | Resin | monomer | Initiator | concentration |
| Composition Y1 | PY150 | Derivative 3 | Dispersant 2 | Resin 2 | Monomer 2 | Initiator 3 | 40 |
| Composition Y2 | PY185 | Derivative 1 | Dispersant 1 | Resin 1 | Monomer 1 | Initiator 1 | |
| Comparative | PY150 | Comparative | Dispersant 1 | Resin 1 | Monomer 1 | Initiator 1 | 40 |
| composition Y1 | | derivative 1 | | | | | |
| Comparative | PY185 | | | | | | |
| composition Y2 | | | | | | | |

<<Magenta Composition M1>>

(Production of Pigment Dispersion Liquid M1)

A mixed solution obtained by mixing the following raw materials was mixed and dispersed for 3 hours using a beads mill (zirconia beads having a diameter of 0.1 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was dispersed under a pressure of 2000 kg/cm³ at a flow rate of 500 g/min. This dispersion treatment was repeated up to 10 times, thereby obtaining a pigment dispersion liquid M1.

Raw Materials of Dispersion Liquid:

| | |
|---|---|
| PR122 | 10.0 parts by mass |
| Pigment derivative 2 | 1.1 parts by mass |
| Dispersant 1 | 6.7 parts by mass |
| PGMEA | 82.2 parts by mass |

(Production of Magenta Composition M1)

Subsequently, after stirring a mixed solution obtained by mixing the following raw materials, the obtained mixed solution was filtered through a nylon filter (manufactured by Pall Corporation) having a pore size of 0.45 μm to obtain a magenta composition M1.

Raw Materials of Composition:

| | |
|---|---|
| Pigment dispersion liquid M1 | 62.4 parts by mass |
| Resin 2 (40% by mass PGMEA solution) | 0.6 parts by mass |
| Polymerizable monomer 3 | 2.2 parts by mass |
| Photopolymerization initiator 1 | 0.7 parts by mass |
| Surfactant 1 (1% by mass PGMEA solution) | 4.2 parts by mass |
| Ultraviolet absorber 1 | 0.4 parts by mass |
| Silane coupling agent 1 | 0.1 parts by mass |
| PGMEA | 29.4 parts by mass |

<<Magenta Composition M2 and Compositions of Comparative Examples>>

A magenta composition M2 and magenta compositions of Comparative Examples (comparative compositions M1 and M2) were obtained by the same components, formulation, and procedure as in the case of the magenta composition M1, except that the types of the components of the dispersion liquid and the composition were changed as shown in Table 6.

Table 6 shows the characteristic components of each of the above-described magenta compositions. In Table 6, the description of the surfactant, the ultraviolet absorber, the silane coupling agent, and PGMEA is omitted because these components are common components in all the compositions. In addition, for each composition, the pigment concentration is also shown in the table.

TABLE 6
Magenta composition

| | Solid content in pigment dispersion liquid | | | Solid content in additive | | | |
|---|---|---|---|---|---|---|---|
| | Coloring | Pigment | | | Polymerizable | | Pigment |
| | material 1 | derivative | Dispersant | Resin | monomer | Initiator | concentration |
| Composition M1 | PR122 | Derivative 2 | Dispersant 1 | Resin 2 | Monomer 3 | Initiator 1 | 47 |
| Composition M2 | PR177 | Derivative 1 | Dispersant 1 | Resin 1 | Monomer 1 | Initiator 1 | |
| Comparative | PR122 | Comparative | Dispersant 1 | Resin 1 | Monomer 1 | Initiator 1 | 47 |
| composition M1 | | derivative 1 | | | | | |
| Comparative | PR177 | | | | | | |
| composition M2 | | | | | | | |

<<Cyan Composition C1>>

(Production of Pigment Dispersion Liquid C1)

A mixed solution obtained by mixing the following raw materials was mixed and dispersed for 3 hours using a beads mill (zirconia beads having a diameter of 0.1 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was dispersed under a pressure of 2000 kg/cm³ at a flow rate of 500 g/min. This dispersion treatment was repeated up to 10 times, thereby obtaining a pigment dispersion liquid C1.

Raw Materials of Dispersion Liquid:

| | |
|---|---|
| PG7 | 10.0 parts by mass |
| Pigment derivative 1 | 1.1 parts by mass |
| Dispersant 1 | 6.7 parts by mass |
| PGMEA | 82.2 parts by mass |

(Production of Cyan Composition C1)

Subsequently, after stirring a mixed solution obtained by mixing the following raw materials, the obtained mixed solution was filtered through a nylon filter (manufactured by Pall Corporation) having a pore size of 0.45 μm to obtain a cyan composition C1.

Raw Materials of Composition:

| | |
|---|---|
| Pigment dispersion liquid C1 | 49.3 parts by mass |
| Resin 1 (40% by mass PGMEA solution) | 0.6 parts by mass |
| Polymerizable monomer 2 | 3.0 parts by mass |
| Photopolymerization initiator 2 | 0.6 parts by mass |
| Surfactant 1 (0.2% by mass EEP solution) | 4.2 parts by mass |
| Ultraviolet absorber 1 | 0.4 parts by mass |
| PGMEA | 15.6 parts by mass |
| EEP | 26.3 parts by mass |

<<Cyan Compositions C2 and C3, and Compositions of Comparative Examples>>

Cyan compositions C2 and C3, and cyan compositions of Comparative Examples (comparative compositions C1 to C3) were obtained by the same components, formulation, and procedure as in the case of the cyan composition C1, except that the types of the components of the dispersion liquid and the composition were changed as shown in Table 7. The coloring material of the composition C2 and the comparative composition C2 is a mixed pigment in which ⅓ of PG7 in the coloring material of the composition C1 is changed to PG36.

<<Cyan Composition C4>>

(Production of Pigment Dispersion Liquid C4)

A mixed solution obtained by mixing the following raw materials was mixed and dispersed for 3 hours using a beads mill (zirconia beads having a diameter of 0.1 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was dispersed under a pressure of 2000 kg/cm³ at a flow rate of 500 g/min. This dispersion treatment was repeated up to 10 times, thereby obtaining a pigment dispersion liquid C4.

Raw Materials of Dispersion Liquid:

| | |
|---|---|
| PB16 | 12.0 parts by mass |
| Pigment derivative 3 | 1.0 part by mass |
| Dispersant 1 | 4.7 parts by mass |
| PGMEA | 82.3 parts by mass |

(Production of Cyan Composition C4)

Subsequently, after stirring a mixed solution obtained by mixing the following raw materials, the obtained mixed solution was filtered through a nylon filter (manufactured by Pall Corporation) having a pore size of 0.45 μm to obtain a cyan composition C4.

Raw Materials of Composition:

| | |
|---|---|
| Pigment dispersion liquid C4 | 22.5 parts by mass |
| Resin 1 (40% by mass PGMEA solution) | 10.7 parts by mass |
| Polymerizable monomer 1 | 1.6 parts by mass |
| Photopolymerization initiator 1 | 1.2 parts by mass |
| Surfactant 1 (1% by mass PGMEA solution) | 4.2 parts by mass |
| Ultraviolet absorber 1 | 0.6 parts by mass |
| Epoxy resin 1 | 0.1 parts by mass |
| PGMEA | 59.1 parts by mass |

<<Cyan Composition C5, and Compositions of Comparative Examples>>

A cyan compositions C5 and cyan compositions of Comparative Examples (comparative compositions C4 and C5) were obtained by the same components, formulation, and procedure as in the case of the cyan composition C4, except that the types of the components of the dispersion liquid and the composition were changed as shown in Table 7.

Table 7 shows the characteristic components of each of the above-described cyan compositions. In Table 7, the description of the surfactant, the ultraviolet absorber, PGMEA, and EEP is omitted because these components are common components in all the compositions. In addition, for each composition, the pigment concentration is also shown in the table.

TABLE 7
Cyan composition

| | Solid content in pigment dispersion liquid | | | | Solid content in additive | | | |
|---|---|---|---|---|---|---|---|---|
| | Coloring | Coloring | Pigment | | | Polymerizable | | Pigment |
| | material 1 | material 2 | derivative | Dispersant | Resin | monomer | Initiator | concentration |
| Composition C1 | PG7 | — | Derivative 1 | Dispersant 1 | Resin 1 | Monomer 2 | Initiator 2 | 42 |
| Composition C2 | PG7 | PG36 | Derivative 4 | Dispersant 2 | Resin 2 | Monomer 3 | Initiator 3 | |
| Composition C3 | Al | — | Derivative 3 | Dispersant 1 | Resin 1 | Monomer 1 | Initiator 1 | |
| | phthalocyanine | | | | | | | |
| Composition C4 | PB16 | — | Derivative 3 | Dispersant 1 | Resin 1 | Monomer 1 | Initiator 1 | 25 |
| Composition C5 | PB15:4 | — | Derivative 2 | Dispersant 1 | Resin 1 | Monomer 1 | Initiator 1 | 25 |
| Comparative | PG7 | — | Comparative | Dispersant 1 | Resin 1 | Monomer 1 | Initiator 1 | 42 |
| composition C1 | | | derivative 1 | | | | | |
| Comparative | PG7 | PG36 | | | | | | |
| composition C2 | | | | | | | | |
| Comparative | A1 | | | | | | | |
| composition C3 | phthalocyanine | — | | | | | | |
| Comparative | PB16 | — | | | | | | 25 |
| composition C4 | | | | | | | | |
| Comparative | PB15:4 | — | | | | | | 25 |
| composition C5 | | | | | | | | |

<<Composition SIR1 for Near-Infrared Cut Filter>>

(Production of Pigment Dispersion Liquid SIR1)

A mixed solution obtained by mixing the following raw materials was mixed and dispersed for 3 hours using a beads mill (zirconia beads having a diameter of 0.1 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was dispersed under a pressure of 2000 kg/cm³ at a flow rate of 500 g/min. This dispersion treatment was repeated up to 10 times, thereby obtaining a pigment dispersion liquid SIR1.

Raw Materials of Dispersion Liquid:

| | |
|---|---|
| IR coloring agent 1 | 10.0 parts by mass |
| Pigment derivative 5 | 1.1 parts by mass |
| Dispersant 2 | 6.7 parts by mass |
| PGMEA | 82.2 parts by mass |

(Production of Composition SIR1 for Near-Infrared Cut Filter)

Subsequently, after stirring a mixed solution obtained by mixing the following raw materials, the obtained mixed solution was filtered through a nylon filter (manufactured by Pall Corporation) having a pore size of 0.45 μm to obtain a composition SIR1 for near-infrared cut filter.

Raw Materials of Composition:

| | |
|---|---|
| Pigment dispersion liquid SIR1 | 53.8 parts by mass |
| Resin 1 (40% by mass PGMEA solution) | 3.3 parts by mass |
| Polymerizable monomer 1 | 2.4 parts by mass |
| Photopolymerization initiator 2 | 0.9 parts by mass |
| Surfactant 1 (1% by mass PGMEA solution) | 4.2 parts by mass |
| Ultraviolet absorber 1 | 0.7 parts by mass |
| PGMEA | 34.7 parts by mass |

<<Compositions SIR2 and SIR3 for Near-Infrared Cut Filter and Compositions of Comparative Examples>>

Compositions SIR2 and SIR3 for near-infrared cut filter, and compositions of Comparative Examples for near-infrared cut filter (comparative compositions SIR1 to SIR3) were obtained by the same components, formulation, and procedure as in the case of the composition SIR1 for near-infrared cut filter, except that the types of the components of the dispersion liquid and the composition were changed as shown in Table 8.

Table 8 shows the characteristic components of each of the above-described compositions for near-infrared cut filter. In Table 8, the description of the surfactant, the ultraviolet absorber, and PGMEA is omitted because these components are common components in all the compositions. In addition, for each composition, the pigment concentration is also shown in the table.

TABLE 8
Composition for near-infrared cut filter

| | Solid content in pigment dispersion liquid | | | Solid content in additive | | | |
|---|---|---|---|---|---|---|---|
| | | Pigment | | | Polymerizable | | Pigment |
| | Coloring material 1 | derivative | Dispersant | Resin | monomer | Initiator | concentration |
| Composition SIR1 | IR coloring agent 1 | Derivative 5 | Dispersant 2 | Resin 1 | Monomer 1 | Initiator 2 | 40 |
| Composition SIR2 | IR coloring agent 2 | Derivative 1 | Dispersant 2 | Resin 2 | Monomer 3 | Initiator 2 | |
| Composition SIR3 | IR coloring agent 3 | Derivative 2 | Dispersant 1 | Resin 2 | Monomer 2 | Initiator 3 | |
| Comparative | IR coloring agent 1 | Comparative | Dispersant 1 | Resin 1 | Monomer 1 | Initiator 1 | 40 |
| composition SIR1 | | derivative 1 | | | | | |
| Comparative | IR coloring agent 2 | | | | | | |
| composition SIR2 | | | | | | | |
| Comparative | IR coloring agent 3 | | | | | | |
| composition SIR3 | | | | | | | |

<<Composition IRP1 for Near-Infrared Transmission Filter>>

(Production of Pigment Dispersion Liquid IRP1)

A mixed solution obtained by mixing the following raw materials was mixed and dispersed for 3 hours using a beads mill (zirconia beads having a diameter of 0.1 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was dispersed under a pressure of 2000 kg/cm³ at a flow rate of 500 g/min. This dispersion treatment was repeated up to 10 times, thereby obtaining a pigment dispersion liquid IRP1.

Raw Materials of Dispersion Liquid:

| | |
|---|---|
| PR254 | 5.7 parts by mass |
| PY139 | 0.5 parts by mass |
| PV23 | 1.1 parts by mass |
| PB15:6 | 4.4 parts by mass |
| Pigment derivative 5 | 1.3 parts by mass |
| Dispersant 2 | 4.7 parts by mass |
| PGMEA | 82.3 parts by mass |

(Production of Composition IRP1 for Near-Infrared Transmission Filter)

After stirring a mixed solution obtained by mixing the following raw materials, the obtained mixed solution was filtered through a nylon filter (manufactured by Pall Corporation) having a pore size of 0.45 μm to obtain a composition IRP1 for near-infrared transmission filter.

Raw Materials of Composition:

| | |
|---|---|
| Pigment dispersion liquid IRP1 | 69.0 parts by mass |
| Resin 1 (40% by mass PGMEA solution) | 1.6 parts by mass |
| Polymerizable monomer 1 | 1.2 parts by mass |
| Photopolymerization initiator 1 | 0.6 parts by mass |
| Surfactant 1 (0.2% by mass PGMEA solution) | 4.2 parts by mass |
| Slime coupling agent 1 | 0.4 parts by mass |
| PGMEA | 23.0 parts by mass |

<<Composition IRP2 for Near-Infrared Transmission Filter>>

(Production of Pigment Dispersion Liquid IRP2)

A mixed solution obtained by mixing the following raw materials was mixed and dispersed for 3 hours using a beads mill (zirconia beads having a diameter of 0.1 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was dispersed under a pressure of 2000 kg/cm³ at a flow rate of 500 g/min. This dispersion treatment was repeated up to 10 times, thereby obtaining a pigment dispersion liquid IRP2.

Raw Materials of Dispersion Liquid:

| | |
|---|---|
| Perylene black | 5.7 parts by mass |
| PY139 | 0.5 parts by mass |
| PV23 | 1.1 parts by mass |
| PB15:6 | 4.4 parts by mass |
| Pigment derivative 2 | 1.3 parts by mass |
| Dispersant 1 | 4.7 parts by mass |
| PGMEA | 82.3 parts by mass |

(Production of Composition IRP2 for Near-Infrared Transmission Filter)

After stirring a mixed solution obtained by mixing the following raw materials, the obtained mixed solution was filtered through a nylon filter (manufactured by Pall Corporation) having a pore size of 0.45 μm to obtain a composition IRP2 for near-infrared transmission filter.

Raw Materials of Composition:

| | |
|---|---|
| Pigment dispersion liquid IRP2 | 69.0 parts by mass |
| Resin 2 (40% by mass PGMEA solution) | 1.6 parts by mass |
| Polymerizable monomer 3 | 1.2 parts by mass |
| Photopolymerization initiator 1 | 0.6 parts by mass |
| Surfactant 1 (0.2% by mass PGMEA solution) | 4.2 parts by mass |
| Silane coupling agent 1 | 0.4 parts by mass |
| PGMEA | 23.0 parts by mass |

<<Composition IRP3 for Near-Infrared Transmission Filter>>

(Production of Pigment Dispersion Liquid IRP3)

A mixed solution obtained by mixing the following raw materials was mixed and dispersed for 3 hours using a beads mill (zirconia beads having a diameter of 0.1 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was dispersed under a pressure of 2000 kg/cm³ at a flow rate of 500 g/min. This dispersion treatment was repeated up to 10 times, thereby obtaining a pigment dispersion liquid IRP3.

Raw Materials of Dispersion Liquid:

| | |
|---|---|
| Bisbenzofuranone | 5.7 parts by mass |
| PY139 | 0.5 parts by mass |
| PV23 | 1.1 parts by mass |
| PB15:6 | 4.4 parts by mass |
| Pigment derivative 1 | 1.3 parts by mass |
| Dispersant 2 | 4.7 parts by mass |
| PGMEA | 82.3 parts by mass |

(Production of Composition IRP3 for Near-Infrared Transmission Filter)

After stirring a mixed solution obtained by mixing the following raw materials, the obtained mixed solution was filtered through a nylon filter (manufactured by Pall Corporation) having a pore size of 0.45 μm to obtain a composition IRP3 for near-infrared transmission filter.

Raw Materials of Composition:

| | |
|---|---|
| Pigment dispersion liquid IRP3 | 69.0 parts by mass |
| Resin 1 (40% by mass PGMEA solution) | 1.6 parts by mass |
| Polymerizable monomer 2 | 1.2 parts by mass |
| Photopolymerization initiator 1 | 0.6 parts by mass |
| Surfactant 1 (0.2% by mass PGMEA solution) | 4.2 parts by mass |
| Silane coupling agent 1 | 0.4 parts by mass |
| PGMEA | 23.0 parts by mass |

<<Compositions of Comparative Examples for Near-Infrared Transmission Filter>>

Compositions of Comparative Examples for near-infrared transmission filter (comparative compositions IRP1 to IRP3) were obtained by the same components, formulation, and procedure as in the case of the composition IRP1 for near-infrared transmission filter, except that the types of the components of the dispersion liquid and the composition were changed as shown in Table 9.

Table 9 shows the characteristic components of each of the above-described compositions for near-infrared transmission filter. In Table 9, the description of the surfactant, the silane coupling agent, and PGMEA is omitted because these components are common components in all the compositions. In addition, for each composition, the pigment concentration is also shown in the table.

TABLE 9
Composition for near-infrared transmission filter

| | Solid content in pigment dispersion liquid | | | | | | Solid content in additive | | | Pigment |
|---|---|---|---|---|---|---|---|---|---|---|
| | Coloring | Coloring | Coloring | Coloring | Pigment | | | Polymerizable | | concen- |
| | material 1 | material 2 | material 3 | material 4 | derivative | Dispersant | Resin | monomer | Initiator | tration |
| Composition IRP1 | PR254 | PY139 | PV23 | PB15:6 | Derivative 5 | Dispersant 2 | Resin 1 | Monomer 1 | Initiator 1 | 60 |
| Composition IRP2 | Perylene | PY139 | PV23 | PB15:6 | Derivative 2 | Dispersant 1 | Resin 2 | Monomer 3 | Initiator 1 | |
| | black | | | | | | | | | |
| Composition IRP3 | Bisbenzo- | PY139 | PV23 | PB15:6 | Derivative 1 | Dispersant 2 | Resin 1 | Monomer 2 | Initiator 1 | |
| | furanone | | | | | | | | | |
| Comparative | PR254 | PY139 | PV23 | PB15:6 | Comparative | Dispersant 1 | Resin 1 | Monomer 1 | Initiator 1 | 60 |
| composition IRP1 | | | | | derivative 1 | | | | | |
| Comparative | Perylene | | | | | | | | | |
| composition IRP2 | black | | | | | | | | | |
| Comparative | Bisbenzo- | | | | | | | | | |
| composition IRP3 | furanone | | | | | | | | | |

<<White Composition W>>

(Production of Pigment Dispersion Liquid W)

A mixed solution obtained by mixing the following raw materials was mixed and dispersed for 3 hours using a beads mill (zirconia beads having a diameter of 0.1 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was dispersed under a pressure of 2000 kg/cm³ at a flow rate of 500 g/min. This dispersion treatment was repeated up to 10 times, thereby obtaining a pigment dispersion liquid W.

Raw Materials of Dispersion Liquid:

| | |
|---|---|
| TiO₂ | 12.3 parts by mass |
| Pigment derivative 4 | 0.7 parts by mass |
| Dispersant 1 | 4.7 parts by mass |
| PGMEA | 82.3 parts by mass |

(Production of White Composition W)

Subsequently, after stirring a mixed solution obtained by mixing the following raw materials, the obtained mixed solution was filtered through a nylon filter (manufactured by Pall Corporation) having a pore size of 0.45 μm to obtain a white composition W.

Raw Materials of Composition:

| | |
|---|---|
| Pigment dispersion liquid W | 48.3 parts by mass |
| Resin 2 (40% by mass PGMEA solution) | 0.6 parts by mass |
| Polymerizable monomer 1 | 2.7 parts by mass |
| Photopolymerization initiator 1 | 0.5 parts by mass |
| Surfactant 1 (1% by mass cyclohexanone solution) | 2.5 parts by mass |
| Ultraviolet absorber 1 | 1.1 parts by mass |
| PGMEA | 2.2 parts by mass |
| Cyclohexanone | 42.1 parts by mass |

<<White Composition of Comparative Example>>

A white composition of Comparative Example (comparative composition W) was obtained by the same components, formulation, and procedure as in the case of the white composition W, except that the types of the components of the dispersion liquid and the composition were changed as shown in Table 10.

Table 10 shows the characteristic components of each of the above-described white compositions. In Table 10, the description of the surfactant, the ultraviolet absorber, PGMEA, and cyclohexanone is omitted because these components are common components in all the compositions. In addition, for each composition, the pigment concentration is also shown in the table.

TABLE 10
White composition

| | Solid content in pigment | | | | | | |
|---|---|---|---|---|---|---|---|
| | dispersion liquid | | | Solid content in additive | | | |
| | Coloring | | | | Poly- | | Pigment |
| | material | Pigment | | | merizable | | concen- |
| | 1 | derivative | Dispersant | Resin | monomer | Initiator | tration |
| Composition | TiO₂ | Derivative 4 | Dispersant | Resin | Monomer | Initiator | 50 |
| W | | | 1 | 2 | 1 | 1 | |
| Comparative | TiO₂ | Comparative | Dispersant | Resin | Monomer | Initiator | 50 |
| composition | | derivative 1 | 1 | 1 | 1 | 1 | |
| W | | | | | | | |

<Production of Structural Body>

### Example 1

First, an 8-inch (1 inch=approximately 25.4 mm) silicon wafer was prepared. An undercoat composition was applied to this silicon wafer by a spin coating method, and heated at 100° C. for 2 minutes and further at 230° C. for 2 minutes using a hot plate, thereby forming an undercoat layer having a film thickness of 10 nm on the wafer. Subsequently, the above-described green composition G1 was applied onto the undercoat layer by a spin coating method, and heated at 100° C. for 2 minutes using a hot plate, thereby forming a green composition layer having a film thickness of 0.5 μm on the undercoat layer. Next, using an i-ray stepper exposure device FPA-3000 i5+(manufactured by Canon Corporation), the above-described green composition layer was exposed through a mask having a 1.0 μm×1.0 μm Bayer pattern at an exposure dose of 150 mJ/cm². Next, puddle development was performed to the green composition layer at 23° C. for 60 seconds using a tetramethylammonium hydroxide (TMAH) 0.3% by mass aqueous solution. Thereafter, rinsing with a spin shower and washing with pure water were performed thereto, and the wafer was further heated at 220° C. for 5 minutes using a hot plate, thereby forming a green pixel having a thickness of 0.5 μm and 1.0 μm square.

Using the above-described red composition R1, the same treatment was performed on the silicon wafer on which the green pixel had been formed, thereby forming a red pixel having a thickness of 0.5 μm and 1.0 μm square at a position adjacent to the green pixel on the silicon wafer. As a result, a structural body in which the green pixel and the red pixel were adjacent to each other on one side facing each other, specifically a structural body (structure type I) having a pixel arrangement as shown in FIGS. 1A to 1C was formed. Here, for example, the green pixel is the first pixel P1, and the red pixel is the second pixel P2.

### Examples 2 to 9 and 20 to 25, and Comparative Examples 1 to 9, 20 to 27, 29, and 30

Structural bodies of the structure type I were prepared respectively by adopting, as a combination of compositions for forming the structural body of the structure type I, a combination shown in Tables 11 and 12, and performing the same treatment as in Example 1 to form the first pixel and the second pixel sequentially.

### Example 10

First, using the above-described green composition G1, a green pixel having a thickness of 0.5 μm and 1.0 μm square was formed on a silicon wafer by the same method as in Example 1. Next, using the above-described red composition R1, the same treatment was performed on the silicon wafer on which the green pixel had been formed, thereby forming a red pixel having a thickness of 0.5 μm and 1.0 μm square at a position adjacent to the green pixel on the silicon wafer. Finally, using the above-described blue composition B1, the same treatment was performed on the silicon wafer on which the green pixel and the red pixel had been formed, thereby forming a blue pixel having a thickness of 0.5 μm and 1.0 μm square at a position adjacent to the green pixel on the silicon wafer. In forming the red pixel and the blue pixel, a mask having a 1.0 μm×1.0 μm island pattern was used during exposure.

As a result, a structural body in which the green pixel and the red pixel were adjacent to each other on one side facing each other, and the green pixel and the blue pixel were adjacent to each other on one side facing each other, specifically a structural body (structure type IIa) having a pixel arrangement as shown in FIG. 2A was formed. Here, for example, the green pixel is the first pixel P1, the red pixel is the second pixel P2, and the blue pixel is the third pixel P3.

### Examples 11 to 13 and Comparative Examples 10 to 13 and 28

Structural bodies of the structure type IIa were prepared respectively by adopting, as a combination of compositions for forming the structural body of the structure type IIa, a combination shown in Tables 11 and 12, and performing the same treatment as in Example 10 to form the first pixel, the second pixel, and the third pixel sequentially.

### Example 14

An undercoat composition was applied to the silicon wafer same as in Example 1 by a spin coating method, and heated at 100° C. for 2 minutes and further at 230° C. for 2 minutes using a hot plate, thereby forming an undercoat layer having a film thickness of 10 nm on the wafer. Subsequently, the above-described green composition G1 was applied onto the undercoat layer by a spin coating method, and heated at 100° C. for 2 minutes using a hot plate, thereby forming a green composition layer having a film thickness of 0.5 μm on the undercoat layer. Next, using an i-ray stepper exposure device FPA-3000 i5+(manufactured by Canon Corporation), the above-described green composition layer was exposed through a mask having a 1.0 μm×1.0 μm island pattern at an exposure dose of 150 mJ/cm². Next, puddle development was performed to the green composition layer at 23° C. for 60 seconds using a tetramethylammonium hydroxide (TMAH) 0.3% by mass aqueous solution. Thereafter, rinsing with a spin shower and washing with pure water were performed thereto, and the wafer was further heated at 220° C. for 5 minutes using a hot plate, thereby forming a green pixel having a thickness of 0.5 μm and 1.0 μm square.

Next, using the above-described red composition R1, the same treatment was performed on the silicon wafer on which the green pixel had been formed, thereby forming a red pixel having a thickness of 0.5 μm and 1.0 μm square at a position adjacent to the green pixel on the silicon wafer. Next, using the above-described blue composition B1, the same treatment was performed on the silicon wafer on which the green pixel and the red pixel had been formed, thereby forming a blue pixel having a thickness of 0.5 μm and 1.0 μm square at a position adjacent to the green pixel on the silicon wafer. Finally, using the above-described composition IRP1 for near-infrared transmission filter, the same treatment was performed on the silicon wafer on which the green pixel, the red pixel, and the blue pixel had been formed, thereby forming a near-infrared transmission pixel having a thickness of 0.5 μm and 1.0 μm square at a position on the silicon wafer where vertices faced each other with the green pixel.

As a result, a structural body in which the green pixel and the red pixel were adjacent to each other on one side facing each other, the green pixel and the blue pixel were adjacent to each other on one side facing each other, and the near-infrared transmission pixel was adjacent to both red pixel and blue pixel, specifically a structural body (structure type III) having a pixel arrangement as shown in FIG. 3A was formed. Here, for example, the green pixel is the first pixel P1, the red pixel is the second pixel P2, the blue pixel is the third pixel P3, and the near-infrared transmission pixel is the fourth pixel P4.

### Examples 15 to 19 and Comparative Examples 14 to 19

Structural bodies of the structure type III were prepared respectively by adopting, as a combination of compositions for forming the structural body of the structure type III, a combination shown in Tables 11 and 12, and performing the same treatment as in Example 14 to form the first pixel, the second pixel, the third pixel, and the fourth pixel sequentially.

### Example 26

A silicon oxide layer was formed on an 8-inch silicon wafer by a plasma CVD method. Next, this silicon oxide layer was patterned by a dry etching method under the conditions described in paragraph Nos. 0128 to 0133 of JP2016-014856A, to form partition walls (width: 0.1 μm, thickness: 0.25 μm) formed of silicon oxide in a lattice form at intervals of 1.0 μm. The size of the opening of the partition wall on the silicon wafer (area partitioned by the partition wall on the silicon wafer) was 1.0 μm in length and 1.0 μm in width.

Next, using the above-described green composition G1, a green pixel having a thickness of 0.5 μm and 1.0 μm square was formed on this silicon wafer on which the partition walls had been formed by the same method as in Example 1. In this case, the position of the mask during exposure was adjusted so that one pixel corresponded to one area separated by the partition wall. Next, using the above-described red composition R1, the same treatment was performed on the silicon wafer on which the green pixel had been formed, thereby forming a red pixel having a thickness of 0.5 μm and 1.0 μm square at a position adjacent to the green pixel on the silicon wafer. Finally, using the above-described blue composition B1, the same treatment was performed on the silicon wafer on which the green pixel and the red pixel had been formed, thereby forming a blue pixel having a thickness of 0.5 μm and 1.0 μm square at a position adjacent to the green pixel on the silicon wafer. In forming the red pixel and the blue pixel, a mask having a 1.0 μm×1.0 μm island pattern was used during exposure.

As a result, a structural body in which the green pixel and the red pixel were adjacent to each other on one side facing each other, and the green pixel and the blue pixel were adjacent to each other on one side facing each other, specifically a structural body (structure type IIb) having a pixel arrangement as shown in FIG. 2A and having the partition wall at a boundary portion between each pixel as shown in FIGS. 2B and 2C was formed. Here, for example, the green pixel is the first pixel P1, the red pixel is the second pixel P2, and the blue pixel is the third pixel P3.

### Examples 27 to 32

Structural bodies of the structure type IIb were prepared respectively by adopting, as a combination of compositions for forming the structural body of the structure type IIb, a combination shown in Table 11, and performing the same treatment as in Example 26 to form the first pixel, the second pixel, and the third pixel sequentially.

TABLE 11

| | Structure | | | | | Stability | | | |
|---|---|---|---|---|---|---|---|---|---|
| Example | type | First pixel | Second pixel | Third pixel | Fourth pixel | a | b | c | d |
| 1 | I | Composition G1 | Composition R1 | — | — | 5 | — | — | — |
| 2 | I | Composition G1 | Composition B1 | — | — | 5 | — | — | — |
| 3 | I | Composition R1 | Composition B1 | — | — | 5 | — | — | — |
| 4 | I | Composition Y1 | Composition R1 | — | — | 5 | — | — | — |
| 5 | I | Composition Y1 | Composition B1 | — | — | 5 | — | — | — |
| 6 | I | Composition Y1 | Composition C1 | — | — | 5 | — | — | — |
| 7 | I | Composition Y1 | Composition M1 | — | — | 5 | — | — | — |
| 8 | I | Composition C1 | Composition M1 | — | — | 5 | — | — | — |
| 9 | I | Composition SIR1 | Composition IRP1 | — | — | 5 | — | — | — |
| 10 | IIa | Composition G1 | Composition R1 | Composition B1 | — | 5 | 5 | — | — |
| 11 | IIa | Composition Y1 | Composition R1 | Composition B1 | — | 5 | 5 | — | — |
| 12 | IIa | Composition Y1 | Composition M1 | Composition C1 | — | 5 | 5 | — | — |
| 13 | IIa | Composition Y1 | Composition R1 | Composition C1 | — | 5 | 5 | — | — |
| 14 | III | Composition G1 | Composition R1 | Composition B1 | Composition IRP1 | 5 | 5 | 5 | 5 |
| 15 | III | Composition Y1 | Composition R1 | Composition B1 | Composition IRP1 | 5 | 5 | 5 | 5 |
| 16 | III | Composition Y1 | Composition M1 | Composition C1 | Composition IRP1 | 5 | 5 | 5 | 5 |
| 17 | III | Composition Y1 | Composition R1 | Composition C1 | Composition IRP1 | 5 | 5 | 5 | 5 |
| 18 | III | Composition G1 | Composition R1 | Composition B1 | Composition W1 | 5 | 5 | 5 | 5 |
| 19 | III | Composition Y1 | Composition R1 | Composition B1 | Composition W1 | 5 | 5 | 5 | 5 |
| 20 | I | Composition G4 | Composition R4 | — | — | 5 | — | — | — |
| 21 | I | Composition G4 | Composition B3 | — | — | 5 | — | — | — |
| 22 | I | Composition R4 | Composition B3 | — | — | 5 | — | — | — |
| 23 | I | Composition G5 | Composition R5 | — | — | 5 | — | — | — |
| 24 | I | Composition G5 | Composition B4 | — | — | 5 | — | — | — |
| 25 | I | Composition R5 | Composition B4 | — | — | 5 | — | — | — |
| 26 | IIb | Composition G1 | Composition R1 | Composition B1 | — | 5 | 5 | — | — |
| 27 | IIb | Composition Y1 | Composition R1 | Composition B1 | — | 5 | 5 | — | — |
| 28 | IIb | Composition Y1 | Composition M1 | Composition C1 | — | 5 | 5 | — | — |
| 29 | IIb | Composition Y1 | Composition R1 | Composition C1 | — | 5 | 5 | — | — |
| 30 | IIb | Composition G22 | Composition R1 | Composition B1 | — | 3 | 3 | — | — |
| 31 | IIb | Composition G23 | Composition R1 | Composition B1 | — | 4 | 4 | — | — |
| 32 | IIb | Composition G24 | Composition R1 | Composition B1 | — | 4 | 4 | — | — |

TABLE 12

| Comparative | Structure | | | | | Stability | | | |
|---|---|---|---|---|---|---|---|---|---|
| example | type | First pixel | Second pixel | Third pixel | Fourth pixel | a | b | c | d |
| 1 | I | Comparative | Comparative | — | — | 1 | — | — | — |
| | | composition G1 | composition R1 | | | | | | |
| 2 | I | Comparative | Comparative | — | — | 1 | — | — | — |
| | | composition G1 | composition B1 | | | | | | |
| 3 | I | Comparative | Comparative | — | — | 1 | — | — | — |
| | | composition R1 | composition B1 | | | | | | |
| 4 | I | Comparative | Comparative | — | — | 1 | — | — | — |
| | | composition Y1 | composition R1 | | | | | | |
| 5 | I | Comparative | Comparative | — | — | 1 | — | — | — |
| | | composition Y1 | composition B1 | | | | | | |
| 6 | I | Comparative | Comparative | — | — | 1 | — | — | — |
| | | composition Y1 | composition C1 | | | | | | |
| 7 | I | Comparative | Comparative | — | — | 1 | — | — | — |
| | | composition Y1 | composition M1 | | | | | | |
| 8 | I | Comparative | Comparative | — | — | 1 | — | — | — |
| | | composition C1 | composition M1 | | | | | | |
| 9 | I | Comparative | Comparative | — | — | 1 | — | — | — |
| | | composition SIR1 | composition IRP1 | | | | | | |
| 10 | IIa | Comparative | Comparative | Comparative | — | 1 | 1 | — | — |
| | | composition G1 | composition R1 | composition B1 | | | | | |
| 11 | IIa | Comparative | Comparative | Comparative | — | 1 | 1 | — | — |
| | | composition Y1 | composition R1 | composition B1 | | | | | |
| 12 | IIa | Comparative | Comparative | Comparative | — | 1 | 1 | — | — |
| | | composition Y1 | composition M1 | composition C1 | | | | | |
| 13 | IIa | Comparative | Comparative | Comparative | — | 1 | 1 | — | — |
| | | composition Y1 | composition R1 | composition C1 | | | | | |
| 14 | III | Comparative | Comparative | Comparative | Comparative | 1 | 1 | 1 | 1 |
| | | composition G1 | composition R1 | composition B1 | composition IRP1 | | | | |
| 15 | III | Comparative | Comparative | Comparative | Comparative | 1 | 1 | 1 | 1 |
| | | composition Y1 | composition R1 | composition B1 | composition IRP1 | | | | |
| 16 | III | Comparative | Comparative | Comparative | Comparative | 1 | 1 | 1 | 1 |
| | | composition Y1 | composition M1 | composition C1 | composition IRP1 | | | | |
| 17 | III | Comparative | Comparative | Comparative | Comparative | 1 | 1 | 1 | 1 |
| | | composition Y1 | composition R1 | composition C1 | composition IRP1 | | | | |
| 18 | III | Comparative | Comparative | Comparative | Comparative | 1 | 1 | 1 | 1 |
| | | composition G1 | composition R1 | composition B1 | composition W1 | | | | |
| 19 | III | Comparative | Comparative | Comparative | Comparative | 1 | 1 | 1 | 1 |
| | | composition Y1 | composition R1 | composition B1 | composition W1 | | | | |
| 20 | I | Comparative | Comparative | — | — | 1 | — | — | — |
| | | composition G4 | composition R4 | | | | | | |
| 21 | I | Comparative | Comparative | — | — | 1 | — | — | — |
| | | composition G4 | composition B3 | | | | | | |
| 22 | I | Comparative | Comparative | — | — | 1 | — | — | — |
| | | composition R4 | composition B3 | | | | | | |
| 23 | I | Comparative | Comparative | — | — | 2 | — | — | — |
| | | composition G5 | composition R5 | | | | | | |
| 24 | I | Comparative | Comparative | — | — | 2 | — | — | — |
| | | composition G5 | composition B4 | | | | | | |
| 25 | I | Comparative | Comparative | — | — | 2 | — | — | — |
| | | composition R5 | composition B4 | | | | | | |
| 26 | I | Comparative | Composition B1 | — | — | 1 | — | — | — |
| | | composition G1 | | | | | | | |
| 27 | I | Comparative | Composition C1 | — | — | 1 | — | — | — |
| | | composition Y1 | | | | | | | |
| 28 | IIa | Composition Y1 | Comparative | Comparative | — | 1 | 1 | — | — |
| | | | composition M1 | composition C1 | | | | | |
| 29 | I | Comparative | Comparative | — | — | 2 | — | — | — |
| | | composition Y1 | composition C4 | | | | | | |
| 30 | I | Comparative | Comparative | — | — | 2 | — | — | — |
| | | composition Y1 | composition C5 | | | | | | |

<Production of Photosensitive Composition>

Furthermore, in addition to the above-described photosensitive compositions, using the above-described raw materials and the following new raw materials, various compositions shown in Tables 13 to 23 were newly produced by the procedure and formulation described later.

<<Raw Material>>

<<<Coloring Material: Pigment and Dye>>>
PR202: C. I. Pigment Red 202
PR264: C. I. Pigment Red 264
PR269: C. I. Pigment Red 269
PR291: C. I. Pigment Red 291
PR296: C. I. Pigment Red 296
PR297: C. I. Pigment Red 297
PG59: C. I. Pigment Green 59
PG63: C. I. Pigment Green 63
PB15:3: C. I. Pigment Blue 15:3
PB15:4: C. I. Pigment Blue 15:4
PB16: C. I. Pigment Blue 16
PV19: C. I. Pigment Violet 19
PY215: C. I. Pigment Yellow 215
PY228: C. I. Pigment Yellow 228
PY231: C. I. Pigment Yellow 231
PY233: C. I. Pigment Yellow 233
PV2: C. I. Pigment Violet 2
PV37: C. I. Pigment Violet 37

<<<Pigment Derivative of Examples>>>
Pigment derivative 101: compound C-60 in Table 1 described above (εmax: 100 L·mol⁻¹·cm⁻¹ or less, basic)
Pigment derivative 102: compound having the following structure (εmax: 100 L·mol⁻¹·cm⁻¹ or less, basic)
Pigment derivative 103: compound having the following structure (εmax: 100 L·mol⁻¹·cm⁻¹ or less, basic)
Pigment derivative 104: compound C-93 in Table 1 described above (εmax: 100 L·mol⁻¹·cm⁻¹ or less, basic)
Pigment derivative 105: compound C-95 in Table 1 described above (εmax: 100 L·mol⁻¹·cm⁻¹ or less, basic)

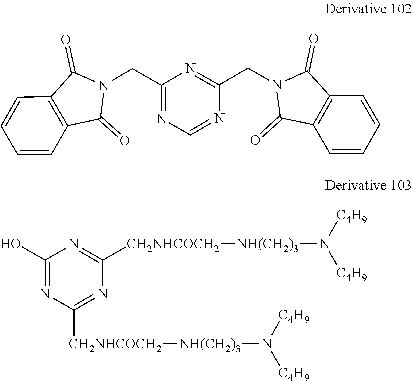

<<<Dispersant>>>
Dispersant 4: compound having the following structure (Mw: 30000). The numerical value described together with the main chain indicates a molar ratio of a repeating unit.

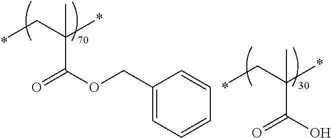

Dispersant 5: Solsperse 20000 (manufactured by Lubrizol Corporation)

<<<Resin>>>
Resin 3: CYCLOMER P (ACA) 230AA (Mw: 14000, manufactured by DAICEL-ALLNEX LTD.)
Resin 4: compound having the following structure (Mw: 14000). The numerical value described together with the main chain indicates a molar ratio of a repeating unit.

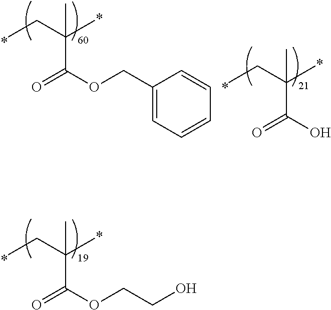

<<<Photopolymerization Initiator>>>
Photopolymerization initiator 4: compound having the following structure

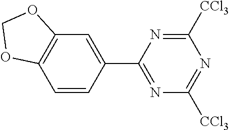

Photopolymerization initiator 5: compound having the following structure

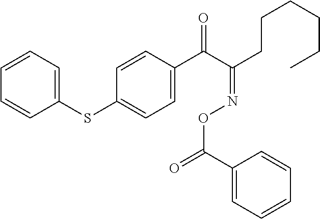 [SMILES: CCCCCC/C(=N/OC(=O)c1ccccc1)C(=O)c1ccc(Sc2ccccc2)cc1]

<<<Surfactant>>>
Surfactant 2: nonionic surfactant (Pionin D 6112W, manufactured by TAKEMOTO OIL & FAT Co., Ltd.)

<<<Epoxy Resin>>>
Epoxy resin 2: EPICLON N-695 (manufactured by DIC Corporation)

<<<Polymerization Inhibitor>>>
Polymerization inhibitor 1: compound having the following structure

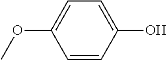

<<<Solvent>>>
PGME: propylene glycol monomethyl ether

<<Green Compositions G101 to G135>>

Green compositions G101 to G112, G115 to G123, and G128 to G135 were obtained by the same components, formulation, and procedure as in the case of the green composition G1, except that the types of the components of the dispersion liquid and the composition were changed as shown in Table 13. In addition, green compositions G113, G124, and G126 were obtained by the same components, formulation, and procedure as in the case of the green composition G20, except that the types of the components of the dispersion liquid and the composition were changed as shown in the same table. In addition, green compositions G114, G125, and G127 were obtained by the same components, formulation, and procedure as in the case of the green composition G21, except that the types of the components of the dispersion liquid and the composition were changed as shown in the same table.

TABLE 13
Green composition

| | Solid content in pigment dispersion liqiud | | | | | Solid content in additive | | | Pigment |
|---|---|---|---|---|---|---|---|---|---|
| | Coloring | Coloring | Coloring | Pigment | | | Polymerizable | | concen- |
| No. | material 1 | material 2 | material 3 | derivative | Dispersant | Resin | monomer | Initiator | tration |
| G101 | PG58 | PY185 | — | Derivative 101 | Dispersant 1 | Resin 1 | Monomer 1 | Initiator 1 | 60 |
| G102 | PG36 | PY150 | — | Derivative 101 | Dispersant 1 | Resin 2 | Monomer 3 | Initiator 3 | |
| G103 | PG36 | PY185 | — | Derivative 101 | Dispersant 1 | Resin 1 | Monomer 1 | Initiator 3 | |
| G104 | PG36 | PY185 | — | Derivative 102 | Dispersant 1 | Resin 1 | Monomer 3 | Initiator 2 | |
| G105 | PG36 | PY185 | — | Derivative 103 | Dispersant 1 | Resin 2 | Monomer 1 | Initiator 1 | |
| G106 | PG36 | PY185 | — | Derivative 104 | Dispersant 1 | Resin 1 | Monomer 1 | Initiator 2 | |
| G107 | PG36 | PY185 | — | Derivative 105 | Dispersant 1 | Resin 1 | Monomer 2 | Initiator 3 | |
| G108 | PG36 | PY185 | — | Derivative 101 | Dispersant 2 | Resin 2 | Monomer 3 | Initiator 1 | |
| G109 | PG36 | PY185 | — | Derivative 102 | Dispersant 2 | Resin 1 | Monomer 1 | Initiator 3 | |
| G110 | PG36 | PY185 | — | Derivative 103 | Dispersant 2 | Resin 2 | Monomer 3 | Initiator 3 | |
| G111 | PG36 | PY185 | — | Derivative 104 | Dispersant 2 | Resin 2 | Monomer 2 | Initiator 1 | |
| G112 | PG36 | PY185 | — | Derivative 105 | Dispersant 2 | Resin 1 | Monomer 1 | Initiator 3 | |
| G113 | PG58 | PY185 | PY150 | Derivative 101 | Dispersant 1 | Resin 1 | Monomer 1 | Initiator 1 | |
| G114 | PG36 | PY185 | PY150 | Derivative 101 | Dispersant 1 | Resin 1 | Monomer 1 | Initiator 3 | |
| G115 | PG58 | PY150 | — | Derivative 101 | Dispersant 1 | Resin 1 | Monomer 1 | Initiator 1 | |
| G116 | PG59 | PY150 | — | Derivative 101 | Dispersant 1 | Resin 1 | Monomer 1 | Initiator 1 | |
| G117 | PG63 | PY150 | — | Derivative 101 | Dispersant 1 | Resin 1 | Monomer 1 | Initiator 1 | |
| G118 | PG59 | PY185 | — | Derivative 101 | Dispersant 1 | Resin 1 | Monomer 1 | Initiator 1 | |
| G119 | PG63 | PY185 | — | Derivative 101 | Dispersant 1 | Resin 1 | Monomer 1 | Initiator 1 | |
| G120 | PG36 | PY215 | — | Derivative 101 | Dispersant 1 | Resin 2 | Monomer 3 | Initiator 3 | |
| G121 | PG58 | PY215 | — | Derivative 101 | Dispersant 1 | Resin 1 | Monomer 1 | Initiator 3 | |
| G122 | PG59 | PY215 | — | Derivative 101 | Dispersant 1 | Resin 2 | Monomer 3 | Initiator 3 | |
| G123 | PG63 | PY215 | — | Derivative 101 | Dispersant 1 | Resin 1 | Monomer 1 | Initiator 3 | |
| G124 | PG36 | PY185 | PY215 | Derivative 101 | Dispersant 1 | Resin 1 | Monomer 1 | Initiator 1 | |
| G125 | PG58 | PY185 | PY215 | Derivative 101 | Dispersant 1 | Resin 1 | Monomer 1 | Initiator 3 | |
| G126 | PG59 | PY185 | PY215 | Derivative 101 | Dispersant 1 | Resin 1 | Monomer 1 | Initiator 1 | |
| G127 | PG63 | PY185 | PY215 | Derivative 101 | Dispersant 1 | Resin 1 | Monomer 1 | Initiator 3 | |
| G128 | PG36 | PY231 | — | Derivative 101 | Dispersant 1 | Resin 2 | Monomer 3 | Initiator 3 | |
| G129 | PG58 | PY231 | — | Derivative 101 | Dispersant 1 | Resin 1 | Monomer 1 | Initiator 3 | |
| G130 | PG59 | PY231 | — | Derivative 101 | Dispersant 1 | Resin 2 | Monomer 3 | Initiator 3 | |
| G131 | PG63 | PY231 | — | Derivative 101 | Dispersant 1 | Resin 1 | Monomer 1 | Initiator 3 | |
| G132 | PG36 | PY233 | — | Derivative 101 | Dispersant 1 | Resin 2 | Monomer 3 | Initiator 3 | |
| G133 | PG58 | PY233 | — | Derivative 101 | Dispersant 1 | Resin 1 | Monomer 1 | Initiator 3 | |
| G134 | PG59 | PY233 | — | Derivative 101 | Dispersant 1 | Resin 2 | Monomer 3 | Initiator 3 | |
| G135 | PG63 | PY233 | — | Derivative 101 | Dispersant 1 | Resin 1 | Monomer 1 | Initiator 3 | |

<<Red Compositions R101 and R103 to R118>>

Red compositions R101 and R103 to R118 were obtained by the same components, formulation, and procedure as in the case of the red composition R1, except that the types of the components of the dispersion liquid and the composition were changed as shown in Table 14.

<<Red Composition R102>>

(Production of Pigment Dispersion Liquid R102)

A mixed solution obtained by mixing the following raw materials was mixed and dispersed for 3 hours using a beads mill (zirconia beads having a diameter of 0.1 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was dispersed under a pressure of 2000 kg/cm³ at a flow rate of 500 g/min. This dispersion treatment was repeated up to 10 times, thereby obtaining a pigment dispersion liquid R1.

Raw Materials of Dispersion Liquid:

| | |
|---|---|
| PR254 | 5.25 parts by mass |
| PY139 | 0.90 parts by mass |
| PO71 | 5.25 parts by mass |
| Pigment derivative 101 | 1.60 parts by mass |
| Dispersant 1 | 4.70 parts by mass |
| PGMEA | 82.30 parts by mass |

(Production of Red Composition R102)

Subsequently, after stirring a mixed solution obtained by mixing the following raw materials, the obtained mixed solution was filtered through a nylon filter (manufactured by Pall Corporation) having a pore size of 0.45 μm to obtain a red composition R102.

Raw Materials of Composition:

| | |
|---|---|
| Pigment dispersion liquid R102 | 58.9 parts by mass |
| Resin 2 (40% by mass PGMEA solution) | 2.0 parts by mass |
| Polymerizable monomer 2 | 0.9 parts by mass |
| Photopolymerization initiator 3 | 0.5 parts by mass |
| Surfactant 1 (1% by mass PGMEA solution) | 4.2 parts by mass |
| Ultraviolet absorber 1 | 0.1 parts by mass |
| Epoxy resin 1 | 0.1 parts by mass |
| PGMEA | 33.3 parts by mass |

<<Red Compositions R119 to R126>

Red compositions R119 to R126 were obtained by the same components, formulation, and procedure as in the case of the red composition R102, except that the types of the components of the dispersion liquid and the composition were changed as shown in Table 14.

TABLE 14
Red composition

| | Solid content in pigment dispersion liquid | | | | | Solid content in additive | | | Pigment |
|---|---|---|---|---|---|---|---|---|---|
| | Coloring | Coloring | Coloring | Pigment | | | Polymerizable | | concen- |
| No. | material 1 | material 2 | material 3 | derivative | Dispersant | Resin | monomer | Initiator | tration |
| R101 | PR254 | PY139 | — | Derivative 101 | Dispersant 1 | Resin 1 | Monomer 1 | Initiator 1 | 60 |
| R102 | PR254 | PY139 | PO71 | Derivative 101 | Dispersant 1 | Resin 2 | Monomer 2 | Initiator 3 | |
| R103 | PR272 | PY139 | — | Derivative 101 | Dispersant 1 | Resin 2 | Monomer 3 | Initiator 3 | |
| R104 | PR254 | PY139 | — | Derivative 102 | Dispersant 1 | Resin 1 | Monomer 2 | Initiator 2 | |
| R105 | PR254 | PY139 | — | Derivative 103 | Dispersant 1 | Resin 1 | Monomer 1 | Initiator 1 | |
| R106 | PR254 | PY139 | — | Derivative 104 | Dispersant 1 | Resin 2 | Monomer 3 | Initiator 2 | |
| R107 | PR254 | PY139 | — | Derivative 105 | Dispersant 1 | Resin 1 | Monomer 1 | Initiator 3 | |
| R108 | PR254 | PY139 | — | Derivative 101 | Dispersant 2 | Resin 2 | Monomer 1 | Initiator 1 | |
| R109 | PR254 | PY139 | — | Derivative 102 | Dispersant 2 | Resin 1 | Monomer 3 | Initiator 3 | |
| R110 | PR254 | PY139 | — | Derivative 103 | Dispersant 2 | Resin 2 | Monomer 3 | Initiator 3 | |
| R111 | PR254 | PY139 | — | Derivative 104 | Dispersant 2 | Resin 1 | Monomer 1 | Initiator 1 | |
| R112 | PR254 | PY139 | — | Derivative 105 | Dispersant 2 | Resin 1 | Monomer 3 | Initiator 3 | |
| R113 | PR272 | PY139 | — | Derivative 101 | Dispersant 1 | Resin 1 | Monomer 1 | Initiator 1 | |
| R114 | PR264 | PY139 | — | Derivative 101 | Dispersant 1 | Resin 2 | Monomer 2 | Initiator 3 | |
| R115 | PR269 | PY139 | — | Derivative 101 | Dispersant 1 | Resin 2 | Monomer 3 | Initiator 3 | |
| R116 | PR291 | PY139 | — | Derivative 101 | Dispersant 1 | Resin 1 | Monomer 1 | Initiator 1 | |
| R117 | PR296 | PY139 | — | Derivative 101 | Dispersant 1 | Resin 1 | Monomer 1 | Initiator 1 | |
| R118 | PR297 | PY139 | — | Derivative 101 | Dispersant 1 | Resin 1 | Monomer 1 | Initiator 1 | |
| R119 | PR296 | PY139 | PR254 | Derivative 101 | Dispersant 1 | Resin 1 | Monomer 1 | Initiator 1 | |
| R120 | PR297 | PY139 | PR254 | Derivative 101 | Dispersant 1 | Resin 1 | Monomer 1 | Initiator 1 | |
| R121 | PR272 | PY139 | PR254 | Derivative 101 | Dispersant 1 | Resin 1 | Monomer 1 | Initiator 1 | |
| R122 | PR272 | PY139 | PR264 | Derivative 101 | Dispersant 1 | Resin 2 | Monomer 2 | Initiator 3 | |
| R123 | PR272 | PY139 | PR269 | Derivative 101 | Dispersant 1 | Resin 2 | Monomer 3 | Initiator 3 | |
| R124 | PR272 | PY139 | PR291 | Derivative 101 | Dispersant 1 | Resin 2 | Monomer 2 | Initiator 3 | |
| R125 | PR272 | PY139 | PR296 | Derivative 101 | Dispersant 1 | Resin 1 | Monomer 1 | Initiator 1 | |
| R126 | PR272 | PY139 | PR297 | Derivative 101 | Dispersant 1 | Resin 2 | Monomer 2 | Initiator 3 | |

<<Blue Compositions B101 to B114>>

Blue compositions B101 to B114 were obtained by the same components, formulation, and procedure as in the case of the blue composition B1, except that the types of the components of the dispersion liquid and the composition were changed as shown in Table 15.

TABLE 15
Blue composition

| | Solid content in pigment dispersion liquid | | | | Solid content in additive | | | Pigment |
|---|---|---|---|---|---|---|---|---|
| | Coloring | Coloring | Pigment | | | Polymerizable | | concen- |
| No. | material 1 | material 2 | derivative | Dispersant | Resin | monomer | Initiator | tration |
| B101 | PB15:6 | PV23 | Derivative 101 | Dispersant 1 | Resin 1 | Monomer 1 | Initiator 1 | 60 |
| B102 | PB15:6 | Xanthene | Derivative 101 | Dispersant 1 | Resin 2 | Monomer 3 | Initiator 3 | |
| B103 | PB15:6 | PV23 | Derivative 102 | Dispersant 1 | Resin 1 | Monomer 1 | Initiator 2 | |
| B104 | PB15:6 | PV23 | Derivative 103 | Dispersant 1 | Resin 2 | Monomer 2 | Initiator 1 | |
| B105 | PB15:6 | PV23 | Derivative 104 | Dispersant 1 | Resin 1 | Monomer 1 | Initiator 3 | |
| B106 | PB15:6 | PV23 | Derivative 105 | Dispersant 1 | Resin 2 | Monomer 1 | Initiator 1 | |
| B107 | PB15:6 | PV23 | Derivative 101 | Dispersant 2 | Resin 1 | Monomer 2 | Initiator 2 | |
| B108 | PB15:6 | PV23 | Derivative 102 | Dispersant 2 | Resin 2 | Monomer 1 | Initiator 1 | |
| B109 | PB15:6 | PV23 | Derivative 103 | Dispersant 2 | Resin 2 | Monomer 3 | Initiator 1 | |
| B110 | PB15:6 | PV23 | Derivative 104 | Dispersant 2 | Resin 2 | Monomer 1 | Initiator 3 | |
| B111 | PB15:6 | PV23 | Derivative 105 | Dispersant 2 | Resin 1 | Monomer 1 | Initiator 1 | |
| B112 | PB15:6 | PV2 | Derivative 101 | Dispersant 1 | Resin 1 | Monomer 1 | Initiator 1 | |
| B113 | PB15:6 | PV19 | Derivative 101 | Dispersant 1 | Resin 1 | Monomer 1 | Initiator 1 | |
| B114 | PB15:6 | PV37 | Derivative 101 | Dispersant 1 | Resin 1 | Monomer 1 | Initiator 1 | |

<<Yellow Compositions Y101 to Y112>>

Yellow compositions Y101 to Y112 were obtained by the same components, formulation, and procedure as in the case of the yellow composition Y1, except that the types of the components of the dispersion liquid and the composition were changed as shown in Table 16.

TABLE 16
Yellow composition

| | Solid content in pigment dispersion liquid | | | Solid content in additive | | | Pigment |
|---|---|---|---|---|---|---|---|
| | Coloring | Pigment | | | Polymerizable | | concen- |
| No. | material 1 | derivative | Dispersant | Resin | monomer | Initiator | tration |
| Y101 | PY150 | Derivative 101 | Dispersant 2 | Resin 2 | Monomer 2 | Initiator 3 | 40 |
| Y102 | PY185 | Derivative 101 | Dispersant 1 | Resin 1 | Monomer 1 | Initiator 1 | |
| Y103 | PY215 | Derivative 101 | Dispersant 2 | Resin 2 | Monomer 2 | Initiator 3 | |
| Y104 | PY228 | Derivative 101 | Dispersant 1 | Resin 1 | Monomer 1 | Initiator 1 | |
| Y105 | PY231 | Derivative 101 | Dispersant 2 | Resin 2 | Monomer 2 | Initiator 3 | |
| Y106 | PY233 | Derivative 101 | Dispersant 1 | Resin 1 | Monomer 1 | Initiator 1 | |
| Y107 | PY150 | Derivative 102 | Dispersant 2 | Resin 2 | Monomer 2 | Initiator 3 | |
| Y108 | PY185 | Derivative 102 | Dispersant 1 | Resin 1 | Monomer 1 | Initiator 1 | |
| Y109 | PY215 | Derivative 102 | Dispersant 2 | Resin 2 | Monomer 2 | Initiator 3 | |
| Y110 | PY228 | Derivative 102 | Dispersant 1 | Resin 1 | Monomer 1 | Initiator 1 | |
| Y111 | PY231 | Derivative 102 | Dispersant 2 | Resin 2 | Monomer 2 | Initiator 3 | |
| Y112 | PY233 | Derivative 102 | Dispersant 1 | Resin 1 | Monomer 1 | Initiator 1 | |

<<Magenta Compositions M101 to M110>>

Magenta compositions M101 to M110 were obtained by the same components, formulation, and procedure as in the case of the magenta composition M1, except that the types of the components of the dispersion liquid and the composition were changed as shown in Table 17.

TABLE 17
Magenta composition

| | Solid content in pigment dispersion liquid | | | Solid content in additive | | | Pigment |
|---|---|---|---|---|---|---|---|
| | Coloring | Pigment | | | Polymerizable | | concen- |
| No. | material 1 | derivative | Dispersant | Resin | monomer | Initiator | tration |
| M101 | PR122 | Derivative 101 | Dispersant 1 | Resin 2 | Monomer 3 | Initiator 1 | 47 |
| M102 | PR177 | Derivative 101 | Dispersant 1 | Resin 1 | Monomer 1 | Initiator 1 | |
| M103 | PR202 | Derivative 101 | Dispersant 1 | Resin 2 | Monomer 3 | Initiator 1 | |
| M104 | PV19 | Derivative 101 | Dispersant 1 | Resin 1 | Monomer 1 | Initiator 1 | |
| M105 | PV23 | Derivative 101 | Dispersant 1 | Resin 2 | Monomer 3 | Initiator 1 | |
| M106 | PR122 | Derivative 102 | Dispersant 1 | Resin 2 | Monomer 3 | Initiator 1 | |
| M107 | PR177 | Derivative 102 | Dispersant 1 | Resin 1 | Monomer 1 | Initiator 1 | |
| M108 | PR202 | Derivative 102 | Dispersant 1 | Resin 2 | Monomer 3 | Initiator 1 | |
| M109 | PV19 | Derivative 102 | Dispersant 1 | Resin 1 | Monomer 1 | Initiator 1 | |
| M110 | PV23 | Derivative 102 | Dispersant 1 | Resin 2 | Monomer 3 | Initiator 1 | |

<<Cyan Compositions C101 to C116>>

Cyan compositions C101 to C104, and C109 to C112 were obtained by the same components, formulation, and procedure as in the case of the cyan composition C1, except that the types of the components of the dispersion liquid and the composition were changed as shown in Table 18. The coloring material in the compositions C102, C103, C110, and C111 is a mixed pigment in which ⅓ of PG7 in the coloring material of the cyan composition C1 is changed to the coloring material 2 in the table. In addition, cyan compositions C105 to C108, and C113 to C116 were obtained by the same components, formulation, and procedure as in the case of the cyan composition C4, except that the types of the components of the dispersion liquid and the composition were changed as shown in the same table.

TABLE 18
Cyan composition

| | Solid content in pigment dispersion liquid | | | | Solid content in additive | | | Pigment |
|---|---|---|---|---|---|---|---|---|
| | Coloring | Coloring | Pigment | | | Polymerizable | | concen- |
| No. | material 1 | material 2 | derivative | Dispersant | Resin | monomer | Initiator | tration |
| C101 | PG7 | — | Derivative 101 | Dispersant 1 | Resin 1 | Monomer 2 | Initiator 2 | 42 |
| C102 | PG7 | PG36 | Derivative 101 | Dispersant 2 | Resin 2 | Monomer 3 | Initiator 3 | |
| C103 | PG7 | PB16 | Derivative 101 | Dispersant 2 | Resin 2 | Monomer 3 | Initiator 3 | |
| C104 | Al | — | Derivative 101 | Dispersant 1 | Resin 1 | Monomer 1 | Initiator 1 | |
| | phthalocyanine | | | | | | | |
| C105 | PB16 | — | Derivative 101 | Dispersant 1 | Resin 1 | Monomer 1 | Initiator 1 | 25 |
| C106 | PB15:3 | — | Derivative 101 | Dispersant 1 | Resin 1 | Monomer 1 | Initiator 1 | |
| C107 | PB15:4 | — | Derivative 101 | Dispersant 1 | Resin 1 | Monomer 1 | Initiator 1 | |
| C108 | PG63 | — | Derivative 101 | Dispersant 1 | Resin 1 | Monomer 1 | Initiator 1 | |
| C109 | PG7 | — | Derivative 102 | Dispersant 1 | Resin 1 | Monomer 2 | Initiator 2 | 42 |
| C110 | PG7 | PG36 | Derivative 102 | Dispersant 2 | Resin 2 | Monomer 3 | Initiator 3 | |
| C111 | PG7 | PB16 | Derivative 102 | Dispersant 2 | Resin 2 | Monomer 3 | Initiator 3 | |
| C112 | Al | — | Derivative 102 | Dispersant 1 | Resin 1 | Monomer 1 | Initiator 1 | |
| | phthalocyanine | | | | | | | |
| C113 | PB16 | — | Derivative 102 | Dispersant 1 | Resin 1 | Monomer 1 | Initiator 1 | 25 |
| C114 | PB15:3 | — | Derivative 102 | Dispersant 1 | Resin 1 | Monomer 1 | Initiator 1 | |
| C115 | PB15:4 | — | Derivative 102 | Dispersant 1 | Resin 1 | Monomer 1 | Initiator 1 | |
| C116 | PG63 | — | Derivative 102 | Dispersant 1 | Resin 1 | Monomer 1 | Initiator 1 | |

<<Compositions SIR101 to SIR106 for Near-Infrared Cut Filter>>

Compositions SIR 101 to SIR106 for near-infrared cut filter were obtained by the same components, formulation, and procedure as in the case of the composition SIR1 for near-infrared cut filter, except that the types of the components of the dispersion liquid and the composition were changed as shown in Table 19.

TABLE 19
Composition for near-infrared cut filter

| | Solid content in pigment dispersion liquid | | | Solid content in additive | | | Pigment |
|---|---|---|---|---|---|---|---|
| | Coloring | Pigment | | | Polymerizable | | concen- |
| No. | material 1 | derivative | Dispersant | Resin | monomer | Initiator | tration |
| SIR101 | IR coloring | Derivative | Dispersant | Resin | Monomer | Initiator | 40 |
| | agent 1 | 101 | 2 | 1 | 1 | 2 | |
| SIR102 | IR coloring | Derivative | Dispersant | Resin | Monomer | Initiator | |
| | agent 2 | 101 | 2 | 2 | 3 | 2 | |
| SIR103 | IR coloring | Derivative | Dispersant | Resin | Monomer | Initiator | |
| | agent 3 | 101 | 1 | 2 | 2 | 3 | |
| SIR104 | IR coloring | Derivative | Dispersant | Resin | Monomer | Initiator | |
| | agent 1 | 102 | 2 | 1 | 1 | 2 | |
| SIR105 | IR coloring | Derivative | Dispersant | Resin | Monomer | Initiator | |
| | agent 2 | 102 | 2 | 2 | 3 | 2 | |
| SIR106 | IR coloring | Derivative | Dispersant | Resin | Monomer | Initiator | |
| | agent 3 | 102 | 1 | 2 | 2 | 3 | |

<<Compositions IRP101 to IRP118 for Near-Infrared Transmission Filter>>

Compositions IRP101, IRP104, IRP107, IRP110, IRP113, and IRP116 for near-infrared transmission filter were obtained by the same components, formulation, and procedure as in the case of the composition IRP1 for near-infrared transmission filter, except that the types of the components of the dispersion liquid and the composition were changed as shown in Table 20. In addition, compositions IRP102, IRP105, IRP108, IRP111, IRP114, and IRP117 for near-infrared transmission filter were obtained by the same components, formulation, and procedure as in the case of the composition IRP2 for near-infrared transmission filter, except that the types of the components of the dispersion liquid and the composition were changed as shown in the same table. In addition, compositions IRP103, IRP106, IRP109, IRP112, IRP115, and IRP118 for near-infrared transmission filter were obtained by the same components, formulation, and procedure as in the case of the composition IRP3 for near-infrared transmission filter, except that the types of the components of the dispersion liquid and the composition were changed as shown in the same table.

TABLE 20
Composition for near-infrared transmission filter

| | Solid content in pigment dispersion liquid | | | | | | Solid content in additive | | | |
|---|---|---|---|---|---|---|---|---|---|---|
| | | Coloring | Coloring | Coloring | | | | Poly- | | Pigment |
| | Coloring | material | material | material | Pigment | | | merizable | | concen- |
| No. | material 1 | 2 | 3 | 4 | derivative | Dispersant | Resin | monomer | Initiator | tration |
| IRP101 | PR254 | PY139 | PV23 | PB15:6 | Derivative | Dispersant | Resin | Monomer | Initiator | 60 |
| | | | | | 101 | 2 | 1 | 1 | 1 | |
| IRP102 | Perylene | PY139 | PV23 | PB15:6 | Derivative | Dispersant | Resin | Monomer | Initiator | |
| | black | | | | 101 | 1 | 2 | 3 | 1 | |
| IRP103 | Bisbenzo- | PY139 | PV23 | PB15:6 | Derivative | Dispersant | Resin | Monomer | Initiator | |
| | furanone | | | | 101 | 2 | 1 | 2 | 1 | |
| IRP104 | PR254 | PY139 | PV23 | PB15:4 | Derivative | Dispersant | Resin | Monomer | Initiator | |
| | | | | | 101 | 2 | 1 | 1 | 1 | |
| IRP105 | Perylene | PY139 | PV23 | PB15:4 | Derivative | Dispersant | Resin | Monomer | Initiator | |
| | black | | | | 101 | 1 | 2 | 3 | 1 | |
| IRP106 | Bisbenzo- | PY139 | PV23 | PB15:4 | Derivative | Dispersant | Resin | Monomer | Initiator | |
| | furanone | | | | 101 | 2 | 1 | 2 | 1 | |
| IRP107 | PR254 | PY139 | PV23 | PB16 | Derivative | Dispersant | Resin | Monomer | Initiator | |
| | | | | | 101 | 2 | 1 | 1 | 1 | |
| IRP108 | Perylene | PY139 | PV23 | PB16 | Derivative | Dispersant | Resin | Monomer | Initiator | |
| | black | | | | 101 | 1 | 2 | 3 | 1 | |
| IRP109 | Bisbenzo- | PY139 | PV23 | PB16 | Derivative | Dispersant | Resin | Monomer | Initiator | |
| | furanone | | | | 101 | 2 | 1 | 2 | 1 | |
| IRP110 | PR254 | PY139 | PV23 | PB15:6 | Derivative | Dispersant | Resin | Monomer | Initiator | |
| | | | | | 102 | 2 | 1 | 1 | 1 | |
| IRP111 | Perylene | PY139 | PV23 | PB15:6 | Derivative | Dispersant | Resin | Monomer | Initiator | |
| | black | | | | 102 | 1 | 2 | 3 | 1 | |
| IRP112 | Bisbenzo- | PY139 | PV23 | PB15:6 | Derivative | Dispersant | Resin | Monomer | Initiator | |
| | furanone | | | | 102 | 2 | 1 | 2 | 1 | |
| IRP113 | PR254 | PY139 | PV23 | PB15:4 | Derivative | Dispersant | Resin | Monomer | Initiator | |
| | | | | | 102 | 2 | 1 | 1 | 1 | |
| IRP114 | Perylene | PY139 | PV23 | PB15:4 | Derivative | Dispersant | Resin | Monomer | Initiator | |
| | black | | | | 102 | 1 | 2 | 3 | 1 | |
| IRP115 | Bisbenzo- | PY139 | PV23 | PB15:4 | Derivative | Dispersant | Resin | Monomer | Initiator | |
| | furanone | | | | 102 | 2 | 1 | 2 | 1 | |
| IRP116 | PR254 | PY139 | PV23 | PB16 | Derivative | Dispersant | Resin | Monomer | Initiator | |
| | | | | | 102 | 2 | 1 | 1 | 1 | |
| IRP117 | Perylene | PY139 | PV23 | PB16 | Derivative | Dispersant | Resin | Monomer | Initiator | |
| | black | | | | 102 | 1 | 2 | 3 | 1 | |
| IRP118 | Bisbenzo- | PY139 | PV23 | PB16 | Derivative | Dispersant | Resin | Monomer | Initiator | |
| | furanone | | | | 102 | 2 | 1 | 2 | 1 | |

<<White Compositions W101 and W102>>

White compositions W101 and W102 were obtained by the same components, formulation, and procedure as in the case of the white composition W, except that the types of the components of the dispersion liquid and the composition were changed as shown in Table 21

TABLE 21
White composition

| | Solid content in pigment dispersion liquid | | | Solid content in additive | | | Pigment |
|---|---|---|---|---|---|---|---|
| | Coloring | Pigment | | | Polymerizable | | concen- |
| No. | material 1 | derivative | Dispersant | Resin | monomer | Initiator | tration |
| W101 | TiO₂ | Derivative | Dispersant | Resin | Monomer | Initiator | 50 |
| | | 101 | 1 | 2 | 1 | 1 | |
| W102 | TiO₂ | Derivative | Dispersant | Resin | Monomer | Initiator | |
| | | 102 | 1 | 2 | 1 | 1 | |

<<Green Composition G201>>

(Production of Pigment Dispersion Liquid G201)

A mixed solution obtained by mixing raw materials shown in Table 22(a) was mixed and dispersed for 3 hours using a beads mill (zirconia beads having a diameter of 0.1 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was dispersed under a pressure of 2000 kg/cm³ at a flow rate of 500 g/min. This dispersion treatment was repeated up to 10 times, thereby obtaining a pigment dispersion liquid G201.

(Production of Green Composition G201)

Subsequently, after stirring a mixed solution obtained by mixing raw materials shown in Table 22(b), the obtained mixed solution was filtered through a nylon filter (manufactured by Pall Corporation) having a pore size of 0.45 μm to obtain a green composition G201.

TABLE 221

| (a) Raw materials | | (b) Raw materials | |
|---|---|---|---|
| of dispersion liquid | | of composition | |
| | Part | | Part |
| Compound | by mass | Compound | by mass |
| PG36 | 4.47 | Pigment dispersion | 73.92 |
| PG7 | 1.97 | liquid G201 | |
| PY185 | 0.98 | Polymerizable | 5.11 |
| PY139 | 0.87 | monomer 3 | |
| Pigment derivative 1 | 0.44 | Photopolymerization | 0.61 |
| Dispersant 4 | 8.06 | initiator 4 | |
| PGMEA | 30.52 | Epoxy resin 2 | 0.22 |
| Cyclohexanone | 15.44 | Surfactant 2 | 0.22 |
| EEP | 11.1 | Dispersant 5 | 0.11 |
| Xylene | 0.05 | Surfactant 1 | 0.008 |
| Ethyl benzene | 0.02 | Polymerization | 0.005 |
| Total | 73.92 | inhibitor 1 | |
| | | PGMEA | 19.8 |
| | | Total | 100.00 |

<<Green Composition G202>>

(Production of Pigment Dispersion Liquid G202)

A mixed solution obtained by mixing raw materials shown in Table 23(a) was mixed and dispersed for 3 hours using a beads mill (zirconia beads having a diameter of 0.1 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was dispersed under a pressure of 2000 kg/cm³ at a flow rate of 500 g/min. This dispersion treatment was repeated up to 10 times, thereby obtaining a pigment dispersion liquid G202.

(Production of Green Composition G202)

Subsequently, after stirring a mixed solution obtained by mixing raw materials shown in Table 23(b), the obtained mixed solution was filtered through a nylon filter (manufactured by Pall Corporation) having a pore size of 0.45 μm to obtain a green composition G202.

TABLE 23

| (a) Raw materials | | (b) Raw materials | |
|---|---|---|---|
| of dispersion liquid | | of composition | |
| | Part | | Part |
| Compound | by mass | Compound | by mass |
| PG36 | 4.16 | Pigment dispersion | 72.24 |
| PG7 | 1.63 | liquid G202 | |
| PY185 | 0.9 | Resin 3 | 0.04 |
| PY139 | 0.82 | Resin 4 | 1.28 |
| Pigment derivative 1 | 0.4 | Polymerizable | 4.03 |
| Dispersant 4 | 5.52 | monomer 3 | |
| PGMEA | 32.13 | Photopolymerization | 0.87 |
| Cyclohexanone | 13.19 | initiator 5 | |
| EEP | 13.03 | Surfactant 2 | 1.03 |
| PGME | 0.39 | Dispersant 5 | 0.1 |
| Xylene | 0.05 | Surfactant 1 | 0.008 |
| Ethyl benzene | 0.02 | Polymerization | 0.004 |
| Total | 72.24 | inhibitor 1 | |
| | | PGMEA | 20.00 |
| | | Total | 100.00 |

<Production of Structural Body>

### Examples 101 to 109

A combination shown in Table 24 was adopted as a combination of compositions for forming the structural body of the structure type I for each example, and the same treatment as in Example 1 was performed to form the first pixel and the second pixel sequentially.

### Examples 110 to 113

A combination shown in Table 24 was adopted as a combination of compositions for forming the structural body of the structure type IIa for each example, and the same treatment as in Example 10 was performed to form the first pixel, the second pixel, and the third pixel sequentially.

### Examples 114 to 121

A combination shown in Table 24 was adopted as a combination of compositions for forming the structural body of the structure type III for each example, and the same treatment as in Example 14 was performed to form the first pixel, the second pixel, the third pixel, and the fourth pixel sequentially.

### Examples 122 to 125

A combination shown in Table 24 was adopted as a combination of compositions for forming the structural body of the structure type IIb for each example, and the same treatment as in Example 26 was performed to form the first pixel, the second pixel, and the third pixel sequentially.

### Examples 201 and 202

A combination shown in Table 25 was adopted as a combination of compositions for forming the structural body of the structure type I for each example, and the same treatment as in Example 1 was performed to form the first pixel and the second pixel sequentially.

### Examples 203 and 204

A combination shown in Table 25 was adopted as a combination of compositions for forming the structural body of the structure type IIa for each example, and the same treatment as in Example 10 was performed to form the first pixel, the second pixel, and the third pixel sequentially.

### Examples 205 and 206

A combination shown in Table 25 was adopted as a combination of compositions for forming the structural body of the structure type III for each example, and the same treatment as in Example 14 was performed to form the first pixel, the second pixel, the third pixel, and the fourth pixel sequentially.

### Examples 207 and 208

A combination shown in Table 25 was adopted as a combination of compositions for forming the structural body of the structure type IIb for each example, and the same treatment as in Example 26 was performed to form the first pixel, the second pixel, and the third pixel sequentially.

TABLE 24

| Ex- | Structure | | | | | Stability | | | |
|---|---|---|---|---|---|---|---|---|---|
| ample | type | First pixel | Second pixel | Third pixel | Fourth pixel | a | b | c | d |
| 101 | I | Composition | Composition | — | — | 5 | — | — | — |
| | | G101 | R101 | | | | | | |
| 102 | I | Composition | Composition | — | — | 5 | — | — | — |
| | | G101 | B101 | | | | | | |
| 103 | I | Composition | Composition | — | — | 5 | — | — | — |
| | | R101 | B101 | | | | | | |
| 104 | I | Composition | Composition | — | — | 5 | — | — | — |
| | | Y101 | R101 | | | | | | |
| 105 | I | Composition | Composition | — | — | 5 | — | — | — |
| | | Y101 | B101 | | | | | | |
| 106 | I | Composition | Composition | — | — | 5 | — | — | — |
| | | Y101 | C101 | | | | | | |
| 107 | I | Composition | Composition | — | — | 5 | — | — | — |
| | | Y101 | M101 | | | | | | |
| 108 | I | Composition | Composition | — | — | 5 | — | — | — |
| | | C101 | M101 | | | | | | |
| 109 | I | Composition | Composition | — | — | 5 | — | — | — |
| | | SIR101 | IRP101 | | | | | | |
| 110 | IIa | Composition | Composition | Composition | — | 5 | 5 | — | — |
| | | G101 | R101 | B101 | | | | | |
| 111 | IIa | Composition | Composition | Composition | — | 5 | 5 | — | — |
| | | Y101 | R101 | B101 | | | | | |
| 112 | IIa | Composition | Composition | Composition | — | 5 | 5 | — | — |
| | | Y101 | M101 | C101 | | | | | |
| 113 | IIa | Composition | Composition | Composition | — | 5 | 5 | — | — |
| | | Y101 | R101 | C101 | | | | | |
| 114 | III | Composition | Composition | Composition | Composition | 5 | 5 | 5 | 5 |
| | | G101 | R101 | B101 | IRP101 | | | | |
| 115 | III | Composition | Composition | Composition | Composition | 5 | 5 | 5 | 5 |
| | | Y101 | R101 | B101 | IRP101 | | | | |
| 116 | III | Composition | Composition | Composition | Composition | 5 | 5 | 5 | 5 |
| | | Y101 | M101 | C101 | IRP101 | | | | |
| 117 | III | Composition | Composition | Composition | Composition | 5 | 5 | 5 | 5 |
| | | Y101 | R101 | C101 | IRP101 | | | | |
| 118 | III | Composition | Composition | Composition | Composition | 5 | 5 | 5 | 5 |
| | | G101 | R101 | B101 | W101 | | | | |
| 119 | III | Composition | Composition | Composition | Composition | 5 | 5 | 5 | 5 |
| | | Y101 | R101 | B101 | W101 | | | | |
| 120 | III | Composition | Composition | Composition | Composition | 5 | 5 | 5 | 5 |
| | | Y101 | M101 | C101 | W101 | | | | |
| 121 | III | Composition | Composition | Composition | Composition | 5 | 5 | 5 | 5 |
| | | Y101 | R101 | C101 | W101 | | | | |
| 122 | IIb | Composition | Composition | Composition | — | 5 | 5 | — | — |
| | | G101 | R101 | B101 | | | | | |
| 123 | IIb | Composition | Composition | Composition | — | 5 | 5 | — | — |
| | | Y101 | R101 | B101 | | | | | |
| 124 | IIb | Composition | Composition | Composition | — | 5 | 5 | — | — |
| | | Y101 | M101 | C101 | | | | | |
| 125 | IIb | Composition | Composition | Composition | — | 5 | 5 | — | — |
| | | Y101 | R101 | C101 | | | | | |

TABLE 25

| Ex- | Structure | | | | | Stability | | | |
|---|---|---|---|---|---|---|---|---|---|
| ample | type | First pixel | Second pixel | Third pixel | Fourth pixel | a | b | c | d |
| 201 | IIa | Composition | Composition | Composition | — | 5 | 5 | — | — |
| | | G201 | R101 | B101 | | | | | |
| 202 | IIa | Composition | Composition | Composition | — | 5 | 5 | — | — |
| | | G202 | R101 | B101 | | | | | |
| 203 | III | Composition | Composition | Composition | Composition | 5 | 5 | 5 | 5 |
| | | G201 | R101 | B101 | IRP101 | | | | |
| 204 | III | Composition | Composition | Composition | Composition | 5 | 5 | 5 | 5 |
| | | G202 | R101 | B101 | IRP101 | | | | |
| 205 | III | Composition | Composition | Composition | Composition | 5 | 5 | 5 | 5 |
| | | G201 | R101 | B101 | W101 | | | | |
| 206 | III | Composition | Composition | Composition | Composition | 5 | 5 | 5 | 5 |
| | | G202 | R101 | B101 | W101 | | | | |
| 207 | IIb | Composition | Composition | Composition | — | 5 | 5 | — | — |
| | | G201 | R101 | B101 | | | | | |
| 208 | IIb | Composition | Composition | Composition | — | 5 | 5 | — | — |
| | | G202 | R101 | B101 | | | | | |

<Evaluation of Stability>

Each structural body of Examples and Comparative Examples was subjected to a constant temperature and humidity test for 2000 hours in a constant temperature and humidity chamber having a temperature of 50° C. and a humidity of 85%. After the constant temperature and humidity test, the cross section of the structural body was observed at a magnification of 40000 times using a transmission electron microscope, and the generation rate of voids between pixels was examined. The stability was evaluated using the generation rate of voids as an index. Evaluation level 3 or higher is a level at which it can be said that the stability of the deep layer portion of pixel is excellent.

Evaluation level and the detail thereof:

5: generation rate of voids=0

4: 0<generation rate of voids≤0.1

3: 0.1<generation rate of voids≤0.2

2: 0.2<generation rate of voids≤0.5

1: 0.5<generation rate of voids≤1.0

The generation rate of voids was calculated by the following expression for each combination of pixels in contact with each other.

Generation rate of voids=[Number of boundaries in which void is generated in observed boundaries]/[Number of observed boundaries]

In addition, in the present examples, 20 cross sections were randomly selected from the structural body, and a total of 200 boundaries was observed by observing the presence or absence of voids in groups of 10 boundaries, which were arranged continuously for each cross section.

The results are shown in Table 11, Table 12, Table 24, and Table 25. In the item of “Stability” in the tables, “a” indicates the evaluation result in the cross section of the first pixel and the second pixel, “b” indicates the evaluation result in the cross section of the first pixel and the third pixel, “c” indicates the evaluation result in the cross section of the second pixel and the fourth pixel, and “d” indicates the evaluation result in the cross section of the third pixel and the fourth pixel.

As shown in each table, it is found that, by using a transparent pigment derivative for pixels adjacent to each other, a structural body having excellent stability in the deep layer portion of pixel is obtained. In particular, from the comparison between Example 2 and Comparative Example 23, comparison between Example 6 and Comparative Example 24, and comparison between Example 12 and Comparative Example 25, even in a case where the transparent pigment derivative is simply used for only one of the adjacent pixels, the result is that the transparent pigment derivative does not contribute much to the improvement of stability.

In addition, in a case where the pigment concentration is 25% by mass, the judgment value of stability was improved from 2 to 5 by using the transparent pigment derivative (comparison between Examples 23 to 25 and Comparative Examples 23 to 25). On the other hand, in a case where the pigment concentration is 60% by mass and a case where the pigment concentration is 40% by mass, the judgment value of stability was improved from 1 to 5 by using the transparent pigment derivative (comparison between Examples 1 to 3 and Comparative Examples 1 to 3, and comparison between Examples 20 to 22 and Comparative Examples 20 to 22). That is, in a case where the pigment concentration in the pixel is as high as approximately 40% by mass or more, since the deep layer portion of pixel is difficult to cure and the stability over time tends to decrease, it can be said that the present invention is very useful in such a case.

In addition, in Examples and Comparative Examples described above, the same results were obtained even in a case where the green pixels were formed by using the green compositions G2, G3, and G6 to G24 instead of the green composition G1. In Examples and Comparative Examples described above, the same results were obtained even in a case where the red pixels were formed by using the red compositions R2, R3, and R6 to R19 instead of the red composition R1. In Examples and Comparative Examples described above, the same results were obtained even in a case where the blue pixels were formed by using the blue compositions B2 and B5 to B18 instead of the blue composition B1. In Examples and Comparative Examples described above, the same results were obtained even in a case where the yellow pixel was formed by using the yellow composition Y2 instead of the yellow composition Y1. In Examples and Comparative Examples described above, the same results were obtained even in a case where the magenta pixel was formed by using the magenta composition M2 instead of the magenta composition M1. In Examples described above, the same results were obtained even in a case where the cyan pixels were formed by using the cyan compositions C2 to C5 instead of the cyan composition C1. In Comparative Examples described above, the same results were obtained even in a case where the cyan pixels were formed by using the cyan compositions C2 to C5 instead of the cyan composition C1. In Examples and Comparative Examples described above, the same results were obtained even in a case where the pixels of near-infrared cut filter were formed by using the compositions SIR2 and SIR3 for near-infrared cut filter instead of the composition SIR1 for near-infrared cut filter. In Examples and Comparative Examples described above, the same results were obtained even in a case where the pixels of near-infrared transmission filter were formed by using the compositions IRP2 and IRP3 for near-infrared transmission filter instead of the composition IRP1 for near-infrared transmission filter. The same results were obtained in a case where pixels were formed using the compositions of other comparative examples.

Furthermore, with regard to the initiator in the composition, even in a case where an oxime compound other than the oxime compound used in Examples was used, a case where two kinds of oxime compounds were used in combination, a case where an oxime compound and an initiator other than the oxime compound were used, and a case where two kinds of initiators other than the oxime compound were used in combination, same as Examples of the present invention, a structural body having excellent stability was obtained. In addition, even in a case where two kinds of solid contents in the composition, such as resins, polymerizable monomers, and solvents, were used in combination, same as Examples of the present invention, a structural body having excellent stability was obtained.

In a case where each structural body of Examples was incorporated into a solid-state imaging element according to a known method and image quality was evaluated, good performance was obtained.

<Practical Application of Structural Body>

Furthermore, three structural bodies having the same structure as the structural body of Example 1 described above were produced, and microlenses were formed on an optical filter consisting of all the pixels in each structural body by the following method using lens material compositions L1 to L3 for IR lenses, which will be described later, thereby producing three structural bodies with a lens. In a case where the same stability evaluation as above was performed, each structural body was stable as in Example 1. With regard to the structural body of Example 10 described above, three structural bodies with a lens were produced by the same procedure, and the same stability evaluation was performed. This structural body with a lens was stable as in Example 10. With regard to the structural body of Example 18 described above, three structural bodies with a lens were produced by the same procedure, and the same stability evaluation was performed. This structural body with a lens was stable as in Example 18. With regard to the structural body of Example 26 described above, three structural bodies with a lens were produced by the same procedure, and the same stability evaluation was performed. This structural body with a lens was stable as in Example 26.

<<Lens Material Composition L1>>

(Production of Pigment Dispersion Liquid L1)

A mixed solution obtained by mixing the following raw materials was mixed and dispersed for 3 hours using a beads mill (zirconia beads having a diameter of 0.1 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was dispersed under a pressure of 2000 kg/cm³ at a flow rate of 500 g/min. This dispersion treatment was repeated up to 10 times, thereby obtaining a pigment dispersion liquid L1.

Raw Materials of Dispersion Liquid:

| | |
|---|---|
| IR coloring agent 1 | 6.8 parts by mass |
| Derivative 10 | 0.8 parts by mass |
| Dispersant 3 | 6.0 parts by mass |
| PGMEA | 86.4 parts by mass |

(Production of Lens Material Composition L1)

Subsequently, after stirring a mixed solution obtained by mixing the following raw materials, the obtained mixed solution was filtered through a nylon filter (manufactured by Pall Corporation) having a pore size of 0.45 μm to obtain a lens material composition L1.

Raw Materials of Composition:

| | |
|---|---|
| Pigment dispersion liquid L1 | 13.0 parts by mass |
| OGSOL PG-100 (manufactured by Osaka Gas | 16.1 parts by mass |
| Chemicals Co., Ltd.) | |
| Resin 1 (40% by mass PGMEA solution) | 3.3 parts by mass |
| 1,2-Dimethylimidazole | 0.6 parts by mass |
| ADK STAB AO-80 (manufactured by ADEKA | 0.2 parts by mass |
| Corporation) | |
| Surfactant 1 (0.2% by mass PGMEA solution) | 4.2 parts by mass |
| PGMEA | 62.6 parts by mass |

<<Lens Material Compositions L2 and L3>>

Lens material compositions L2 and L3 were obtained by the same components, formulation, and procedure as in the case of the lens material composition L1, except that the types of the components of the dispersion liquid and the composition were changed as shown in Table 26.

In the table, the description of ADK STAB AO-80 and surfactant as the additive, and PGMEA as the solvent is omitted because these components are common components in all the compositions. Regarding the components, the corresponding components were changed for each of the columns of “Component 1”, “Component 2”, and “Component 3” in the table. In addition, OGSOL PG-100 and OGSOL CG-500 (both manufactured by Osaka Gas Chemicals Co., Ltd.) are epoxy resins having a fluorene skeleton, and CR-1030 (manufactured by Osaka Gas Chemicals Co., Ltd.) is an acid-modified fluorene type polyester resin.

TABLE 26
Lens material composition

| | Solid content in pigment | | | | | |
|---|---|---|---|---|---|---|
| | dispersion liquid | | | Solid content in additive | | |
| | Coloring | Pigment | | Component | Component | |
| No. | material | derivative | Dispersant | 1 | 2 | Component 3 |
| L1 | IR coloring | Derivative | Dispersant | OGSOL | Resin 1 | 1,2- |
| | agent 1 | 10 | 3 | PG-100 | | Dimethylimidazole |
| L2 | IR coloring | Derivative | Dispersant | OGSOL | Resin 1 | 4-Aminopyridine |
| | agent 1 | 7 | 3 | CG-500 | | |
| L3 | IR coloring | Derivative | Dispersant | OGSOL | CR-1030 | 1,2- |
| | agent 1 | 9 | 3 | CG-500 | | Dimethylimidazole |

With regard to each of the lens material compositions L1 to L3, Table 27 shows the refractive index with respect to light having a wavelength of 550 nm, the minimum transmittance (film thickness: 0.35 μm) with respect to light having a wavelength of 400 to 700 nm, and the transmittance (film thickness: 0.35 μm) with respect to light having a wavelength of 820 nm. A film (film thickness: 0.35 μm) for measuring the refractive index was produced by applying each lens material composition to a silicon wafer by a spin coating method, heating the wafer at 100° C. for 2 minutes using a hot plate, and further heating the wafer at 220° C. for 5 minutes using a hot plate. On the other hand, a film (film thickness: 0.35 μm) for spectroscopic measurement was produced by applying each lens material composition to a glass wafer by a spin coating method, heating the wafer at 100° C. for 2 minutes using a hot plate, and further heating the wafer at 220° C. for 5 minutes using a hot plate.

TABLE 27

| | Refractive index | Transmittance | |
|---|---|---|---|
| No. | 550 nm | 400 to 700 nm | 820 nm |
| Composition L1 | 1.59 | 95% or more | 60% or less |
| Composition L2 | 1.62 | 95% or more | 60% or less |
| Composition L3 | 1.64 | 95% or more | 60% or less |

<<Method for Forming Microlens>>

After producing the optical filter on the silicon wafer, each lens material composition was applied thereto by a spin coating method, heated at 100° C. for 2 minutes using a hot plate, further heated at 220° C. for 5 minutes using a hot plate, thereby forming a lens material composition layer having a film thickness of 1.2 μm. Thereafter, using a transfer method by etch-back, which is a known technique, a microlens was formed by processing the lens material composition layer such that the height from the lens top to the lens bottom was 400 nm.

### EXPLANATION OF REFERENCES

1: support
2: partition wall
P1 to P4: pixel
R: area where void is likely to occur
S1 to S3: structural body
SIR: near-infrared cut filter

What is claimed is:

1. A structural body comprising:
two pixels which are two-dimensionally arranged in a state of being in contact with each other,
wherein each of the two pixels contains
a pigment,
a pigment derivative in which a maximum value of a molar light absorption coefficient in a wavelength range of 400 to 700 nm is 3000 L·mol⁻¹·cm⁻¹ or less, and
a resin.

2. The structural body according to claim 1,
wherein a width of at least one of the two pixels is 0.3 to 5.0 μm.

3. The structural body according to claim 1,
wherein a thickness of at least one of the two pixels is 0.1 to 2.0 μm.

4. The structural body according to claim 1,
wherein a total content of the pigment and the pigment derivative contained in at least one of the two pixels is 25% to 65% by mass.

5. The structural body according to claim 1,
wherein a mass ratio of a content of the pigment derivative contained in at least one of the two pixels and a content of the pigment contained in the same pixel is 3:97 to 20:80.

6. The structural body according to claim 1,
wherein at least one of the pigment derivatives includes an aromatic ring.

7. The structural body according to claim 6,
wherein the at least one of the pigment derivatives includes a group represented by Formula (A1), 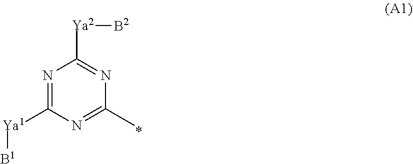
in the formula, * represents a bonding hand,
Ya¹ and Ya² each independently represent —N(Ra¹)— or —O—, where Ra¹ represents a hydrogen atom, an alkyl group, an alkenyl group, an alkynyl group, or an aryl group, and
B¹ and B² each independently represent a hydrogen atom or a substituent.

8. The structural body according to claim 1,
wherein the two pixels are pixels containing different pigments from each other, and
each of the two pixels is a pixel selected from a red pixel, a green pixel, a blue pixel, a yellow pixel, a cyan pixel, a magenta pixel, a black pixel, a white pixel, a pixel of near-infrared cut filter, and a pixel of near-infrared transmission filter.

9. The structural body according to claim 1, further comprising:
a partition wall which is provided between the two pixels and has a lower height than a thickness of the two pixels.

10. A solid-state imaging element comprising:
the structural body according to claim 1 on a semiconductor substrate.

11. An image display device comprising:
the structural body according to claim 1 on a glass substrate.
